(19) United States
(12) Patent Application Publication
(10) Pub. No.: US 2023/0352326 A1
(43) Pub. Date: Nov. 2, 2023

(54) SUBSTRATE PROCESSING APPARATUS AND PROCESSING METHOD

(71) Applicant: EBARA CORPORATION, Tokyo (JP)

(72) Inventors: Kuniaki YAMAGUCHI, Tokyo (JP); Toshio MIZUNO, Tokyo (JP); Itsuki KOBATA, Tokyo (JP); Mitsuru MIYAZAKI, Tokyo (JP); Naoki TOYOMURA, Tokyo (JP); Takuya INOUE, Tokyo (JP)

(21) Appl. No.: 18/349,666

(22) Filed: Jul. 10, 2023

Related U.S. Application Data
(62) Division of application No. 17/036,555, filed on Sep. 29, 2020.
Application No. 17/036,555 is a continuation of application No. 14/872,342, filed on Oct. 1, 2015, now abandoned.

(30) Foreign Application Priority Data
Oct. 3, 2014 (JP) 2014-204739
Oct. 9, 2014 (JP) 2014-207872
Dec. 22, 2014 (JP) 2014-258716

(51) Int. Cl. H01L 21/67; B24B 37/10; B24B 49/14; B24B 53/017; B24B 37/34; H01L 21/304; H01L 21/306; H01L 21/02

(52) U.S. Cl. CPC H01L 21/67248; H01L 21/67178; H01L 21/67109; H01L 21/67051; H01L 21/67046; H01L 21/67028; H01L 21/67219; B24B 37/105; B24B 49/14; B24B 53/017; B24B 37/345; H01L 21/304; H01L 21/30625; H01L 21/6704; H01L 21/02065; H01L 21/02052

(57) ABSTRACT

A polishing apparatus is provided. The polishing apparatus includes:
a polishing unit configured to polish a substrate by bringing a polishing tool into contact with the substrate and moving the substrate relatively to the polishing tool; a cleaning unit; and a first transfer robot configured to transfer the substrate before polishing to the polishing unit and/or configured to transfer the substrate after polishing from the polishing unit to the cleaning unit. The cleaning unit includes: at least one cleaning module, a buff processing module configured to perform a buff process to the substrate, and a second transfer robot configured to transfer the substrate between the cleaning module and the buff processing module, the second transfer robot being different from the first robot.

### CROSS-REFERENCE TO RELATED APPLICATIONS

This application is a divisional of U.S. patent application Ser. No. 17/036,555 filed on Sep. 29, 2020, which is a continuation of U.S. patent application Ser. No. 14/872,342 filed on Oct. 1, 2015, which claims the priority and the benefit of Japanese Patent Application No. 2014-204739 filed on Oct. 3, 2014, Japanese Patent Application No. 2014-207872 filed on Oct. 9, 2014, and Japanese Patent Application No. 2014-258716 filed on Dec. 22, 2014, the entire contents are incorporated herein by reference.

### TECHNICAL FIELD

The present invention relates to a substrate processing apparatus and a processing method. The present invention further relates to a processing component, a processing module, and a processing method. The present invention further relates to a polishing apparatus and a processing method.

### BACKGROUND ART

To perform various kinds of processes to objects (for example, substrates such as semiconductor wafers or various kinds of films formed on a surface of the substrate), processing apparatuses have been used. Examples of such a processing apparatus include a CMP (chemical mechanical polishing) apparatus for performing a polishing process or the like to an object.

A CMP apparatus includes a polishing unit for performing a polishing process to an object, a cleaning unit for performing a cleaning process and a drying process to an object, and a loading/unloading unit for delivering an object to the polishing unit and receiving an object having been cleaned and dried by the cleaning unit. The CMP apparatus further includes a transfer mechanism for transferring an object among the polishing unit, the cleaning unit, and the loading/unloading unit. The CMP apparatus sequentially performs the polishing, cleaning, and drying processes while transferring the object with the transfer mechanism.

In some cases, to remove a polishing liquid or a polishing residue on a surface of a polished object, a CMP apparatus is provided with a processing unit that includes a table on which the object is placed, a head to which a pad having a smaller diameter than the object is attached, and an arm holding the head and horizontally moving in a plane of the object. The processing unit brings the pad into contact with the object and moves the pad relatively to the object to perform a predetermined process to the object.

A conventional technique (for example, U.S. Pat. No. 6,561,881) uses a processing unit that includes a plurality of heads to which respective pads each having a smaller diameter than an object are attached and a plurality of arms holding the respective heads. According to this conventional technique, the plurality of pads can be brought into contact with the object so that a contact area between the pads and the object increases. As a result, improvement of a processing rate can be expected.

The present applicant filed a patent application (Japanese Patent Laid-Open No. 8-71511) concerning a technique in which a finish processing unit that presses a contact member having a smaller diameter than a substrate and causes a relative motion to the substrate after polishing is provided separately from a main polishing unit in a CMP apparatus to further polish the substrate slightly or to clean the substrate.

Regarding flattening techniques including CMP, materials to be polished have been diversified and demands for polishing performance (for example, flatness, polishing damage and productivity) have increased. Regarding CMP apparatuses, because semiconductor apparatuses have been miniaturized, demands for polishing performance and the degree of cleaning have increased.

In a CMP apparatus, generally, an object is cleaned by a roll-shaped sponge (hereinafter, a roll sponge) or a small-diameter sponge (hereinafter, a pencil sponge) being brought into contact with the object. The sponge is made of a soft material such as PVA. To slightly polish a surface of an object to remove adhesive particles that a soft material cannot remove or to remove a microscratch on the surface of the object, providing a finish processing unit in the CMP apparatus has been suggested. The finish processing unit performs a finish process by bringing a member that is harder than PVA into contact with an object. (Japanese Patent Laid-Open No. 8-71511 and Japanese Patent Laid-Open No. 2001-135604)

### SUMMARY OF INVENTION

However, in the above conventional technique that uses the processing unit including the plurality of heads to which the respective pads each having a smaller diameter than an object and the plurality of arms holding the respective heads, no consideration is given to improvement of in-plane uniformity of the object.

That is, the aforementioned processing unit rotates the table and the heads to bring the pads into contact with the object and causes the reciprocating swing of the arms along a radial direction of a processing target surface of the object so that the entire surface of the object is processed. When the arms swing, a contact time of a peripheral edge of the processing target surface of the object with the pads is shorter than that of a center part of the processing target surface with the pads. Therefore, uniformity in processing between the peripheral edge and the center part of the processing target surface may be deteriorated.

In this regard, the conventional technique just uses the plurality of pads each having a smaller diameter than the object. Although a processing rate may be improved, the in-plane uniformity of the object is difficult to be improved.

Therefore, an object of the present invention is to improve a processing rate of an object and in-plane uniformity of the object.

With increasing demands for polishing performance and cleanliness, a CMP apparatus processes a substrate using a buff pad having a smaller size than the substrate to be processed in some cases. Generally, when a buff pad has a smaller size than a substrate to be processed, the buff pad can flatten local unevenness on the surface, polish only a particular area on the substrate, and adjust a polishing amount according to the position of the substrate, providing excellent control performance. On the other hand, when a substrate to be processed is pressed against a polishing pad of a larger size than the substrate and polished, an entire surface of the substrate is always in contact with the polishing pad. Accordingly, the control performance is poor, but the polishing speed increases. When a substrate is processed with a buff pad of a small size, control performance is excellent but a polishing speed tends to decrease compared to a case where a polishing pad having a larger size than a substrate is pressed against the substrate and polished. Therefore, in a buff process using a buff pad having a smaller size than a substrate to be processed, improvement of processing efficiency is demanded.

An object of the present invention is to improve efficiency in a buff process to a substrate in a buff processing apparatus that uses a buff pad having a smaller size than the substrate to be processed.

When a finishing unit is provided in a CMP apparatus to perform a finishing process, as in the conventional technique which provides a finish processing unit in a CMP apparatus, the number of processes increases, which may cause considerable degradation of throughput. Furthermore, an object may wait to be processed by rate controlling in processing. When a polished object that is a metal film, particularly, is left in a wet state including a chemical liquid for a long time, corrosion of the surface of the metal film may progress to affect the processing performance.

To avoid the above problem, a CMP apparatus with a finishing unit leaves room for improvement in the apparatus configuration including a transfer system for efficient transfer.

An object of the present invention is to provide a polishing apparatus and a processing method that can perform a finishing process to an object after a main polishing while preventing degradation of throughput in the apparatus.

### First Embodiment

A first embodiment of the present invention is a processing component that includes a head to which a pad is attached, the pad coming into contact with and moving relatively to an object to perform a predetermined process to the object, and an arm holding the head. The head includes a first head to which a first pad having a smaller diameter than the object is attached, and a second head to which a second pad having a smaller diameter than the first pad is attached, the second head differing from the first head.

### Second Embodiment

A second embodiment of the present invention provides a processing module including the processing component of the first embodiment. The arm includes a first arm and a second arm that is different from the first arm. The first head may be held by the first arm. The second head may be held by the second arm.

### Third Embodiment

According to a third embodiment of the present invention, in the processing module of the second embodiment, the second head may be held by the second arm in such a way that the second pad contacts with a peripheral edge part of the object.

### Fourth Embodiment

According to a fourth embodiment of the present invention, in the processing module of the third embodiment further includes a plurality of the second heads to which the respective second pads are attached, the second heads are held by the second arm in such a way that the second pads are adjacent to each other in a direction of the peripheral edge of the object and are in contact with the peripheral edge part of the object.

### Fifth Embodiment

According to a fifth embodiment of the present invention, in the processing module of the first embodiment, the arm includes a single arm, and the first head and the second head may be held by the single arm.

### Sixth Embodiment

According to a sixth embodiment of the present invention, in the processing module of the fifth embodiment, the second head may be held by the single arm in such a way that the second pad is in contact with at least the peripheral edge part of the object.

### Seventh Embodiment

According to a seventh embodiment of the present invention, in the processing module of the sixth embodiment, the first head and the second head may be held by the single arm so as to be adjacent with each other along a swinging direction of the single arm.

### Eighth Embodiment

According to an eighth embodiment of the present invention, in the processing module of the seventh embodiment, or in an embodiment of a processing module including a processing component, a plurality of the second heads to which the respective second pads are attached may be included, the first head may be held by the single arm, the second heads may be held by the single arm so as to be adjacent to both sides of the first head along the swinging direction of the single arm.

### Ninth Embodiment

A ninth embodiment of the present invention provides a processing module including the processing component of the first embodiment. The arm includes a first arm and a second arm that is coupled with the first arm. The first head may be held by the first arm. The second head may be held by the second arm.

### Tenth Embodiment

A tenth embodiment of the present invention provides a processing module that includes the processing component of the first embodiment, and a table that holds the object. The processing module can process the object by supplying a processing liquid to the object, rotating the table and the head, bringing the first and second pads into contact with the object simultaneously or alternately, and swinging the arms.

### Eleventh Embodiment

According to an eleventh embodiment of the present invention, in the processing module of any one of the second to tenth embodiments, the processing module may be a buff processing module performing a buff process to the object.

### Twelfth Embodiment

According to a twelfth embodiment of the present invention, in the processing module of any one of the second to eleventh embodiments, when the pad includes a plurality of pads, a kind or material of at least one of the pads may be different from a kind or material of the other pads.

### Thirteenth Embodiment

According to a thirteenth embodiment of the present invention, the processing module of any one of the second to eleventh embodiments may further include a plurality of dressers performing conditioning of the pad.

### Fourteenth Embodiment

According to a fourteenth embodiment of the present invention, in the processing module of the thirteenth embodiment, at least one of the plurality of dressers may have a diameter, a kind or a material different from those of the other dressers.

### Fifteenth Embodiment

A fifteenth embodiment of the present invention provides a processing method. The processing method includes bringing a first pad having a smaller diameter than an object into contact with the object and moving the first pad relatively to the object to perform a predetermined first process to the object, and bringing a second pad having a smaller diameter than the first pad into contact with the object and moving the second pad relatively to the object to perform a predetermined second process to the object.

### Sixteenth Embodiment

According to a sixteenth embodiment of the present invention, in the processing method of the fifteenth embodiment, the second process may be performed by bringing the second pad into contact with a peripheral edge part of the object and moving the second pad relatively to the object.

### Seventeenth Embodiment

According to a seventeenth embodiment of the present invention, the processing method of the fifteenth or sixteenth embodiment may further include bringing the first pad into contact with a dresser and moving the first pad relatively to the dresser to perform conditioning of the first pad, and bringing the second pad into contact with a dresser and moving the second pad relatively to the dresser to perform conditioning of the second pad.

### Eighteenth Embodiment

According to an eighteenth embodiment of the present invention, in the processing method of the seventeenth embodiment, the first process and the second process may be performed simultaneously, and the conditioning of the first pad and the conditioning of the second pad may be performed simultaneously.

### Nineteenth Embodiment

According to a nineteenth embodiment of the present invention, in the processing method of the seventeenth embodiment, the conditioning of the second pad may be performed simultaneously in the first process, the conditioning of the first pad may be performed simultaneously in the second process.

### Twentieth Embodiment

According to a twentieth embodiment of the present invention, in the processing method of the seventeenth embodiment, the first process and the second process may be started at different timings, and the conditioning of the first pad and the conditioning of the second pad may be started at different timings.

### Twenty-First Embodiment

According to a twenty-first embodiment of the present invention, in the processing method of any one of the fifteenth to twentieth embodiments, in a processing module that includes a table holding the object, a plurality of heads to which the first pad and the second pad are attached, and one or more arms holding the plurality of heads, the first process and the second process may be performed by supplying a processing liquid to the object, rotating the table and the heads, bringing the first and second pads into contact with the object simultaneously or alternatively, and swinging the arm.

### Twenty-Second Embodiment

A twenty-second embodiment of the present invention provides a buff processing apparatus buffing an object. The buff processing apparatus includes a buff table that supports the object, a buff pad that is configured to swing on the object supported on the buff table while keeping contact with the object to buffing the object, and a temperature controlling device that controls a temperature of the object supported on the buff table. An area of a surface of the buff table for supporting the object is substantially equal to or larger than a contact area of the buff pad with the object.

### Twenty-Third Embodiment

According to a twenty-third embodiment of the present invention, in the buff processing apparatus of the twenty-second embodiment, the temperature controlling device includes a blower that is configured to supply a gas controlled in temperature toward the object supported on the buff table.

### Twenty-Fourth Embodiment

According to a twenty-fourth embodiment of the present invention, in the buff processing apparatus of the twenty-second or twenty-third embodiment, the temperature controlling device includes a fluid circulation passage circulating a fluid into the buff table and a temperature controlling unit controlling a temperature of the fluid passing through the fluid circulation passage in the buff table.

### Twenty-Fifth Embodiment

According to a twenty-fifth embodiment of the present invention, in the buff processing apparatus of any one of the twenty-second to twenty-fourth embodiments, the temperature controlling device includes a temperature controlling unit controlling a temperature of slurry and/or chemical liquid used for buffing of the object.

### Twenty-Sixth Embodiment

According to a twenty-sixth embodiment of the present invention, in the buff processing apparatus of the twenty-fifth embodiment, the buff pad includes a fluid passage for supplying the object with slurry and/or chemical liquid used for buffing of the object through the buff pad.

### Twenty-Seventh Embodiment

According to a twenty-seventh embodiment of the present invention, the buff processing apparatus of any one of the twenty-second to twenty-sixth embodiments further includes a thermometer that is configured to measure a temperature of the object supported on the buff table.

### Twenty-Eighth Embodiment

According to a twenty-eighth embodiment of the present invention, in the buff processing apparatus of the twenty-seventh embodiment, the thermometer includes a radiation thermometer capable of measuring the temperature of the object in a non-contact manner.

### Twenty-Ninth Embodiment

According to a twenty-ninth embodiment of the present invention, in the buff processing apparatus of the twenty-seventh or twenty-eighth embodiment, the thermometer includes a sheet-type in-plane temperature distribution thermometer that is placed in the buff table.

### Thirtieth Embodiment

According to a thirtieth embodiment of the present invention, in the buff processing apparatus of any one of the twenty-seventh to twenty-ninth embodiments, the temperature controlling device is connected to the thermometer, and the temperature controlling device is configured to control the temperature of the object based on the temperature measured by the thermometer.

### Thirty-First Embodiment

A thirty-first embodiment of the present invention provides a buffing method using a buff pad having a smaller size than an object. The method includes controlling a temperature of the object to be buffed.

### Thirty-Second Embodiment

According to a thirty-second embodiment of the present invention, the method of the thirty-first embodiment further includes supplying a gas controlled in temperature to the object.

### Thirty-Third Embodiment

According to a thirty-third embodiment of the present invention, the method of the thirty-first or thirty-second embodiment further includes circulating a fluid controlled in temperature to a fluid circulation passage formed in a buff table supporting the object.

### Thirty-Fourth Embodiment

According to a thirty-fourth embodiment of the present invention, the method of any one of the thirty-first to thirty-third embodiments further includes supplying slurry and/or chemical liquid controlled in temperature to the object.

### Thirty-Fifth Embodiment

According to a thirty-fifth embodiment of the present invention, the method of the thirty-fourth embodiment further includes supplying the slurry and/or the chemical liquid controlled in temperature to the object through a fluid passage formed in the buff pad.

### Thirty-Sixth Embodiment

According to a thirty-sixth embodiment of the present invention, the method of any one of the thirty-first to thirty-fifth embodiments further includes measuring a temperature of the object to be buffed.

### Thirty-Seventh Embodiment

According to a thirty-seventh embodiment of the present invention, the method of the thirty-sixth embodiment further includes controlling the temperature of the object to be buffed based on the measured temperature of the object.

### Thirty-Eighth Embodiment

A thirty-eighth embodiment of the present invention provides a buff processing apparatus for buffing an object. The buff processing apparatus includes a buff table that supports the object, a buff pad that is configured to swing on the object supported on the buff table while keeping contact with the object to buff the object, and temperature controlling means that controls a temperature of the object supported on the buff table. An area of a surface of the buff table for supporting the object is substantially equal to a contact area of the buff pad with the object.

### Thirty-Ninth Embodiment

According to a thirty-ninth embodiment of the present invention, the buff processing apparatus of the thirty-eighth embodiment further includes temperature measuring means that measures the temperature of the object to be buffed.

### Fortieth Embodiment

According to a fortieth embodiment of the present invention, in the buff processing apparatus of the thirty-eighth or thirty-ninth embodiment, the temperature controlling means is configured to control the temperature of the object based on the temperature of the object measured by the temperature measuring means.

### Forty-First Embodiment

A forty-first embodiment of the present invention provides a polishing apparatus. The polishing apparatus includes a polishing unit that polishes an object by bringing a polishing tool into contact with the object and moving the object relatively to the polishing tool, a first transfer robot that transfers the object before polishing to the polishing unit and/or transfers the object after polishing from the polishing unit, and a cleaning unit. The cleaning unit includes at least one cleaning module, a buff processing module that performs a finishing process to the object, and a second transfer robot that transfers the object between the cleaning module and the buff processing module and is different from the first robot.

### Forty-Second Embodiment

According to a forty-second embodiment of the present invention, in the polishing apparatus of the forty-first embodiment, the cleaning unit may include a cleaning chamber that includes the cleaning module inside, a buff processing chamber that includes the buff processing module inside, and a transfer chamber that is placed between the cleaning chamber and the buff processing chamber, and the second transfer robot may be placed in the transfer chamber.

### Forty-Third Embodiment

According to a forty-third embodiment of the present invention, in the polishing apparatus of the forty-second embodiment, a pressure in the transfer chamber may be higher than a pressure in the buff processing chamber.

### Forty-Fourth Embodiment

According to a forty-fourth embodiment of the present invention, in the polishing apparatus of the forty-second embodiment, two buff processing modules may be placed in an up-and-down direction in the buff processing chamber.

### Forty-Fifth Embodiment

According to a forty-fifth embodiment of the present invention, in the polishing apparatus of any one of the forty-first to forth-fourth embodiments, the buff processing module may include a buff table that holds the object with a processing target surface of the object turned up, a buff member that has a smaller diameter than the object and comes into contact with the object to perform the finishing process to the object, and a buff head that holds the buff member, and the buff processing module may perform the finishing process to the object by bringing the buff member into contact with the object and moving the object relatively to the buff member while supplying a buff processing liquid.

### Forty-Sixth Embodiment

According to a forty-sixth embodiment of the present invention, in the polishing apparatus of the forty-fifth embodiment, the buff processing module may further include a dresser that performs conditioning of the buff member, and a dressing table that holds the dresser, and the buff processing module may perform conditioning of the buff member by rotating the dressing table and the buff head and bringing the buff member into contact with the dresser.

### Forty-Seventh Embodiment

According to a forty-seventh embodiment of the present invention, in the polishing apparatus of the forty-fifth or forty-sixth embodiment, two buff processing modules may be placed in an up-and-down direction in the buff processing chamber, and the two buff processing modules may use different buff processing liquids which are at least one of a processing liquid for the buff member and a buff processing liquid for the finishing process.

### Forty-Eighth Embodiment

A forty-eighth embodiment of the present invention provides a processing method. The processing method includes a polishing step of polishing an object by moving the object relatively to a polishing tool while keeping the object in contact with the polishing tool, a first transfer step in which a first transfer robot transfers an object before polishing to perform the polishing step and/or transfers an object after the polishing step, a cleaning step of cleaning the object, a buff processing step of performing a finishing process to the object, and a second transfer step in which a second transfer robot that is different from the first transfer robot transfers the object between the cleaning step and the buff processing step, and the second transfer step being different from the first transporting step.

### Forty-Ninth Embodiment

According to a forty-ninth embodiment of the present invention, in the processing method of the forty-eighth embodiment, the second transfer step may be performed by the second transfer robot in a transfer chamber that is placed between a cleaning chamber including a cleaning module performing the cleaning step inside and a buff processing chamber including a buff processing module performing the buff processing step inside.

### Fiftieth Embodiment

According to a fiftieth embodiment of the present invention, in the processing method of the forty-ninth embodiment, a pressure in the transfer chamber may be higher than a pressure in the buff processing chamber.

### Fifty-First Embodiment

According to a fifty-first embodiment of the present invention, in the processing method of the forty-ninth embodiment, the buff processing step may be performed by two buff processing modules placed in an up-and-down direction in the buff processing chamber.

### Fifty-Second Embodiment

According to a fifty-second embodiment of the present invention, in the processing method of any one of the forty-eighth to fifty-first embodiments, the buff processing step may be performed by the buff processing module that includes a buff table holding the object with a processing target surface of the object turned up, a buff member having a smaller diameter than the object and coming into contact with the object to perform a finishing process to the object, and a buff head that holds the buff member, and the buff processing step may include (A) a main buffing step of buffing the object by bringing the buff member into contact with the object and moving the object relatively to the buff member while supplying a buff processing liquid, (B) an object cleaning step of cleaning the object after the main buffing step, and (C) a buff table cleaning step of cleaning the buff table before a succeeding object is fed into the buff processing module after the object cleaning step.

### Fifty-Third Embodiment

According to a fifty-third embodiment of the present invention, in the processing method of the fifty-second embodiment, the buff processing step may include a step of performing conditioning of the buff member by rotating a dressing table and the buff head and bringing the buff member into contact with a dresser, the dressing table holding the dresser performing conditioning of the buff member.

### Fifty-Fourth Embodiment

According to a fifty-fourth embodiment of the present invention, in the processing method of the fifty-second or fifty-third embodiment, the buff processing step may be performed in such a way that two buff processing modules placed in an up-and-down direction in the buff processing chamber use different buff processing liquids which are at least one of a processing liquid for the buff member and a buff processing liquid for the finishing process.

### Fifty-Fifth Embodiment

According to a fifty-fifth embodiment of the present invention, in the processing method of the fifty-second or fifty-third embodiment, the object cleaning step may include at least one of (A) a buff chemical wash-off step of removing the buff processing liquid by performing the buff process while supplying deionized water, (B) a chemical buff processing step of performing the buff process while supplying a buff processing liquid that is different from that in the main buff step, and (C) a step of rinse-cleaning the object using the buff processing liquid used in the chemical buff processing step or deionized water without bringing the buff member into contact with the object.

### Fifty-Sixth Embodiment

According to a fifty-sixth embodiment of the present invention, in the processing method of any one of the fifty-second to fifty-fifth embodiments, in the buff processing step, a dresser rinsing process that is a process of cleaning a surface of the dresser may be started in the object cleaning step.

### Fifty-Seventh Embodiment

According to a fifty-seventh embodiment of the present invention, in the processing method of any one of the fifty-second to fifty-sixth embodiments, in the buff processing step, a pad rinsing process that is a process of cleaning the buff member with the buff member placed opposite to the dresser may be performed at least before or after performing conditioning of the buff member.

### BRIEF DESCRIPTION OF DRAWINGS

FIG. 1 is a plan view illustrating an entire configuration of a processing apparatus of a present embodiment;

FIG. 2 is a perspective view schematically illustrating a polishing module;

FIG. 3A is a plan view of a cleaning unit;

FIG. 3B is a side view of the cleaning unit;

FIG. 4 is a diagram illustrating a schematic configuration of an upper buff processing module;

FIG. 5 is a diagram illustrating a schematic configuration of a buff processing component of a first embodiment;

FIG. 6 is a diagram illustrating a schematic configuration of a buff processing component of a second embodiment;

FIG. 7 is a diagram illustrating a schematic configuration of a buff processing component of a third embodiment;

FIG. 8 is a diagram illustrating a schematic configuration of a buff processing component of a fourth embodiment;

FIG. 9 is a diagram illustrating a schematic configuration of a buff processing component of a fifth embodiment;

FIG. 10 is a diagram illustrating a schematic configuration of a buff processing component of a sixth embodiment;

FIG. 11 is a diagram illustrating a schematic configuration of a buff processing component of a seventh embodiment;

FIG. 12 is a flowchart of a processing method of the present embodiment;

FIG. 13 is a flowchart of the processing method of the present embodiment;

FIG. 14 is a flowchart of the processing method of the present embodiment;

FIG. 15 is a flowchart of the processing method of the present embodiment;

FIG. 16 is a graph showing a relation between a pad temperature and a polishing speed relative to two different kinds of slurry A and slurry B;

FIG. 17 is a graph showing a relation between a polishing time and a polishing temperature relative to polishing pads having different diameters;

FIG. 18 is a diagram schematically illustrating a buff processing module according to an embodiment that is applicable to the buff processing apparatus of the present invention;

FIG. 19 is a schematic top view of the buff processing apparatus according to an embodiment with a blower for controlling a temperature of a wafer W that is being buffed;

FIG. 20 is a schematic sectional view of the buff processing apparatus according to an embodiment with a temperature controlling unit for controlling the temperature of the wafer W that is being buffed and a fluid circulation passage;

FIG. 21 is a schematic sectional view of the buff processing apparatus according to an embodiment with a temperature adjusting unit for controlling the temperature of the wafer W that is being buffed and a fluid passage;

FIG. 22 is a schematic sectional view of the buff processing apparatus according to an embodiment with a temperature adjusting unit for controlling the temperature of the wafer W that is being buffed;

FIG. 23 is a schematic side view of the buff processing apparatus according to an embodiment with a radiation thermometer for measuring the temperature of the wafer W that is being buffed;

FIG. 24 is a schematic side view of the buff processing apparatus according to an embodiment with a sheet-type in-plane temperature distribution thermometer for measuring the temperature of the wafer W that is being buffed;

FIG. 25 is a plan view of an entire configuration of a polishing apparatus of the present embodiment;

FIG. 26 is a perspective view schematically illustrating a polishing module;

FIG. 27A is a plan view of a cleaning unit;

FIG. 27B is a side view of the cleaning unit;

FIG. 28 is a diagram illustrating a schematic configuration of an upper buff processing module;

FIG. 29 is a diagram illustrating an example of a processing method of the polishing apparatus of the present embodiment;

FIG. 30 is a diagram illustrating an example of the processing method of the polishing apparatus of the present embodiment;

FIG. 31 is a diagram illustrating an example of a processing method of the present embodiment;

FIG. 32 is a diagram showing an outline of a pad rinsing process;

FIG. 33 is a diagram showing an outline of a pad dressing process;

FIG. 34 is a diagram showing an outline of a dresser rinsing process;

FIG. 35A is a diagram illustrating an example of a structure of a buff pad;

FIG. 35B is a diagram illustrating an example of the structure of the buff pad;

FIG. 35C is a diagram illustrating an example of the structure of the buff pad;

FIG. 35D is a diagram illustrating an example of the structure of the buff pad;

FIG. 35E is a diagram illustrating an example of the structure of the buff pad;

FIG. 35F is a diagram illustrating an example of the structure of the buff pad;

FIG. 36 is an explanatory diagram of a swinging range of the buff pad by buff arm;

FIG. 37 is an explanatory diagram of an outline of control of a swinging speed of the buff arm;

FIG. 38 is a diagram illustrating an example of control of the swinging speed of the buff arm; and

FIG. 39 is a diagram illustrating variations of a swinging form of the buff arm.

### DESCRIPTION OF EMBODIMENTS

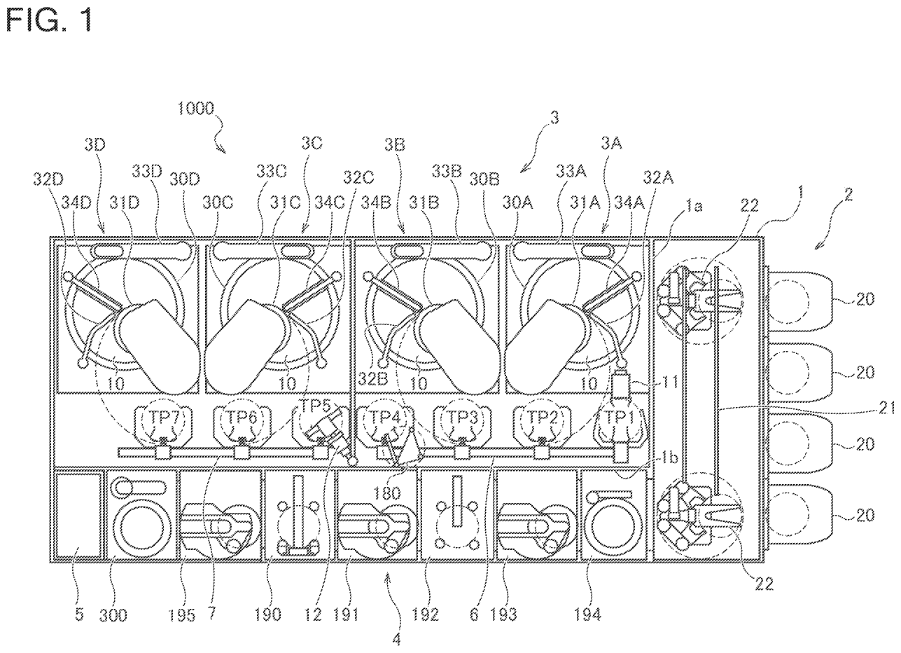

Hereinafter, descriptions will be given of a processing component, a processing module, and a processing method according to an embodiment of the present invention with reference to FIGS. 1 to 15.

<Processing Apparatus>

FIG. 1 is a plan view illustrating an entire configuration of a processing apparatus according to an embodiment of the present invention. As illustrated in FIG. 1, a processing apparatus (a CMP apparatus) 1000 for processing an object includes a housing 1 that has a substantially rectangular shape. Inside the housing 1, a loading/unloading unit 2, a polishing unit 3, and a cleaning unit 4 are partitioned from one another by partition walls 1a and 1b. The loading/unloading unit 2, the polishing unit 3, and the cleaning unit 4 are separately assembled and gas in the respective units is independently exhausted. The cleaning unit 4 includes a power supply part that supplies power to the processing apparatus and a control device 5 that controls processing operations.

<Loading/Unloading Unit>

The loading/unloading unit 2 includes two or more (four in the present embodiment) front loading parts 20 on which a wafer cassette for stocking many objects (for example, wafers (substrates)) is placed. The front loading parts 20 are adjacent to the housing 1 and arranged along a width direction (a direction perpendicular to the longitudinal direction) of the processing apparatus. To the front loading part 20, an open cassette, a SMIF (Standard Manufacturing Interface) pod, or a FOUP (Front Opening Unified Pod) can be mounted. The SMIF and the FOUP each are an airtight container that can house a wafer cassette and be covered with a partition wall to keep an environment isolated from an external space.

On the loading/unloading unit 2, a traveling mechanism 21 is laid along the arrangement of the front loading parts 20. On the traveling mechanism 21, two transfer robots (loaders, transfer mechanisms) 22 that are movable along the arrangement direction of wafer cassettes are provided. The transfer robots 22 moves on the traveling mechanism 21 to access the wafer cassettes mounted on the front loading parts 20 by moving. Each of the transfer robots 22 includes upper and lower hands. The upper hand is used to return a wafer after processing to the wafer cassette. The lower hand is used to take a wafer before processing from the wafer cassette. In this way, the upper and lower hands can be used for different purposes. The lower hand of the transfer robot 22 can reverse a wafer.

Since the loading/unloading unit 2 needs to keep cleanest, a pressure inside the loading/unloading unit 2 is always kept higher than that of any of the external part of the processing apparatus, the polishing unit 3, and the cleaning unit 4. The polishing unit 3 is the dirtiest area because the polishing unit 3 uses slurry as a polishing liquid. Accordingly, a negative pressure is made inside the polishing unit 3 and is kept lower than the internal pressure of the cleaning unit 4. The loading/unloading unit 2 is provided with a filter fan unit (not illustrated) having a clean air filter such as a HEPA filter, an ULPA filter or a chemical filter. Clean air from which particles, toxic vapor or toxic gas has been removed is always blown out from the clean fan filter.

<Polishing Unit>

The polishing unit 3 is an area where polishing (flattening) of a wafer is performed. The polishing unit 3 includes a first polishing module 3A, a second polishing module 3B, a third polishing module 3C, and a fourth polishing module 3D. As illustrated in FIG. 1, the first polishing module 3A, the second polishing module 3B, the third polishing module 3C, and the fourth polishing module 3D are arranged along a longitudinal direction of the processing apparatus.

As illustrated in FIG. 1, the first polishing module 3A includes a polishing table 30A with a polishing pad (a polishing tool) 10 having a polishing surface, a top ring 31A for holding and pressing a wafer against the polishing pad 10 on the polishing table 30A to polish the wafer, a polishing-liquid supplying nozzle 32A for supplying a polishing liquid or a dressing liquid (for example, deionized water) to the polishing pad 10, a dresser 33A for dressing the polishing surface of the polishing pad 10, and an atomizer 34A that injects mixed fluid of liquid (for example, deionized water) and gas (for example, nitrogen gas) or liquid (for example, deionized water) to remove slurry or a polishing product on the polishing surface and a polishing pad residue caused by dressing.

Similarly, the second polishing module 3B includes a polishing table 30B, a top ring 31B, a polishing-liquid supplying nozzle 32B, a dresser 33B, and an atomizer 34B. The third polishing module 3C includes a polishing table 30C, a top ring 31C, a polishing-liquid supplying nozzle 32C, a dresser 33C, and an atomizer 34C. The fourth polishing module 3D includes a polishing table 30D, a top ring 31D, a polishing-liquid supplying nozzle 32D, a dresser 33D, and an atomizer 34D.

Each of the first polishing module 3A, the second polishing module 3B, the third polishing module 3C, and the fourth polishing module 3D has a same configuration. Thus, only the first polishing module 3A will be described below.

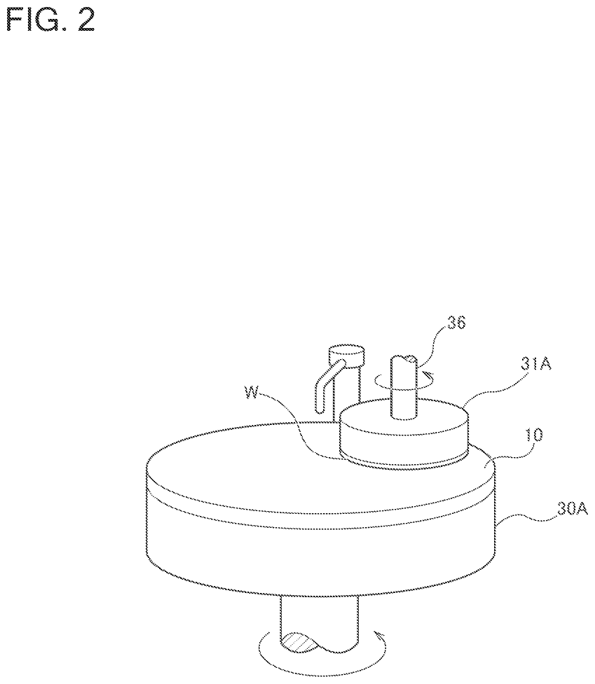

FIG. 2 is a perspective view schematically illustrating the first polishing module 3A. The top ring 31A is supported by a top-ring shaft 36. The polishing pad 10 is attached to an upper surface of the polishing table 30A. An upper surface of the polishing pad 10 forms a polishing surface for polishing a wafer W. Alternatively, fixed abrasive grains may be used instead of the polishing pad 10. The top ring 31A and the polishing table 30A are configured to rotate around a shaft center thereof as illustrated by an arrow. The wafer W is held on a lower surface of the top ring 31A by vacuum suction. During polishing, while a polishing liquid is supplied to the polishing surface of the polishing pad 10 from the polishing-liquid supplying nozzle 32A, the wafer W to be polished is pressed against the polishing surface of the polishing pad 10 by the top ring 31A so that the wafer W is polished.

<Transfer Mechanism>

Next, a transfer mechanism for transferring a wafer will be described. As illustrated in FIG. 1, a first linear transporter 6 is adjacent to the first polishing module 3A and the second polishing module 3B. The first linear transporter 6 is a mechanism for transferring a wafer among four transfer positions (a first transfer position TP1, a second transfer position TP2, a third transfer position TP3, and a fourth transfer position TP4, in order from the side of the loading/unloading unit) arranged along an arrangement direction of the polishing modules 3A and 3B.

A second linear transporter 7 is adjacent to the third polishing module 3C and the fourth polishing module 3D. The second linear transporter 7 is a mechanism for transferring a wafer among three transfer positions (a fifth transfer position TP5, a sixth transfer position TP6, and a seventh transfer position TP7, in order from the side of the loading/unloading unit) arranged along an arrangement direction of the polishing modules 3C and 3D.

A wafer is transferred to the polishing modules 3A and 3B by the first linear transporter 6. The top ring 31A of the first polishing module 3A moves between a polishing position and the second transfer position TP2 by a swinging operation of a top ring head. Accordingly, at the second transport position TP2, a wafer is delivered to the top ring 31A. In the same manner, the top ring 31B of the second polishing module 3B moves between a polishing position and the third transfer position TP3, and a wafer is delivered to the top ring 31B at the third transfer position TP3. The top ring 31C of the third polishing module 3C moves between a polishing position and the sixth transfer position TP6, and a wafer is delivered to the top ring 31C at the sixth transfer position TP6. The top ring 31D of the fourth polishing module 3D moves between a polishing position and the seventh transfer position TP7, and a wafer is delivered to the top ring 31D at the seventh transfer position TP7.

At the first transfer position TP1, a lifter 11 for receiving a wafer from the transfer robots 22 is disposed. A wafer is delivered from the transfer robots 22 to the first linear transporter 6 via the lifter 11. A shutter (not illustrated) is disposed at the partition wall 1a to be positioned between the lifter 11 and the transfer robots 22. When a wafer is transferred, the shutter is opened so that the wafer is delivered from the transfer robots 22 to the lifter 11. A swing transporter 12 is disposed among the first linear transporter 6, the second linear transporter 7, and the cleaning unit 4. The swing transporter 12 has a hand that is movable between the fourth transfer position TP4 and the fifth transfer position TP5. The swing transporter 12 delivers a wafer from the first linear transporter 6 to the second linear transporter 7. A wafer is transferred to the third polishing module 3C and/or the fourth polishing module 3D by the second linear transporter 7. A wafer having been polished at the polishing unit 3 is delivered to the cleaning unit 4 via the swing transporter 12. A temporary placing base 180 for a wafer W that is placed on a non-illustrated frame is placed at the side of the swing transporter 12. The temporary placing base 180 is adjacent to the first linear transporter 6 and is positioned between the first linear transporter 6 and the cleaning unit 4.

<Cleaning Unit>

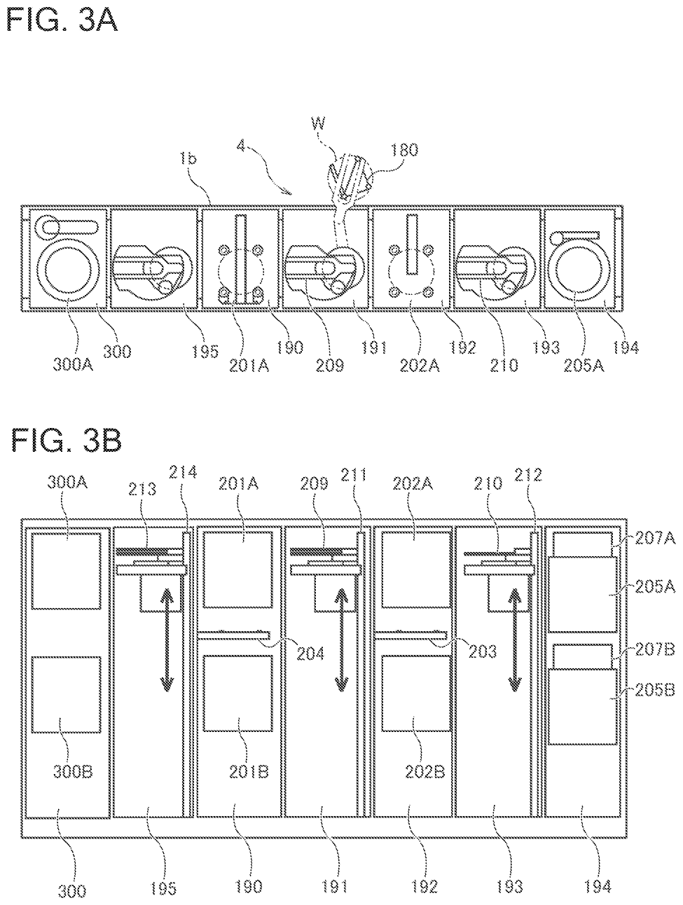

FIG. 3A is a plan view of the cleaning unit 4. FIG. 3B is a side view of the cleaning unit 4. As illustrated in FIGS. 3A and 3B, the cleaning unit 4 is separated into a roll cleaning chamber 190, a first transfer chamber 191, a pen cleaning chamber 192, a second transfer chamber 193, a drying chamber 194, a buff processing chamber 300, and a third transfer chamber 195. The pressure balance among the polishing unit 3, the roll cleaning chamber 190, the pen cleaning chamber 192, the drying chamber 194 and the buff processing chamber 300 can be set to hold the drying chamber 194>the roll cleaning chamber 190 and the pen cleaning chamber 192>the buff processing chamber 300≥the polishing unit 3. The polishing unit uses a polishing liquid. The buff processing chamber also uses a polishing liquid as a buff processing liquid in some cases. Accordingly, the above pressure balance prevent particle components such as abrasive grains in the polishing liquid, particularly, from flowing into the cleaning and drying chambers. Therefore, cleanliness of the cleaning and drying chambers can be maintained.

In the roll cleaning chamber 190, an upper roll cleaning module 201A and a lower roll cleaning module 201B arranged in a longitudinal direction are placed. The upper roll cleaning module 201A is placed above the lower roll cleaning module 201B. Each of the upper roll cleaning module 201A and the lower roll cleaning module 201B is a cleaner that cleans a wafer by pressing two rotating roll sponges (first cleaning tools) against individually front and rear surfaces of the wafer while supplying a cleaning liquid to the front and rear surfaces of the wafer. A temporary placing base 204 for a wafer is placed between the upper roll cleaning module 201A and the lower roll cleaning module 201B.

In the pen cleaning chamber 192, an upper pen cleaning module 202A and a lower pen cleaning module 202B arranged in a longitudinal direction are placed. The upper pen cleaning module 202A is placed above the lower pen cleaning module 202B. Each of the upper pen cleaning module 202A and the lower pen cleaning module 202B is a cleaner that cleans a wafer by pressing a rotating pencil sponge (a second cleaning tool) against a front surface of the wafer and swinging in a radial direction of the wafer while supplying a cleaning liquid to the front surface of the wafer. A temporary placing base 203 for a wafer is placed between the upper pen cleaning module 202A and the lower pen cleaning module 202B.

In the drying chamber 194, an upper drying module 205A and a lower drying module 205B arranged in a longitudinal direction are placed. The upper drying module 205A is separated from the lower drying module 205B. Filter fan units 207A and 207B supplying clean air into the drying modules 205A and 205B, respectively, are placed on upper parts of the upper drying module 205A and the lower drying module 205B, respectively.

The upper roll cleaning module 201A, the lower roll cleaning module 201B, the upper pen cleaning module 202A, the lower pen cleaning module 202B, the temporary placing base 203, the upper drying module 205A, and the lower drying module 205B are fixed to non-illustrated frames via respective bolts or the like.

In the first transfer chamber 191, a first transfer robot (a transfer mechanism) 209 that can move upward and downward is placed. In the second transfer chamber 193, a second transfer robot 210 that can move upward and downward is placed. In the third transfer chamber 195, a third transfer robot (a transfer mechanism) 213 that can move upward and downward is placed. The first transfer robot 209, the second transfer robot 210, and the third transfer robot 213 are supported by supporting shafts 211, 212 and 214, respectively, that extend in a longitudinal direction, in a movable manner. The first transfer robot 209, the second transfer robot 210, and the third transfer robot 213 each have a driving mechanism such as a motor inside to be movable upward and downward along the supporting shafts 211, 212, and 214, respectively. Similarly to the transfer robot 22, the first transfer robot 209 has two upper and lower hands. As shown by a dotted line in FIG. 3A, the first transfer robot 209 is placed at a position for allowing the lower hand to access the aforementioned temporary placing base 180. When the lower hand of the first transfer robot 209 accesses the temporary placing base 180, a shutter (not illustrated) placed on the partition wall 1b opens.

The first transfer robot 209 operates so as to transfer the wafer W among the temporary placing base 180, the upper roll cleaning module 201A, the lower roll cleaning module 201B, the temporary placing base 204, the temporary placing base 203, the upper pen cleaning module 202A and the lower pen cleaning module 202B. The first transfer robot 209 uses the lower hand to transfer a wafer before cleaning (a wafer with slurry adhered), and uses the upper hand to transfer a wafer after cleaning.

The second transfer robot 210 operates so as to transfer the wafer W among the upper pen cleaning module 202A, the lower pen cleaning module 202B, the temporary placing base 203, the upper drying module 205A, and the lower drying module 205B. Since the second transfer robot 210 transfers only a cleaned wafer, the second transfer robot 210 has only one hand. The transfer robot 22 illustrated in FIG. 1 uses the upper hand to take out a wafer from the upper drying module 205A or the lower drying module 205B and return the wafer to the wafer cassette. When the upper hand of the transfer robot 22 accesses the drying modules 205A and 205B, a shutter (not illustrated) placed on the partition wall 1a opens.

The buff processing chamber 300 is provided with an upper buff processing module 300A and a lower buff processing module 300B. The third transfer robot 213 operates so as to transfer the wafer W among the upper roll cleaning module 201A, the lower roll cleaning module 201B, the temporary placing base 204, the upper buff processing module 300A, and the lower buff processing module 300B.

In the present embodiment, in the cleaning unit 4, the buff processing chamber 300, the roll cleaning chamber 190, and the pen cleaning chamber 192 are placed in order from a side far from the loading/unloading unit 2, but not limited to this. An arrangement form of the buff processing chamber 300, the roll cleaning chamber 190, and the pen cleaning chamber 192 may be selected as appropriate depending on wafer quality, throughput or the like. Moreover, the present embodiment describes an example where the upper buff processing module 300A and the lower buff processing module 300B are provided, but not limited to this. Only one of the buff processing modules may be provided. Furthermore, in the present embodiment, in addition to the buff processing chamber 300, the roll cleaning module and the pen cleaning module are described as modules for cleaning the wafer W, but not limited to these modules. Two-fluid jet cleaning (2FJ cleaning) or megasonic cleaning may be performed. In the two-fluid jet cleaning, micro droplets (mist) in high-speed gas are sprayed from a two-fluid nozzle to and collided with the wafer W and a shock wave generated by collision of the micro droplets with the surface of the wafer W is used to remove (clean) particles or the like on the surface of the wafer W. In megasonic cleaning, ultrasonic waves are applied to a cleaning liquid, an acting force caused by vibration acceleration of molecules in the cleaning liquid is applied to adhering particles such as particles to remove the particles. Hereinafter, descriptions are given of the upper buff processing module 300A and the lower buff processing module 300B. Since each of the upper buff processing module 300A and the lower buff processing module 300B has a same configuration, only the upper buff processing module 300A is described.

<Buff-Processing Module>

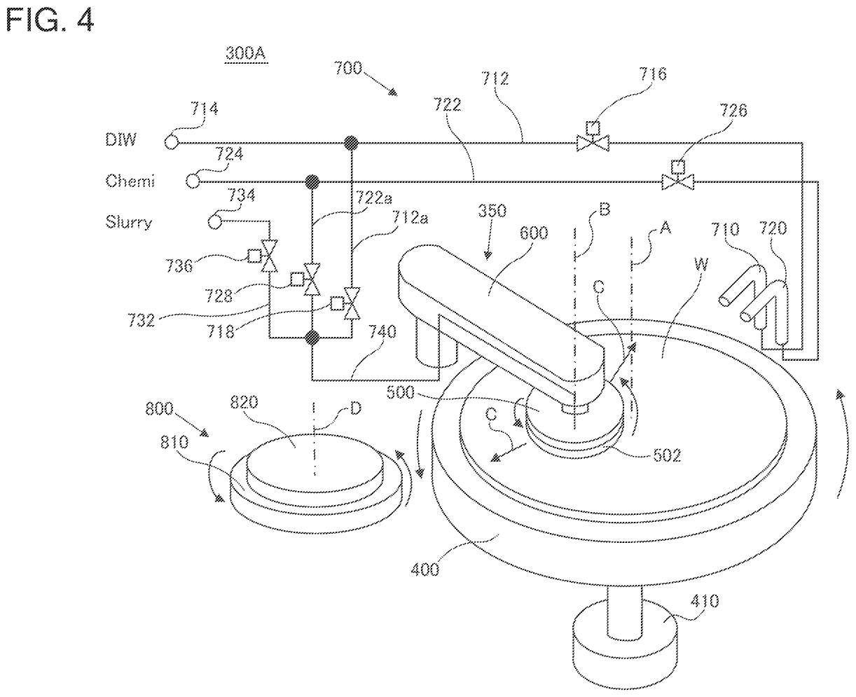

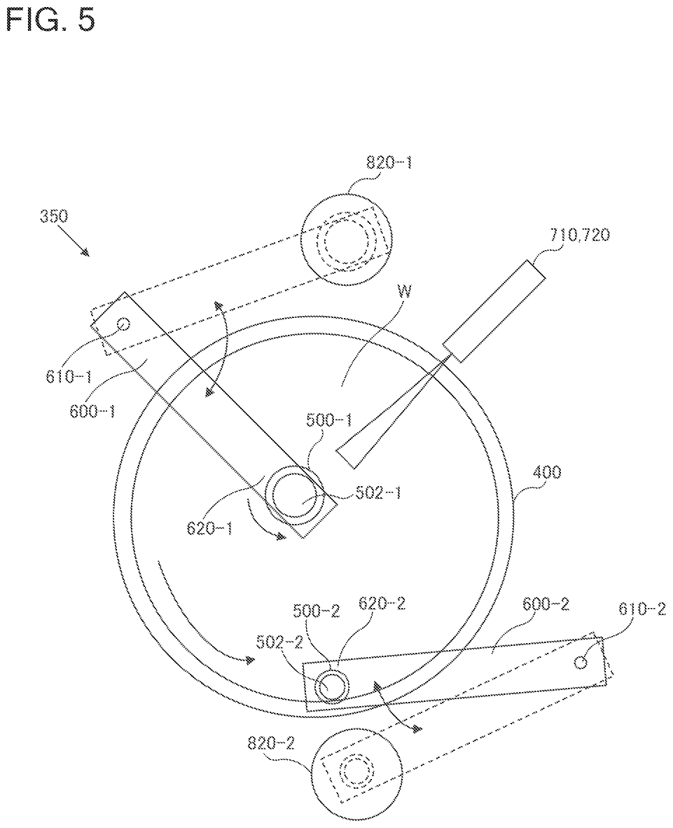

FIG. 4 is a diagram illustrating a schematic configuration of an upper buff processing module. As illustrated in FIG. 4, the upper buff processing module 300A includes a buff table 400 on which the wafer W is placed, a buff processing component 350, a liquid supplying system 700 that supplies a buff processing liquid, and a conditioning unit 800 that performs conditioning (setting) of a buff pad 502. The buff processing component 350 includes a buff head 500 to which the buff pad 502 that buffs a processing target surface of the wafer W and a buff arm 600 that holds the buff head 500. To describe a basic configuration of the buff processing component 350, FIG. 4 illustrates an example of the buff processing component 350 including the single buff arm 600 and the single buff head 500. However, the buff processing component 350 of the present embodiment actually has a configuration described in FIG. 5 or later.

A buff processing liquid includes at least one of DIW (deionized water), a cleaning chemical liquid and a polishing liquid such as slurry. There are mainly two types of a way of the buff process. One is a way to remove a contamination such as slurry or a polishing product remaining on a wafer to be processed when contacting with a buff pad. The other is a way to remove a fixed amount of object to which the above contamination adheres. In the former way, a buff processing liquid is preferably a cleaning chemical liquid or DIW. In the latter way, a buff processing liquid is preferably a polishing liquid. However, in the latter way, the removal amount in the process is preferably lower than 10 nm, for example, and preferably lower than 5 nm in order to maintain the state (the flatness or the remaining film amount) of the processed surface after CMP. In this case, a removal speed does not need to be as high as that in ordinary CMP. In this case, a processing speed may be adjusted by performing, for example, a dilution process to the polishing liquid as appropriate. The buff pad 502 is formed of a foamed-polyurethane hard pad, a suede soft pad, or a sponge, for example. The types of the buff pad may be selected as appropriate depending on the material of an object or a condition of a contamination to be removed. For example, when a contamination is buried in a surface of an object, a hard pad that more easily applies a physical force to the contamination, that is, a pad with high hardness and rigidity may be used as a buff pad. On the other hand, for example, when an object is formed of a material with small mechanical strength such as a Low-k film, a soft pad may be used in order to reduce damage on a processing target surface. When the buff processing liquid is a polishing liquid such as slurry, a removal speed of an object, a removal efficiency of contaminations, presence or absence of a damage are not determined only by hardness and rigidity of the buff pad and may be selected as appropriate. On the surface of the buff pad, a groove shape such as a concentric groove, an XY groove, a swirl groove, and a radial groove, for example, may be formed. Further, the buff pad may have at least one hole penetrating the buff pad and a buff processing liquid may be supplied through this hole. Moreover, the buff pad may be formed of a spongy material into which a buff processing liquid can infiltrate, for example, a PVA sponge. Accordingly, flow distribution of a buff processing liquid in the buff pad plane can be unified and a removed contamination in the buff process can be promptly discharged.

The buff table 400 has a mechanism for adsorbing the wafer W. The buff table 400 is rotatable around a rotation shaft A by a non-illustrated driving mechanism. The buff table 400 may cause angle rotating motion or scroll motion of the wafer W by a non-illustrated driving mechanism. The buff pad 502 is attached to a surface of the buff head 500 opposite to the wafer W. The buff head 500 is rotatable around a rotation shaft B by a non-illustrated driving mechanism. The buff head 500 can press the buff pad 502 against a processing target surface of the wafer W with a non-illustrated driving mechanism. The buff arm 600 can move the buff head 500 within a radius or a diameter of the wafer W, as shown by an arrow C. The buff arm 600 can swing the buff head 500 to a position where the buff pad 502 faces the conditioning unit 800.

The conditioning unit 800 is a member for performing conditioning of a surface of the buff pad 502. The conditioning unit 800 includes a dressing table 810 and a dresser 820 that is placed on the dressing table 810. The dressing table 810 is rotatable around a rotation shaft D by a non-illustrated driving mechanism. The dressing table 810 may cause scroll motion of the dresser 820 by a non-illustrated driving mechanism. The dresser 820 is formed of a diamond dresser that has a surface on which diamond particles are electrodeposited and fixed or has all or part of a contact surface with the buff pad on which diamond abrasive grains are arranged, a brush dresser that has all or part of the contact surface with the buff pad on which resin-made bristles are arranged, or a combination thereof.

In conditioning of the buff pad 502, the upper buff processing module 300A turns the buff arm 600 to a position where the buff pad 502 becomes opposite to the dresser 820. The upper buff processing module 300A rotates the dressing table 810 around the rotation shaft D, rotates the buff head 500, and presses the buff pad 502 against the dresser 820 to perform conditioning of the buff pad 502. The conditioning condition is a conditioning load of 80 N or less. The conditioning load of 40 N or less is preferable in view of the buff pad life. The buff pad 502 and the dresser 820 are preferably used with the rotation speed of 500 rpm or less. In the preset embodiment, the processing target surface of the wafer W and the dressing surface of the dresser 820 are arranged along a horizontal direction, but are not limited to this. For example, the upper buff processing module 300A may place the buff table 400 and the dressing table 810 in such a way that the processing target surface of the wafer W and the dressing surface of the dresser 820 are arranged in a vertical direction. In this case, the buff arm 600 and the buff head 500 are arranged so as to perform the buff process with the buff pad 502 in contact with the vertically arranged processing target surface of the wafer W, and perform the conditioning process with the buff pad 502 in contact with the vertically arranged dressing surface of the dresser 820. Further, either the buff table 400 or the dressing table 810 may be arranged in the vertical direction and the whole or part of the buff arm 600 may rotate in such a way that the buff pad 502 placed on the buff arm 600 becomes perpendicular to the table surfaces.

The liquid supplying system 700 includes a deionized-water nozzle 710 for supplying deionized water (DIW) to the processing target surface of the wafer W. The deionized-water nozzle 710 is connected to a deionized-water supplying source 714 via a deionized-water pipe 712. The deionized-water pipe 712 is provided with an opening and closing valve 716 that can open and close the deionized-water pipe 712. The control device 5 controls opening/closing of the opening and closing valve 716 to supply deionized water to the processing target surface of the wafer W at an arbitrary timing.

Further, the liquid supplying system 700 includes a chemical-liquid nozzle 720 for supplying chemical liquid (Chemi) to the processing target surface of the wafer W. The chemical-liquid nozzle 720 is connected to a chemical-liquid supplying source 724 via a chemical-liquid pipe 722. The chemical-liquid pipe 722 is provided with an opening and closing valve 726 that can open and close the chemical-liquid pipe 722. The control device 5 controls opening/closing of the opening and closing valve 726 to supply chemical liquid to the processing target surface of the wafer W at an arbitrary timing.

The upper buff processing module 300A can selectively supply deionized water, chemical liquid or a polishing liquid such as slurry to the processing target surface of the wafer W, via the buff arm 600, the buff head 500, and the buff pad 502.

That is, a branch deionized-water pipe 712a is branched from the deionized-water pipe 712 at a point between the deionized-water supplying source 714 and the opening and closing valve 716. A branch chemical-liquid pipe 722a is branched from the chemical-liquid pipe 722 at a point between the chemical-liquid supplying source 724 and the opening and closing valve 726. The branch deionized-water pipe 712a, the branch chemical-liquid pipe 722a, and a polishing-liquid pipe 732, which is connected to a chemical-liquid supplying source 734, join a liquid supplying pipe 740. The branch deionized-water pipe 712a is provided with an opening and closing valve 718 that can open and close the branch deionized-water pipe 712a. The branch chemical-liquid pipe 722a is provided with an opening and closing valve 728 that can open and close the branch chemical-liquid pipe 722a. The polishing-liquid pipe 732 is provided with an opening and closing valve 736 that can open and close the polishing-liquid pipe 732.

A first end of the liquid supplying pipe 740 is connected to three system pipes that are the branch deionized-water pipe 712a, the branch chemical-liquid pipe 722a, and the polishing-liquid pipe 732. The liquid supplying pipe 740 extends through the inside of the buff arm 600, the center of the buff head 500, and the center of the buff pad 502. A second end of the liquid supplying pipe 740 opens to the processing target surface of the wafer W. The control device 5 controls opening/closing of the opening and closing valve 718, the opening and closing valve 728 and the opening and closing valve 736 to supply the surface of the wafer W with one of deionized water, a chemical liquid, a polishing liquid such as slurry, or a combined liquid of an arbitrary combination of them at an arbitrary timing.

The upper buff processing module 300A supplies a processing liquid to the wafer W through the liquid supplying pipe 740, rotates the buff table 400 around the rotation shaft A, presses the buff pad 502 against the processing target surface of the wafer W, and rotates the buff head 500 around the rotation shaft B to swing the buff head 500 in a direction of the arrow C so that a buff process can be performed to the wafer W. The buff process condition is a pressure of 3 psi or less, preferably 2 psi or less, considering damage reduction of the wafer W, although the buff process is basically to remove defects by mechanical action. The rotation speed of the wafer W and the buff head 500 is preferably 1000 rpm or less, considering in-plane distribution of a buff processing liquid. The moving speed of the buff head 500 is 300 mm/sec or less. However, an appropriate distribution of the moving speed differs depending on the rotation speed of the wafer W and the buff head 500 and the moving distance of the buff head 500. Accordingly, the moving speed of the buff head 500 in the wafer-W plane is preferably variable. A varying manner of the moving speed in this case is preferably a manner in which the swinging distance in the wafer-W plane is divided into a plurality of sections and the moving speed is set for each section, for example. The flow amount of the buff processing liquid is preferably large to keep the sufficient in-plane distribution of the processing liquid on the wafer even when the wafer W and the buff head 500 rotate at a high speed. However, increase in the flow amount of the processing liquid causes increases in the processing cost. The flow amount is 1000 ml/min or less, and is preferably 500 ml/min or less.

The buff process here includes at least one of a buff polishing process and a buff cleaning process.

The buff polishing process is a process of moving the wafer W relatively to the buff pad 502 while keeping the buff pad 502 in contact with the wafer W, interposing a polishing liquid such as slurry between the wafer W and the buff pad 502 to perform polishing and removing to the processing target surface of the wafer W. In the buff polishing process, a physical acting force that is larger than the physical acting force applied to the wafer W by the roll sponge in the roll cleaning chamber 190 or the physical acting force applied to the wafer W by the pen sponge in the pen cleaning chamber 192 can be applied to the wafer W. Through the buff polishing process, a surface layer part with a contamination can be removed, a part that the polishing unit 3 has failed to remove in main polishing can be additionally removed, or the morphology after the main polishing can be improved.

The buff cleaning process is a process of moving the wafer W relatively to the buff pad 502 while keeping the buff pad 502 in contact with the wafer W, interposing a cleaning processing liquid (a chemical liquid, or a chemical liquid and deionized water) between the wafer W and the buff pad 502 to remove a contamination on the surface of the wafer W or reform the processing target surface. In the buff cleaning process, a physical acting force that is larger than the physical acting force applied to the wafer W by the roll sponge in the roll cleaning chamber 190 or the physical acting force applied to the wafer W by the pen sponge in the pen cleaning chamber 192 can be applied to the wafer W.

<Buff Processing Component>

### First Embodiment

Next, the buff processing component 350 will be described in detail. FIG. 5 is a diagram schematically illustrating a buff processing component of a first embodiment. Hereinafter, a buff processing component in the upper buff processing module 300A will be described, but no limitation is placed to the description. That is, the following embodiments can be applied to a processing component including a head to which a pad contacting with an object and moving relatively to the object for performing a predetermined process to the object is attached to, and an arm that holds the head.

As illustrated in FIG. 5, the buff processing component 350 of the first embodiment includes a first buff arm 600-1 and a second buff arm 600-2 that is different from the first buff arm 600-1. More specifically, the first buff arm 600-1 extends along a wafer-W placing surface of the buff table 400 and is rotatable around a shaft 610-1 outside the buff table 400 and along the wafer-W placing surface of the buff table 400. The second buff arm 600-2 extends along the wafer-W placing surface of the buff table 400 and is rotatable around a shaft 610-2 outside the buff table 400 and along the wafer-W placing surface of the buff table 400.

The buff processing component 350 includes a first buff head 500-1 to which a first buff pad 502-1 having a smaller diameter than the wafer W is attached. Further, the buff processing component 350 includes a second buff head 500-2 to which the second buff pad 502-2 having a smaller diameter than the first buff pad 502-1 is attached, differing from the first buff head 500-1.

The first buff head 500-1 is held by an end 620-1 of the first buff arm 600-1 opposite to the shaft 610-1. The second buff head 500-2 is held by an end 620-2 of the second buff arm 600-2 opposite to the shaft 610-2.

The first buff arm 600-1 and the second buff arm 600-2 are movable horizontally along the processing target surface of the wafer W. For example, when the buff process is performed, the first buff arm 600-1 is swingable between a center part and a peripheral edge part of the wafer W while keeping the first buff pad 502-1 in contact with the wafer W. Also, when the buff process is performed, the second buff arm 600-2 is movable horizontally on the peripheral edge part of the wafer W while keeping the second buff pad 502-2 in contact with the wafer W.

As illustrated in FIG. 5, to perform conditioning of the first buff pad 502-1, the first buff arm 600-1 is movable horizontally between a first dresser 820-1 and the wafer W. Similarly, to perform conditioning of the second buff pad 502-2, the second buff arm 600-2 is movable horizontally between a second dresser 820-2 and the wafer W.

As illustrated in FIG. 5, the first buff head 500-1 is held by the first buff arm 600-1 in such a way that the first buff pad 502-1 contacts with the center part of the wafer W when moving horizontally. The second buff head 500-2 is held by the second buff arm 600-2 in such a way that the second buff pad 502-2 contacts with the peripheral edge part of the wafer W when moving horizontally. The types of the horizontal movement include linear motion and circular arc motion. Examples of the movement direction include one-direction movement from the center side to the peripheral edge part of the wafer W or vice versa, and reciprocating movement within the wafer radius or diameter with the center or peripheral edge side of the wafer W as a starting point. In the horizontal movement, the moving speed of each buff arm may be variable within a movement range. The reason for this is that distribution of a staying time of the buff pad has an influence on distribution of a processing speed of the wafer W. A varying manner of the moving speed in this case is preferably a manner in which the swinging distance in the wafer-W plane is divided into a plurality of sections and the moving speed is set for each section, for example.

The first buff pad 502-1 and the second buff pad 502-2 each have a smaller diameter than the wafer W. For example, when the wafer W is Φ 300 mm, each of the first buff pad 502-1 and the second buff pad 502-2 is preferably Φ 100 mm or less, and more preferably, Φ 60 to 100 mm. The reason for this is that the buff processing speed of the wafer increases because as the diameter of the buff pad increases, an area ratio to the wafer decreases. On the contrary, as the diameter of the buff pad decreases, the in-plane uniformity of the wafer W increases. The reason for this is that a processed area per unit becomes smaller. Therefore, in the present embodiment, in addition to the first buff pad 502-1, the second buff 502-2 pad having a smaller diameter than the first buff pad 502-1 is used. The types and materials of the first buff pad 502-1 and the second buff pad 502-2 do not need to be same and the first buff pad 502-1 and the second buff pad 502-2 of different types and materials may be arranged. Depending on the types, materials and the pad diameters of the respective buff pads, the first dresser 820-1 and the second dresser 820-2 of different types may be arranged.

According to the present embodiment, the buff processing component 350 can perform the buff process by using the plurality of buff pads (the first buff pad 502-1 and the second buff pad 502-2). The buff processing component 350 can perform the buff process by using the first buff pad 502-1 and the second buff pad 502-2 simultaneously, for example. The buff processing component 350 can perform the buff process with alternately conditioning of the first buff pad 502-1 and the second buff pad 502-2 by the dressers 820-1 and 820-2, respectively. In any case, a contact area of the buff pad with the wafer W in the buff process increases, and thus, the buff processing component 350 in the present embodiment can improve the processing rate in the buff process.

In addition, according to the present embodiment, the buff pads having different sizes (the first buff pad 502-1 and the second buff pad 502-2) can be used to perform the buff process. Accordingly, for example, the buff processing component 350 uses the first buff pad 502-1 to buff an area other than the peripheral edge part of the wafer W mainly, and uses the second buff pad 502-2 having a smaller diameter than the first buff pad 502-1 to buff the peripheral edge part of the wafer W mainly. As a result, the buff processing component 350 in the present embodiment can improve the in-plane uniformity of the wafer W.

### Second Embodiment

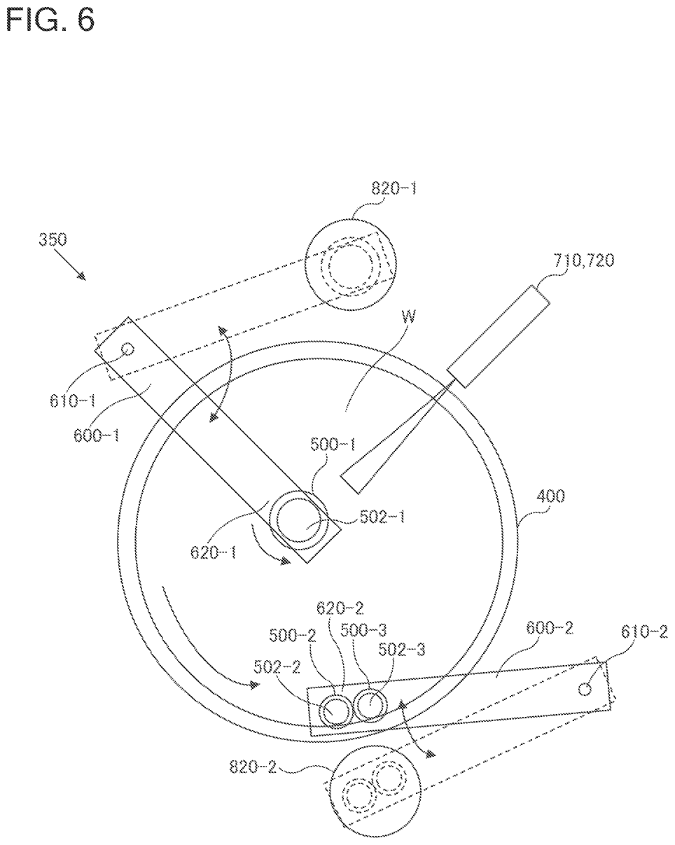

Next, the buff processing component 350 of a second embodiment will be described. FIG. 6 is a diagram illustrating a schematic configuration of a buff processing component of the second embodiment.

As illustrated in FIG. 6, the buff processing component 350 of the second embodiment includes a first buff arm 600-1 and a second buff arm 600-2 that is different from the first buff arm 600-1. More specifically, the first buff arm 600-1 extends along a wafer-W placing surface of the buff table 400 and is rotatable around a shaft 610-1 outside the buff table 400 and along the wafer-W placing surface of the buff table 400. The second buff arm 600-2 extends along the wafer-W placing surface of the buff table 400 and is rotatable around a shaft 610-2 outside the buff table 400 and along the wafer-W placing surface of the buff table 400.

The buff processing component 350 includes the first buff head 500-1 to which the first buff pad 502-1 having a smaller diameter than the wafer W is attached. Further, the processing component 350 includes the second buff head 500-2 and a third buff head 500-3 to which a plurality of the second buff pads 502-2 and a plurality of third buff pads 502-3 each having a smaller diameter than the first buff pad 502-1 are attached, respectively, and each differ from the first buff pad 502-1.

The first buff head 500-1 is held by an end 620-1 of the first buff arm 600-1 opposite to the shaft 610-1. The second buff head 500-2 and the third buff head 500-3 are held by an end 620-2 of the second buff arm 600-2 opposite to the shaft 610-2.

The first buff arm 600-1 and the second buff arm 600-2 are movable horizontally along the processing target surface of the wafer W. For example, when the buff process is performed, the first buff arm 600-1 is movable horizontally between a center part and a peripheral edge part of the wafer W while keeping the first buff pad 502-1 in contact with the wafer W. Also, when the buff process is performed, the second buff arm 600-2 is movable horizontally on the peripheral edge part of the wafer W while keeping the second buff pad 502-2 and the third buff pad 502-3 in contact with the wafer W.

As illustrated in FIG. 6, to perform conditioning of the first buff pad 502-1, the first buff arm 600-1 is movable horizontally between a first dresser 820-1 and the wafer W. Similarly, to perform conditioning of the second buff pad 502-2 and the third buff pad 502-3, the second buff arm 600-2 is movable horizontally between a second dresser 820-2 and the wafer W.

As illustrated in FIG. 6, the first buff head 500-1 is held by the first buff arm 600-1 in such a way that the first buff pad 502-1 contacts with the center part of the wafer W when moving horizontally. The second buff head 500-2 and the third buff head 500-3 are held by the second buff arm 600-2 in such a way that the second buff pads 502-2 and the third buff pads 502-3 contact with the peripheral edge part of the wafer W when moving horizontally.

The second buff pad 502-2 and the third buff pad 502-3 are held by the second buff arm 600-2 in such a way that the second buff pads 502-2 and the third buff pads 502-3 are adjacent along the direction of the peripheral edge direction of the wafer W and contact with the peripheral edge part of the wafer W. The types of the horizontal movement include linear motion and circular arc motion. Examples of the movement direction include one-direction movement from the center side to the peripheral edge part of the wafer W or vice versa, and reciprocating movement within the wafer radius or diameter with the center or peripheral edge side of the wafer W as a starting point. In the horizontal movement, the moving speed of each buff arm may be variable within a movement range. The reason for this is that distribution of a staying time of the buff pads has an influence on distribution of a processing speed of the wafer W. A varying manner of the moving speed in this case is preferably a manner in which the swinging distance in the wafer-W plane is divided into a plurality of sections and the moving speed is set for each section, for example.

The first buff pad 502-1, the second buff pad 502-2, and the third buff pad 502-3 each have a smaller diameter than the wafer W. For example, when the wafer W is Φ 300 mm, the first buff pad 502-1 is preferably Φ 100 mm or less, and more preferably, Φ 60 to 100 mm. The reason for this is that the buff processing speed of the wafer increases because as the diameter of the buff pad increases, an area ratio to the wafer decreases. On the contrary, as the diameter of the buff pad decreases, the in-plane uniformity of the wafer W increases. The reason for this is that a processed area per unit becomes smaller. Therefore, in the present embodiment, in addition to the first buff pad 502-1, the second buff pads 502-2 and the third buff pads 502-3 each having a smaller diameter than the first buff pad 502-1 are used. The second buff pad 502-2 and the third buff pad 502-3 may have a same pad diameter. Alternatively, one of the second buff pad 502-2 and the third buff pad 502-3 may have a smaller buff-pad diameter than the other in order to obtain the in-plane uniformity of the processing speed to the further outer circumference. The types and materials of the first buff pad 502-1, the second buff pads 502-2, and the third buff pads 502-3 do not need to be same and the first buff pad 502-1, the second buff pads 502-2, and the third buff pads 502-3 of different types and materials may be arranged. Depending on the types, materials and the pad diameters of the respective buff pads, the first dresser 820-1 and the second dresser 820-2 of different types may be arranged. In this case, unlike in FIG. 6, the buff pads have the respective dressers.

According to the present embodiment, the buff processing component 350 can perform the buff process by using the plurality of buff pads (the first buff pad 502-1, the second buff pad 502-2 and the third buff pad 502-3). The buff processing component 350 can perform the buff process by using the first buff pad 502-1, the second buff pad 502-2 and the third buff pad 502-3 simultaneously, for example. The buff processing component 350 can perform the buff process with alternately conditioning of the first buff pad 502-1, the second buff pad 502-2 and the third buff pad 502-3 by the dressers 820-1 and 820-2, respectively. In any case, a contact area of the buff pad with the wafer W in the buff process increases, and thus, the buff processing component 350 in the present embodiment can improve the processing rate in the buff process.

In addition, according to the present embodiment, the buff pads having different sizes (the first buff pad 502-1, the second buff pads 502-2 and the third buff pads 502-3) can be used to perform the buff process. Accordingly, for example, the buff processing component 350 uses the first buff pad 502-1 to buff an area other than the peripheral edge part of the wafer W mainly, and uses the second buff pads 502-2 and the third buff pads 502-3 to buff the peripheral edge part of the wafer W mainly. As a result, the buff processing component 350 in the present embodiment can improve the in-plane uniformity of the wafer W. Furthermore, according to the present embodiment, the buff process can be performed using the second buff pads 502-2 and the third buff pads 502-3 adjacent to each other along the direction of the peripheral edge part of the wafer W, and thus, the processing rate at the peripheral edge part can be improved.

### Third Embodiment

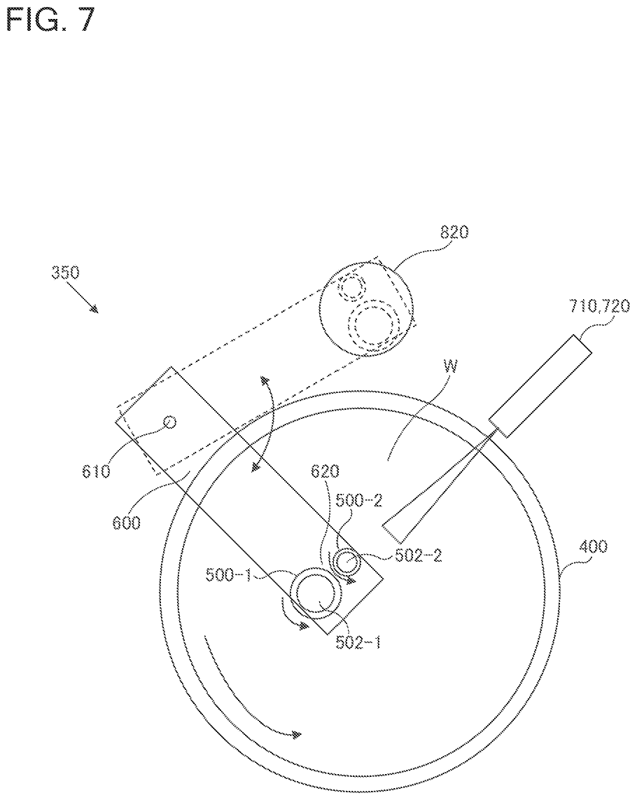

Next, the buff processing component 350 of a third embodiment will be described. FIG. 7 is a diagram illustrating a schematic configuration of a buff processing component of the third embodiment.

As illustrated in FIG. 7, the buff processing component 350 of the third embodiment includes the single buff arm 600. More specifically, the buff arm 600 extends along the wafer-W placing surface of the buff table 400 and is rotatable around a shaft 610 outside the buff table 400 and along the wafer-W placing surface of the buff table 400.

The buff processing component 350 includes a first buff head 500-1 to which a first buff pad 502-1 having a smaller diameter than the wafer W is attached. Further, the buff processing component 350 includes a second buff head 500-2 to which the second buff pad 502-2 having a smaller diameter than the first buff pad 502-1 is attached, differing from the first buff head 500-1.

The first buff head 500-1 and the second buff head 500-2 are held by an end 620 of the buff arm 600, opposite to the shaft 610.

The buff arm 600 is movable horizontally along the processing target surface of the wafer W. For example, when the buff process is performed, the buff arm 600 is movable horizontally between a center part and a peripheral edge part of the wafer W while keeping the first buff pad 502-1 and the second buff pad 502-2 in contact with the wafer W.

As illustrated in FIG. 7, to perform conditioning of the first buff pad 502-1 and the second buff pad 502-2, the buff arm 600 is movable horizontally between the dresser 820 and the wafer W.

The first buff head 500-1 and the second buff head 500-2 are held by the buff arm 600 in such a way that the first buff head 500-1 and the second buff head 500-2 are adjacent to each other along a direction of the horizontal movement of the buff arm 600. When the buff process is performed, the buff arm 600 moves horizontally between the center part and the peripheral edge part of the wafer W in a state the first buff pad 502-1 and the second buff pad 502-2 are in contact with the wafer W. As a result, the first buff head 500-1 is held by the buff arm 600 in such a way that the first buff pad 502-1 contacts with the center part of the wafer W. The second buff head 500-2 is held by the buff arm 600 in such a way that the second buff pad 502-2 contacts at least with the peripheral edge part of the wafer W. The types of the horizontal movement include linear motion and circular arc motion. Examples of the movement direction include one-direction movement from the center side to the peripheral edge part of the wafer W or vice versa, and reciprocating movement within the wafer radius or diameter with the center or peripheral edge side of the wafer W as a starting point. In the horizontal movement, the moving speed of each buff arm may be variable within a movement range. The reason for this is that distribution of a staying time of the buff pad has an influence on distribution of a processing speed of the wafer W. A varying manner of the moving speed in this case is preferably a manner in which the swinging distance in the wafer-W plane is divided into a plurality of sections and the moving speed is set for each section, for example.

The first buff pad 502-1 and the second buff pad 502-2 each have a smaller diameter than the wafer W. For example, when the wafer W is Φ 300 mm, the first buff pad 502-1 is preferably Φ 100 mm or less, and more preferably, Φ 60 to 100 mm. The reason for this is that the buff processing speed of the wafer increases because as the diameter of the buff pad increases, an area ratio to the wafer decreases. On the contrary, as the diameter of the buff pad decreases, the in-plane uniformity of the wafer W increases. The reason for this is that a processed area per unit becomes smaller. Therefore, in the present embodiment, in addition to the first buff pad 502-1, the second buff pad 502-2 having a smaller diameter than the first buff pad 502-1 is used. The types and materials of the first buff pad 502-1 and the second buff pad 502-2 do not need to be same and the first buff pad 502-1 and the second buff pad 502-2 of different types and materials may be arranged. Depending on the types, materials and the pad diameters of each buff pad, the dresser 820 of different types may be arranged. In this case, unlike in FIG. 7, the buff pads have the respective dressers.

According to the present embodiment, the buff processing component 350 can perform the buff process by using the plurality of buff pads (the first buff pad 502-1 and the second buff pad 502-2). The buff processing component 350 can perform the buff process by using the first buff pad 502-1 and the second buff pad 502-2 simultaneously, for example. Accordingly, a contact area of the buff pad with the wafer W in the buff process increases, and thus, the buff processing component 350 can improve the processing rate in the buff process.

In addition, according to the present embodiment, the buff pads having different sizes (the first buff pad 502-1 and the second buff pad 502-2) can be used to perform the buff process. Accordingly, for example, the buff processing component 350 uses the first buff pad 502-1 to buff an area other than the peripheral edge part of the wafer W mainly, and uses the second buff pad 502-2 having a smaller diameter than the first buff pad 502-1 to buff an area other than the center part of the wafer W, particularly the peripheral edge part. As a result, the buff processing component 350 in the present embodiment can improve the in-plane uniformity of the wafer W.

### Fourth Embodiment

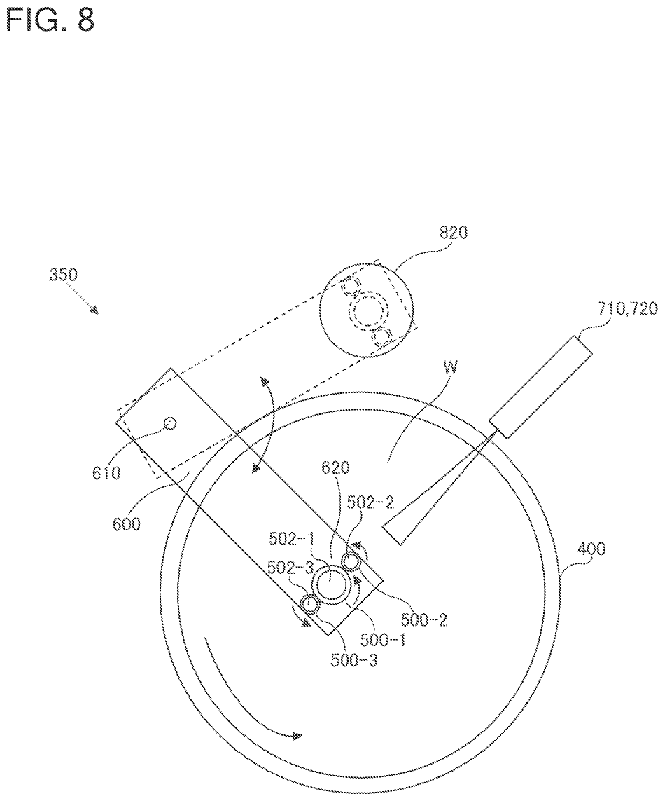

Next, the buff processing component 350 of a fourth embodiment will be described. FIG. 8 is a diagram illustrating a schematic configuration of a buff processing component of the fourth embodiment.

As illustrated in FIG. 8, the buff processing component 350 of the fourth embodiment includes the single buff arm 600. More specifically, the buff arm 600 extends along the wafer-W placing surface of the buff table 400 and is rotatable around a shaft 610 outside the buff table 400 and along the wafer-W placing surface of the buff table 400.

The buff processing component 350 includes a first buff head 500-1 to which a first buff pad 502-1 having a smaller diameter than the wafer W is attached. Further, the buff processing component 350 includes a second buff head 500-2 and a third buff head 500-3 to which the second buff pad 502-2 and the third buff pad 502-3 each having a smaller diameter than the first buff pad 502-1 are attached, differing from the first buff head 500-1.

The first buff head 500-1, the second buff head 500-2 and the third buff head 500-3 are held by an end 620 of the buff arm 600, opposite to the shaft 610.

The buff arm 600 is movable horizontally along the processing target surface of the wafer W. For example, when the buff process is performed, the buff arm 600 is movable horizontally between the opposite peripheral edge parts through the center part of the wafer W while keeping the first buff pad 502-1, the second buff pad 502-2 and the third buff pad 502-3 in contact with the wafer W.

As illustrated in FIG. 8, to perform conditioning of the first buff pad 502-1, the second buff pad 502-2 and the third buff pad 502-3, the buff arm 600 is movable horizontally between the dresser 820 and the wafer W.

The first buff head 500-1 is held by a center part of the buff arm 600 in the swinging direction. The second buff head 500-2 and the third buff head 500-3 are held by the buff arm 600 in such a way that the second buff head 500-2 and the third buff head 500-3 are adjacent to both sides of the first buff head 500-1 along the direction of the horizontal movement of the buff arm 600. When the buff process is performed, the buff arm 600 is movable horizontally between the opposite peripheral edge parts of the wafer W through the center part of the wafer W in a state the first buff pad 502-1 and the second buff pad 502-2 are in contact with the wafer W. As a result, the first buff head 500-1 is held by the buff arm 600 in such a way that the first buff pad 502-1 contacts with the center part of the wafer W. The second buff head 500-2 and the third buff head 500-3 are held by the buff arm 600 in such a way that the second buff pad 502-2 and the third buff pad 502-3 contact at least with the peripheral edge part of the wafer W. The types of the horizontal movement include linear motion and circular arc motion. Examples of the movement direction include one-direction movement from the center side to the peripheral edge part of the wafer W or vice versa, and reciprocating movement within the wafer radius or diameter with the center or peripheral edge side of the wafer W as a starting point. In the horizontal movement, the moving speed of the buff arm may be variable within a movement range. The reason for this is that distribution of a staying time of the buff pad has an influence on distribution of a processing speed of the wafer W. A varying manner of the moving speed in this case is preferably a manner in which the swinging distance in the wafer-W plane is divided into a plurality of sections and the moving speed is set for each section, for example.

The first buff pad 502-1, the second buff pad 502-2, and the third buff pad 502-3 each have a smaller diameter than the wafer W. For example, when the wafer W is Φ 300 mm, the first buff pad 502-1 is preferably Φ 100 mm or less, and more preferably, Φ 60 to 100 mm. The reason for this is that the buff processing speed of the wafer increases because as the diameter of the buff pad increases, an area ratio to the wafer decreases. On the contrary, as the diameter of the buff pad decreases, the in-plane uniformity of the wafer W increases. The reason for this is that a processed area per unit becomes smaller. Therefore, in the present embodiment, in addition to the first buff pad 502-1, the second buff pads 502-2 and the third buff pads 502-3 each having a smaller diameter than the first buff pad 502-1 are used. The second buff pad 502-2 and the third buff pad 502-3 may have a same pad diameter. Alternatively, one of the second buff pad 502-2 and the third buff pad 502-3 may have a smaller buff-pad diameter than the other in order to obtain the in-plane uniformity of the processing speed to the further outer circumference. The types and materials of the first buff pad 502-1, the second buff pads 502-2, and the third buff pads 502-3 do not need to be same and the first buff pad 502-1, the second buff pads 502-2, and the third buff pads 502-3 of different types and materials may be arranged. Depending on the types, materials and the pad diameters of the respective buff pads, the dresser 820 of different types may be arranged. In this case, unlike in FIG. 8, the buff pads have the respective dressers.

According to the present embodiment, the buff processing component 350 can perform the buff process by using the plurality of buff pads (the first buff pad 502-1, the second buff pad 502-2 and the third buff pad 502-3). The buff processing component 350 can perform the buff process by using the first buff pad 502-1, the second buff pad 502-2 and the third buff pad 502-3 simultaneously, for example. Accordingly, a contact area of the buff pad with the wafer W in the buff process increases, and thus, the buff processing component 350 in the present embodiment can improve the processing rate in the buff process.

In addition, according to the present embodiment, the buff pads having different sizes (the first buff pad 502-1, the second buff pad 502-2 and the third buff pad 502-3) can be used to perform the buff process. Accordingly, for example, the buff processing component 350 uses the first buff pad 502-1 to buff an area other than the peripheral edge part of the wafer W mainly, and uses the second buff pad 502-2 and the third buff pad 502-3 having a smaller diameter than the first buff pad 502-1 to buff the peripheral edge part of the wafer W mainly. As a result, the buff processing component 350 in the present embodiment can improve the in-plane uniformity of the wafer W. Furthermore, according to the present embodiment, the second buff pad 502-2 and the third buff pad 502-3 are arranged at both sides of the first buff pad 502-1 along the swinging direction of buff arm 600. As a result, the buff process can be performed to the peripheral edge part of the wafer W using the second buff pad 502-2 and the third buff pad 502-3, and thus, the processing rate at the peripheral edge part can be improved.

### Fifth Embodiment

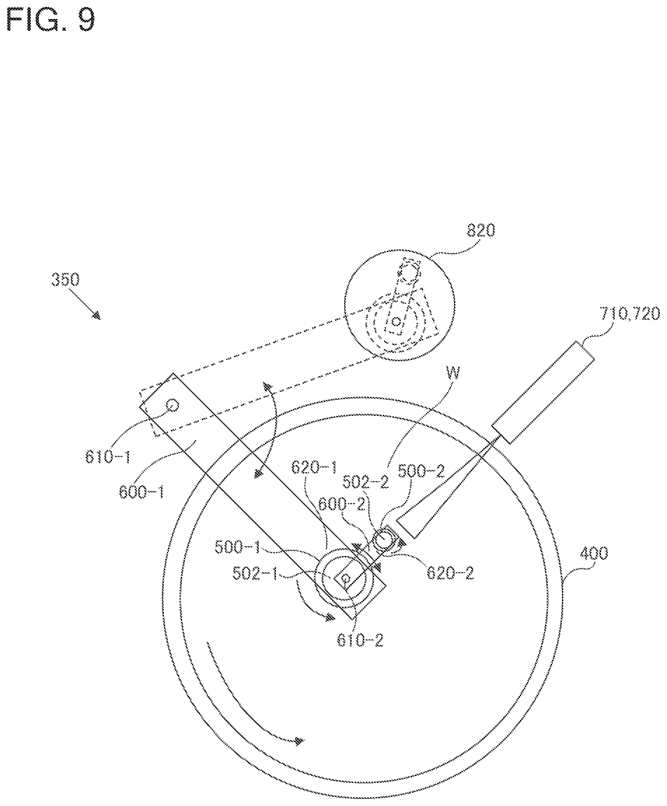

Next, the buff processing component 350 of a fifth embodiment will be described. FIG. 9 is a diagram illustrating a schematic configuration of a buff processing component of the fifth embodiment.

As illustrated in FIG. 9, the buff processing component 350 of a fifth embodiment includes the first buff arm 600-1 and the second buff arm 600-2 that is coupled with the first buff arm 600-1. More specifically, the first buff arm 600-1 extends along the wafer-W placing surface of the buff table 400 and is rotatable around the shaft 610-1 outside the buff table 400 and along the wafer-W placing surface of the buff table 400. The second buff arm 600-2 extends along the wafer-W placing surface of the buff table 400 and is rotatable around the shaft 610-2 of the first buff arm 600-1 that is provided at the end 620-1 opposite to the shaft 610-1 and along the wafer-W placing surface of the buff table 400.

The buff processing component 350 includes a first buff head 500-1 to which a first buff pad 502-1 having a smaller diameter than the wafer W is attached. Further, the buff processing component 350 includes a second buff head 500-2 to which the second buff pad 502-2 having a smaller diameter than the first buff pad 502-1 is attached, differing from the first buff head 500-1.

The first buff head 500-1 is held by an end 620 of the first buff arm 600-1 opposite to the shaft 610-1. The second buff head 500-2 is held by an end 620-2 of the second buff arm 600-2 opposite to the shaft 610-2.

The first buff arm 600-1 and the second buff arm 600-2 are movable horizontally along the processing target surface of the wafer W. For example, when the buff process is performed, the first buff arm 600-1 is movable horizontally between a center part and a peripheral edge part of the wafer W while keeping the first buff pad 502-1 in contact with the wafer W. Also, when the buff process is performed, the second buff arm 600-2 is movable horizontally at least on the peripheral edge part of the wafer W while keeping the second buff pad 502-2 in contact with the wafer W.

As illustrated in FIG. 9, to perform conditioning of the first buff pad 502-1 and the second buff pad 502-2, the first buff arm 600-1 is movable horizontally between the dresser 820 and the wafer W.

As illustrated in FIG. 9, the first buff head 500-1 is held by the first buff arm 600-1 in such a way that the first buff pad 502-1 contacts with the center part of the wafer W when moving horizontally. The second buff head 500-2 is held by the second buff arm 600-2 in such a way that the second buff pad 502-2 contacts with the peripheral edge part of the wafer W when moving horizontally. The types of the horizontal movement include linear motion and circular arc motion. Examples of the movement direction include one-direction movement from the center side to the peripheral edge part of the wafer W or vice versa, and reciprocating movement within the wafer radius or diameter with the center or peripheral edge side of the wafer W as a starting point. In the horizontal movement, the moving speed of each buff arm may be variable within a movement range. The reason for this is that distribution of a staying time of the buff pad has an influence on distribution of a processing speed of the wafer W. A varying manner of the moving speed in this case is preferably a manner in which the swinging distance in the wafer-W plane is divided into a plurality of sections and the moving speed is set for each section, for example.

The first buff pad 502-1 and the second buff pad 502-2 each have a smaller diameter than the wafer W. For example, when the wafer W is Φ 300 mm, the first buff pad 502-1 is preferably Φ 100 mm or less, and more preferably, Φ 60 to 100 mm. The reason for this is that the buff processing speed of the wafer increases because as the diameter of the buff pad increases, an area ratio to the wafer decreases. On the contrary, as the diameter of the buff pad decreases, the in-plane uniformity of the wafer W increases. The reason for this is that a processed area per unit becomes smaller. Therefore, in the present embodiment, in addition to the first buff pad 502-1, the second buff pad 502-2 having a smaller diameter than the first buff pad 502-1 is used. The types and materials of the first buff pad 502-1 and the second buff pad 502-2 do not need to be same and the first buff pad 502-1 and the second buff pad 502-2 of different types and materials may be arranged. Depending on the types, materials and the pad diameters of each buff pad, the dresser 820 of different types may be arranged. In this case, unlike in FIG. 9, the buff pads have the respective dressers.

According to the present embodiment, the buff processing component 350 can perform the buff process by using the plurality of buff pads (the first buff pad 502-1 and the second buff pad 502-2). The buff processing component 350 can perform the buff process by using the first buff pad 502-1 and the second buff pad 502-2 simultaneously, for example. Accordingly, a contact area of the buff pad with the wafer W in the buff process increases, and thus, the buff processing component 350 in the present embodiment can improve the processing rate in the buff process.

In addition, according to the present embodiment, the buff pads having different sizes (the first buff pad 502-1 and the second buff pads 502-2) can be used to perform the buff process. Accordingly, for example, the buff processing component 350 uses the first buff pad 502-1 to buff an area other than the peripheral edge part of the wafer W mainly, and uses the second buff pads 502-2 and the third buff pads 502-3 to buff the peripheral edge part of the wafer W mainly. As a result, the buff processing component 350 in the present embodiment can improve the in-plane uniformity of the wafer W.

### Sixth Embodiment

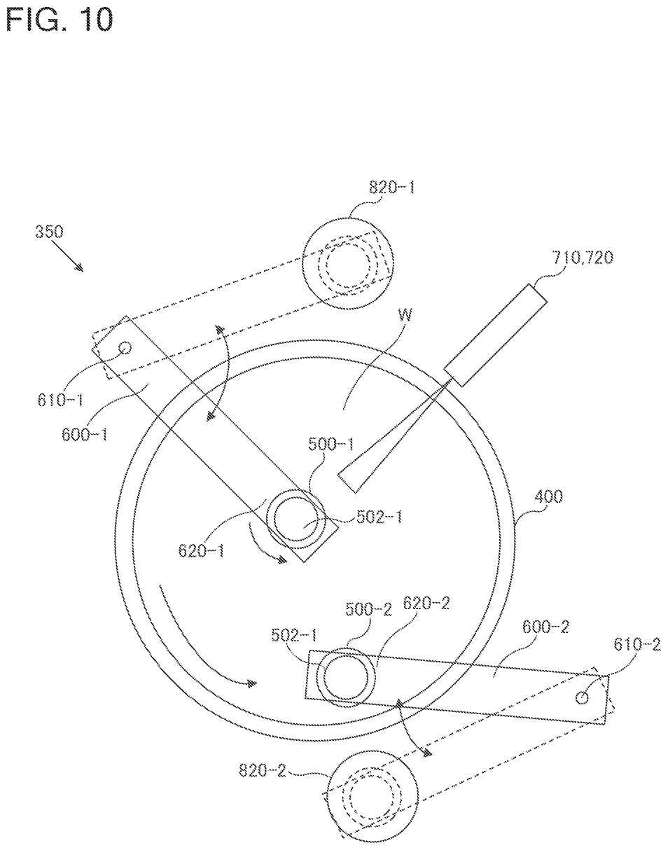

Next, the buff processing component 350 of a sixth embodiment will be described. FIG. 10 is a diagram illustrating a schematic configuration of a buff processing component of the sixth embodiment.

As illustrated in FIG. 10, the buff processing component 350 of the sixth embodiment includes a first buff arm 600-1 and a second buff arm 600-2 that is different from the first buff arm 600-1. More specifically, the first buff arm 600-1 extends along a wafer-W placing surface of the buff table 400 and is rotatable around a shaft 610-1 outside the buff table 400 and along the wafer-W placing surface of the buff table 400. The second buff arm 600-2 extends along the wafer-W placing surface of the buff table 400 and is rotatable around a shaft 610-2 outside the buff table 400 and along the wafer-W placing surface of the buff table 400.

The buff processing component 350 includes a first buff head 500-1 to which a first buff pad 502-1 having a smaller diameter than the wafer W is attached. Further, the buff processing component 350 includes a second buff head 500-2 to which the second buff pad 502-2 having a smaller diameter than the wafer W is attached, differing from the first buff head 500-1.

The first buff head 500-1 is held by an end 620-1 of the first buff arm 600-1 opposite to the shaft 610-1. The second buff head 500-2 is held by an end 620-2 of the second buff arm 600-2 opposite to the shaft 610-2.

The first buff arm 600-1 and the second buff arm 600-2 are movable horizontally along the processing target surface of the wafer W. For example, when the buff process is performed, the first buff arm 600-1 is movable horizontally between the center part and the peripheral edge part of the wafer W while keeping the first buff pad 502-1 in contact with the wafer W. Also, when the buff process is performed, the second buff arm 600-2 is movable horizontally between the center part and the peripheral edge part of the wafer W while keeping the second buff pad 502-2 in contact with the wafer W.

As illustrated in FIG. 10, to perform conditioning of the first buff pad 502-1, the first buff arm 600-1 is movable horizontally between the first dresser 820-1 and the wafer W. Similarly, to perform conditioning of the second buff pad 502-2, the second buff arm 600-2 is movable horizontally between the second dresser 820-2 and the wafer W. The types of the horizontal movement include linear motion and circular arc motion. Examples of the movement direction include one-direction movement from the center side to the peripheral edge part of the wafer W or vice versa, and reciprocating movement within the wafer radius or diameter with the center or peripheral edge side of the wafer W as a starting point. In the horizontal movement, the moving speed of each buff arm may be variable within a movement range. The reason for this is that distribution of a staying time of the buff pad has an influence on distribution of a processing speed of the wafer W. A varying manner of the moving speed in this case is preferably a manner in which the swinging distance in the wafer-W plane is divided into a plurality of sections and the moving speed is set for each section, for example.

The first buff pad 502-1 and the second buff pad 502-2 each have a smaller diameter than the wafer W. For example, when the wafer W is Φ 300 mm, each of the first buff pad 502-1 and the second buff pad 502-2 is preferably Φ 100 mm or less, and more preferably, Φ 60 to 100 mm. The reason for this is that the buff processing speed of the wafer increases because as the diameter of the buff pad increases, an area ratio to the wafer decreases. The types and materials of the first buff pad 502-1 and the second buff pad 502-2 do not need to be same and the first buff pad 502-1 and the second buff pad 502-2 of different types and materials may be arranged. Depending on the types, materials and the pad diameters of the respective buff pads, the first dresser 820-1 and the second dresser 820-2 of different types may be arranged.

According to the present embodiment, the buff processing component 350 can perform the buff process by using the plurality of buff pads (the first buff pad 502-1 and the second buff pad 502-2). The buff processing component 350 can perform the buff process by using the first buff pad 502-1 and the second buff pad 502-2 simultaneously, for example. The buff processing component 350 can perform the buff process with alternately conditioning of the first buff pad 502-1 and the second buff pad 502-2 by the dressers 820-1 and 820-2, respectively. In any case, a contact area of the buff pad with the wafer W in the buff process increases, and thus, the buff processing component 350 in the present embodiment can improve the processing rate in the buff process.

### Seventh Embodiment

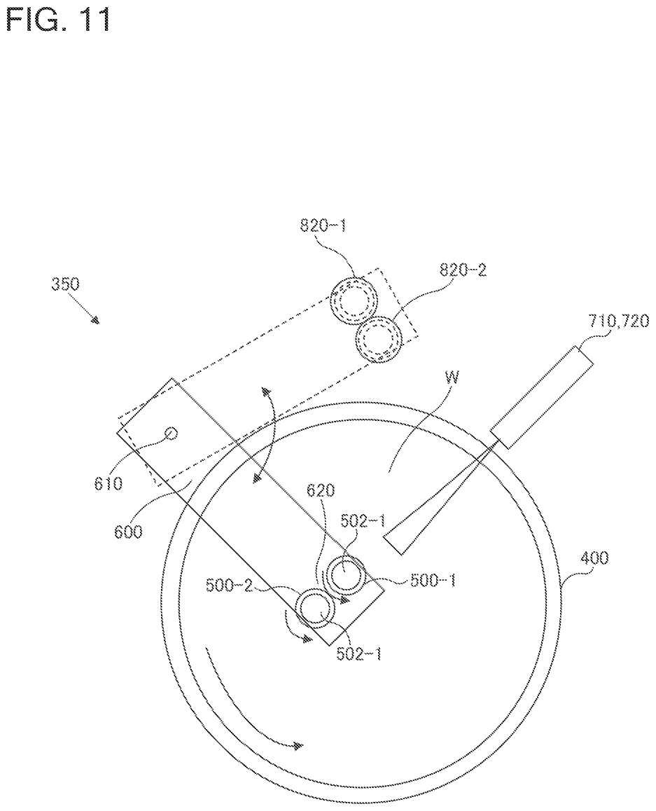

Next, the buff processing component 350 of a seventh embodiment will be described. FIG. 11 is a diagram illustrating a schematic configuration of a buff processing component of the seventh embodiment.

As illustrated in FIG. 11, the buff processing component 350 of the seventh embodiment includes the single buff arm 600. More specifically, the buff arm 600 is rotatable around the shaft 610 outside the buff table 400 and extends along the wafer-W placing surface of the buff table 400.

The buff processing component 350 includes a first buff head 500-1 to which a first buff pad 502-1 having a smaller diameter than the wafer W is attached. Further, the buff processing component 350 includes a second buff head 500-2 to which the second buff pad 502-2 having a smaller diameter than the wafer W is attached, differing from the first buff head 500-1.

The first buff head 500-1 and the second buff head 500-2 are held by an end 620 of the buff arm 600, opposite to the shaft 610.

The buff arm 600 is movable horizontally along the processing target surface of the wafer W. For example, when the buff process is performed, the buff arm 600 is movable horizontally between a center part and a peripheral edge part of the wafer W while keeping the first buff pad 502-1 and the second buff pad 502-2 in contact with the wafer W.

As illustrated in FIG. 11, to perform conditioning of the first buff pad 502-1 and the second buff pad 502-2, the buff arm 600 is movable horizontally between the dressers 820-1 and 820-2 and the wafer W.

The first buff head 500-1 and the second buff head 500-2 are held by the buff arm 600 in such a way that the first buff head 500-1 and the second buff head 500-2 are adjacent to each other along a swinging direction of the buff arm 600. When the buff process is performed, the buff arm 600 moves horizontally between the center part and the peripheral edge part of the wafer W in a state the first buff pad 502-1 and the second buff pad 502-2 are in contact with the wafer W. The types of the horizontal movement include linear motion and circular arc motion. Examples of the movement direction include one-direction movement from the center side to the peripheral edge part of the wafer W or vice versa, and reciprocating movement within the wafer radius or diameter with the center or peripheral edge side of the wafer W as a starting point. In the horizontal movement, the moving speed of each buff arm may be variable within a movement range. The reason for this is that distribution of a staying time of the buff pad has an influence on distribution of a processing speed of the wafer W. A varying manner of the moving speed in this case is preferably a manner in which the swinging distance in the wafer-W plane is divided into a plurality of sections and the moving speed is set for each section, for example.

The first buff pad 502-1 and the second buff pad 502-2 each have a smaller diameter than the wafer W. For example, when the wafer W is Φ 300 mm, each of the first buff pad 502-1 and the second buff pad 502-2 is preferably Φ 100 mm or less, and more preferably, Φ 60 to 100 mm. The reason for this is that the buff processing speed of the wafer increases because as the diameter of the buff pad increases, an area ratio to the wafer decreases. The types and materials of the first buff pad 502-1 and the second buff pad 502-2 do not need to be same and the first buff pad 502-1 and the second buff pad 502-2 of different types and materials may be arranged. Depending on the types, materials and the pad diameters of the respective buff pads, the first dresser 820-1 and the second dresser 820-2 of different types may be arranged. In FIG. 11, the dresser is divided into the first dresser 820-1 and the second dresser 820-2, but one dresser may be provided.

According to the present embodiment, the buff processing component 350 can perform the buff process by using the plurality of buff pads (the first buff pad 502-1 and the second buff pad 502-2). The buff processing component 350 can perform the buff process by using the first buff pad 502-1 and the second buff pad 502-2 simultaneously, for example. Accordingly, a contact area of the buff pad with the wafer W in the buff process increases, and thus, the buff processing component 350 in the present embodiment can improve the processing rate in the buff process.

<Processing Method>

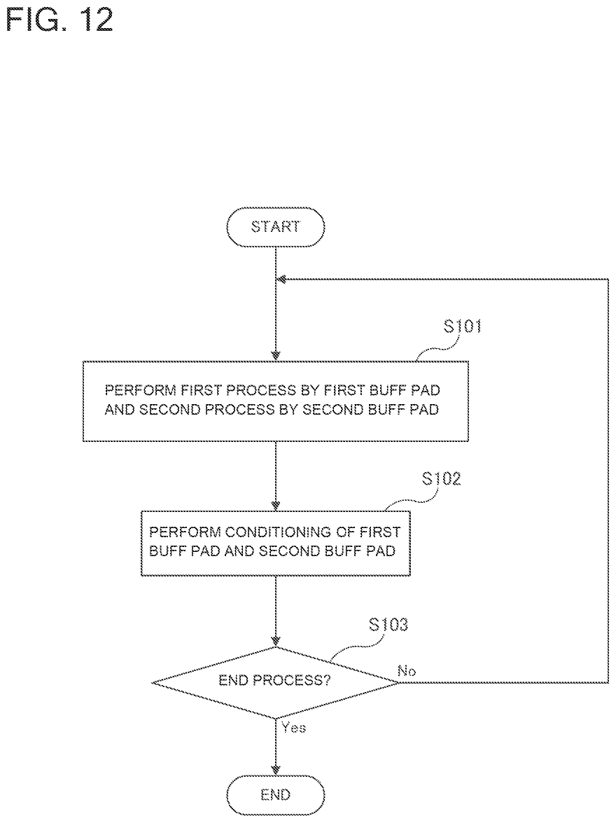

Next, a processing method of the present embodiment will be described. FIG. 12 is a flowchart of the processing method of the present embodiment. As the embodiments in FIGS. 7, 8, 9 and 11, FIG. 12 illustrates an example of the processing method in an embodiment in which the first buff pad 502-1 and the second buff pad 502-2 perform a buff process to the wafer W at a same timing and perform conditioning at a same timing. In the case of the configuration in FIG. 8, the third buff pad 502-3 performs the same process as the second buff pad 502-2.

In the processing method of the present embodiment, first, the buff processing component 350 performs a predetermined first process (a buff process) to the wafer W by bringing the first buff pad 502-1 into contact with the wafer W and moving the first buff pad 502-1 relatively to the wafer W, and also performs a predetermined second process (a buff process) to the wafer W by bringing the second buff pad 502-2 having a smaller diameter than the first buff pad 502-1 into contact with the wafer W and moving the second buff pad 502-2 relatively to the wafer W (step S101). The first process in step S101 is performed by the first buff pad 502-1 being brought into contact with an area (e.g., a center part) other than an area in the wafer W that the second buff pad 502-2 processes and moving relatively to the area. The second process is performed by the second buff pad 502-2 being brought into contact with an area (e.g., a peripheral edge part) other than the area in the wafer W that the first buff pad 502-1 processes and moving relatively to the area. In the present embodiment, a processed area by the first buff pad 502-1 differs from a processed area by the second buff pad 502-2, but not limited to this. The buff processing component 350 may perform the buff process to the both areas in a partially overlapping way without clearly separating the processed area by the first buff pad 502-1 from the processed area by the second buff pad 502-2.

Subsequently, the buff processing component 350 performs conditioning of the first buff pad 502-1 and the second buff pad 502-2 by turning the buff arm 600 or the buff arms 600-1 and 600-2 (step S102).

Subsequently, the buff processing component 350 determines whether to end the process (step S103). When the buff processing component 350 determines to continue performing the process to the same wafer W or to continue to perform the process because the succeeding wafer W is transferred, for example (No at step S103), the process returns to step S101 and continues. In contrast, when the buff processing component 350 determines to end the process (Yes at step S103), the process ends. Determination of whether to continue performing the process to the same wafer W is made in the following way, as an example. That is, the upper processing module 300A may include a Wet-ITM (In-line Thickness Monitor). The wet-ITM can detect (measure) film thickness distribution (or distribution of information of a film thickness) of the wafer W with a detecting head being above the wafer in a noncontact manner and moving over the entire surface of the wafer W. Regarding the ITM, the Wet-ITM is effective for measurement during the process. However, to obtain a film thickness or a signal corresponding to the film thickness at other times or after the process, the ITM does not need to be mounted on the upper processing module 300A. The ITM may be mounted on a part other than the processing module, for example, the loading/unloading unit to perform measurement when the wafer is taken into/out from the FOUP or the like. The same can be applied to the following embodiments. As means for detecting (measuring) the film thickness distribution (or distribution of a signal corresponding to the film thickness) of the processing target surface of the wafer W that is being processed, other than the Wet-ITM and the ITM described above, an overcurrent sensor or an optical sensor, which are not illustrated, may be used. The overcurrent sensor, which can be used for a processed surface of a conductive material, is arranged to face the processed surface of the wafer W. The overcurrent sensor supplies high-frequency current to a sensor coil placed in proximity to the processed surface of the wafer W to cause overcurrent in the wafer W, and detects distribution of the film thickness or the signal corresponding to the film thickness of the wafer W, based on change in the overcurrent or combined impedance according to the thickness of the processed area of the wafer W. The optical sensor is arranged to face the processed surface of the wafer W. The optical sensor, which can be used for a processed surface of a light-transmissive material, irradiates light to the processed surface of the wafer W and receives reflection light that is reflected by the processed surface of the wafer W or reflected after passing through the wafer W, and detects the distribution of the film thickness of the wafer W based on the received light. The upper processing module 300A can include a data base storing preset distribution of a target film thickness of the processing target surface of the wafer W or a signal corresponding to the target film thickness. Based on the difference between the distribution of the film thickness or the signal corresponding to the film thickness of the processed surface detected by the Wet-ITM, the ITM, the overcurrent sensor or the optical sensor and the distribution of the target film thickness or the signal corresponding to the target film thickness stored in the data base, the buff processing component 350 can determine whether to continue performing the process to the same wafer W. For example, when the difference is larger than a preset threshold, the buff processing component 350 may determine to continue performing the process to the same wafer W.

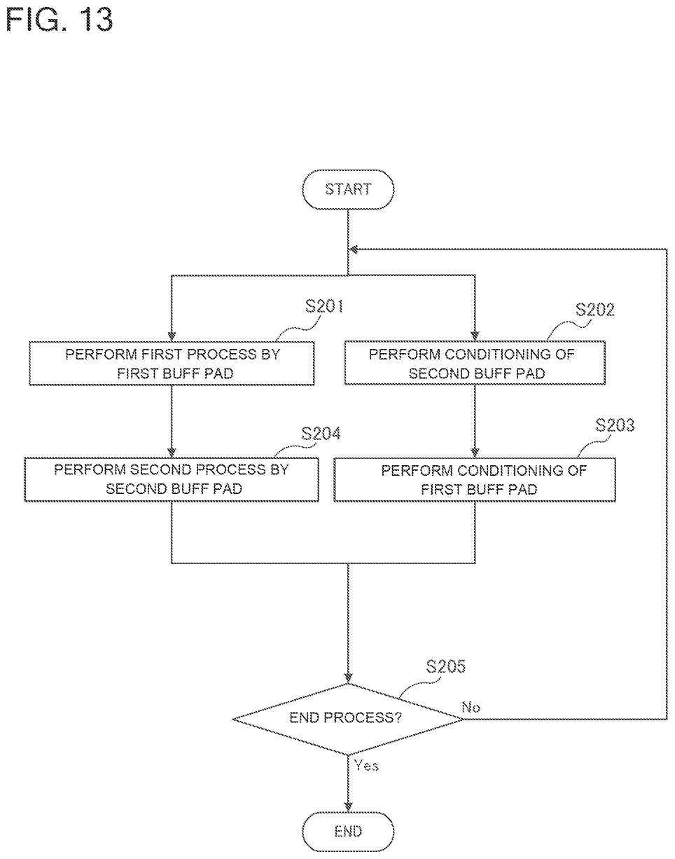

Next, another example of the processing method of the present embodiment will be described. FIG. 13 is a flowchart of the processing method of the present embodiment. FIG. 13 illustrates an example of the processing method of the embodiments in FIGS. 5, 6 and 10, in which the first buff pad 502-1 and the second buff pad 502-2 perform the buff process to the wafer W at different timings, and perform conditioning at different timings. In the case of the configuration in FIG. 6, the third buff pad 502-3 performs the same process as the second buff pad 502-2.

The buff processing component 350 performs the predetermined first process (the buff process) to the wafer W by bringing the first buff pad 502-1 into contact with the wafer W and moving the first buff pad 502-1 relatively to the wafer W (step S201). The first process in step S201 is performed by the first buff pad 502-1 being brought into contact with an area (e.g., the center part) other than an area in the wafer W that the second buff pad 502-2 processes and moving relatively to the area.

At the same timing as step S201, the buff processing component 350 performs conditioning of the second buff pad 502-2 (step S202).

Subsequently, the buff processing component 350 performs the predetermined second process (the buff process) to the wafer W by turning the buff arm 600-2, bringing the second buff pad 502-2 having a smaller diameter than the first buff pad 502-1 into contact with the wafer W and moving the second buff pad 502-2 relatively to the wafer W (step S203). The second process is performed by the second buff pad 502-2 being brought into contact with an area (e.g., the peripheral edge part) other than the area in the wafer W that the first buff pad 502-1 processes and moving relatively to the area. In the present embodiment, a processed area by the first buff pad 502-1 differs from a processed area by the second buff pad 502-2, but not limited to this. The buff processing component 350 may perform the buff process to the both areas in a partially overlapping way without clearly separating the processed area by the first buff pad 502-1 from the processed area by the second buff pad 502-2.

At the same timing as step S203, the buff processing component 350 performs conditioning of the first buff pad 502-1 by turning the buff arm 600-1 (step S204).

Subsequently, the buff processing component 350 determines whether to end the process (step S205). When the buff processing component 350 determines to continue performing the process to the same wafer W or to continue performing the process because the succeeding wafer W is transferred, for example (No at step S205), the process returns to step S201 and continues. In contrast, when the buff processing component 350 determines to end the process (Yes at step S205), the process ends. Determination of whether to continue performing the process to the same wafer W is made in the same way as above. Thus, the detailed description thereof is omitted.

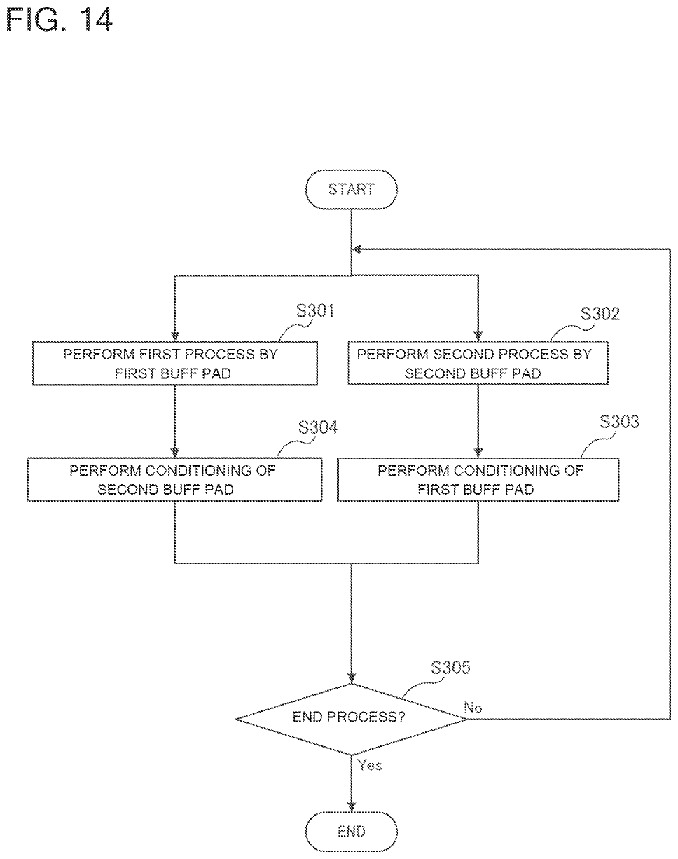

Next, another example of the processing method of the present embodiment will be described. FIG. 14 is a flowchart of the processing method of the present embodiment. FIG. 14 illustrates an example of the processing method of the embodiments in FIGS. 5, 6 and 10, in which the first buff pad 502-1 and the second buff pad 502-2 perform the buff process to the wafer W at the same timing, and perform conditioning at the same timing. In the case of the configuration in FIG. 6, the third buff pad 502-3 performs the same process as the second buff pad 502-2.

The buff processing component 350 performs the predetermined first process (the buff process) to the wafer W by bringing the first buff pad 502-1 into contact with the wafer W and moving the first buff pad 502-1 relatively to the wafer W (step S301). The first process in step S301 is performed by the first buff pad 502-1 being brought into contact with an area (e.g., the center part) other than an area in the wafer W that the second buff pad 502-2 processes and moving relatively to the area.

At the same timing as step S301, the buff processing component 305 performs the predetermined second process (the buff process) to the wafer W by bringing the second buff pad 502-2 having a smaller diameter than the first buff pad 502-1 into contact with the wafer W and moving the second buff pad 502-2 relatively to the wafer W (step S302). The second process is performed by the second buff pad 502-2 being brought into contact with an area (e.g., the peripheral edge part) other than the area in the wafer W that the first buff pad 502-1 processes and moving relatively to the area. In the present embodiment, a processed area by the first buff pad 502-1 differs from a processed area by the second buff pad 502-2, but not limited to this. The buff processing component 350 may perform the buff process to the both areas in a partially overlapping way without clearly separating the processed area by the first buff pad 502-1 from the processed area by the second buff pad 502-2.

Subsequently, the buff processing component 350 performs conditioning of the second buff pad 502-2 by turning the buff arm 600-2 (step S303).

At the same timing as step S303, the buff processing component 350 performs conditioning of the first buff pad 502-1 by turning the buff arm 600-1 (step S304).

Subsequently, the buff processing component 350 determines whether to end the process (step S305). When the buff processing component 350 determines to continue performing the process to the same wafer W or to continue performing the process because the succeeding wafer W is transferred, for example (No at step S305), the process returns to step S301 and continues. In contrast, when the buff processing component 350 determines to end the process (Yes at step S305), the process ends. Determination of whether to continue performing the process to the same wafer W is made in the same way as above. Thus, the detailed description thereof is omitted.

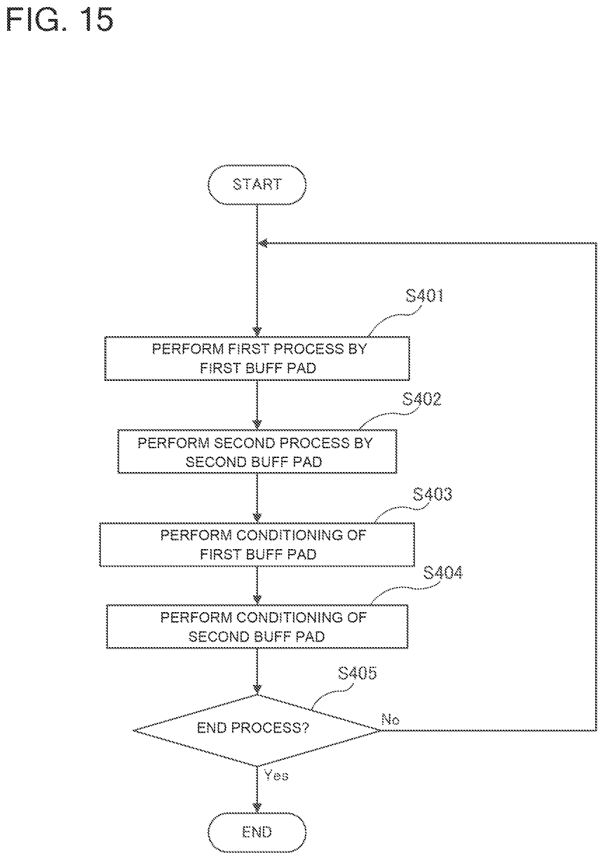

Next, still another example of the processing method of the present embodiment will be described. FIG. 15 is a flowchart of the processing method of the present embodiment. FIG. 15 illustrates an example of the processing method of the embodiments in FIGS. 5, 6 and 10, in which the two buff arms 600-1 and 600-2 are not linked with each other and perform the buff process and the conditioning process to the first buff pad 502-1 and the second buff pad 502-2 at respective own timings. In the case of the configuration in FIG. 6, the third buff pad 502-3 performs the same process as the second buff pad 502-2.

The buff processing component 350 performs the predetermined first process (the buff process) to the wafer W by bringing the first buff pad 502-1 into contact with the wafer W and moving the first buff pad 502-1 relatively to the wafer W (step S401). The first process in step S401 is performed by the first buff pad 502-1 being brought into contact with an area (e.g., the center part) other than an area in the wafer W that the second buff pad 502-2 processes and moving relatively to the area.

Subsequently, the buff processing component 350 performs the predetermined second process (the buff process) to the wafer W by bringing the second buff pad 502-2 having a smaller diameter than the first buff pad 502-1 into contact with the wafer W and moving the second buff pad 502-2 relatively to the wafer W (step S402). The second process is performed by the second buff pad 502-2 being brought into contact with an area (e.g., the peripheral edge part) other than the area in the wafer W that the first buff pad 502-1 processes and moving relatively to the area. In the present embodiment, a processed area by the first buff pad 502-1 differs from a processed area by the second buff pad 502-2, but not limited to this. The buff processing component 350 may perform the buff process to the both areas in a partially overlapping way without clearly separating the processed area by the first buff pad 502-1 from the processed area by the second buff pad 502-2. In this way, the first process and the second process are started at different timings.

Subsequently, the buff processing component 350 performs conditioning of the first buff pad 502-1 by turning the buff arm 600-1 (step S403).

Subsequently, the buff processing component 350 performs conditioning of the second buff pad 502-2 by turning the buff arm 600-2 (step S404). In this way, conditioning of the first buff pad 502-1 and conditioning of the second buff pad 502-2 are started at different timings.

Subsequently, the buff processing component 350 determines whether to end the process (step S405). When the buff processing component 350 determines to continue performing the process to the same wafer W or to continue performing the process because the succeeding wafer W is transferred, for example (No at step S405), the process returns to step S401 and continues. In contrast, when the buff processing component 350 determines to end the process (Yes at step S405), the process ends. Determination of whether to continue performing the process to the same wafer W is made in the same way as above. Thus, the detailed description thereof is omitted. The aforementioned order of steps S401 to S404 is just an example. When the two buff arms 600-1 and 600-2 are not linked with each other and perform the buff process and the conditioning process to the first buff pad 502-1 and the second buff pad 502-2 at the respective own timings, steps S401 to S404 may be performed at an arbitrary order.

According to the processing method of the present embodiment, since the contact area of the buff pad with the wafer W in the buff process increases, the processing rate in the buff process can be improved. In addition, according to the processing method of the present embodiment, the buff process can be performed using the buff pads having different sizes (the first buff pad 502-1 and the second buff pad 502-2). Accordingly, for example, the buff processing component 350 can perform the buff process mainly to an area other than the peripheral edge part of the wafer W using the first buff pad 502-1 and perform the buff process to the peripheral edge part of the wafer W using the second buff pad 502-2 having a smaller diameter than the first buff pad 502-1. As a result, according to the processing method of the present embodiment, the in-plane uniformity of the processing speed of the wafer W can be improved.

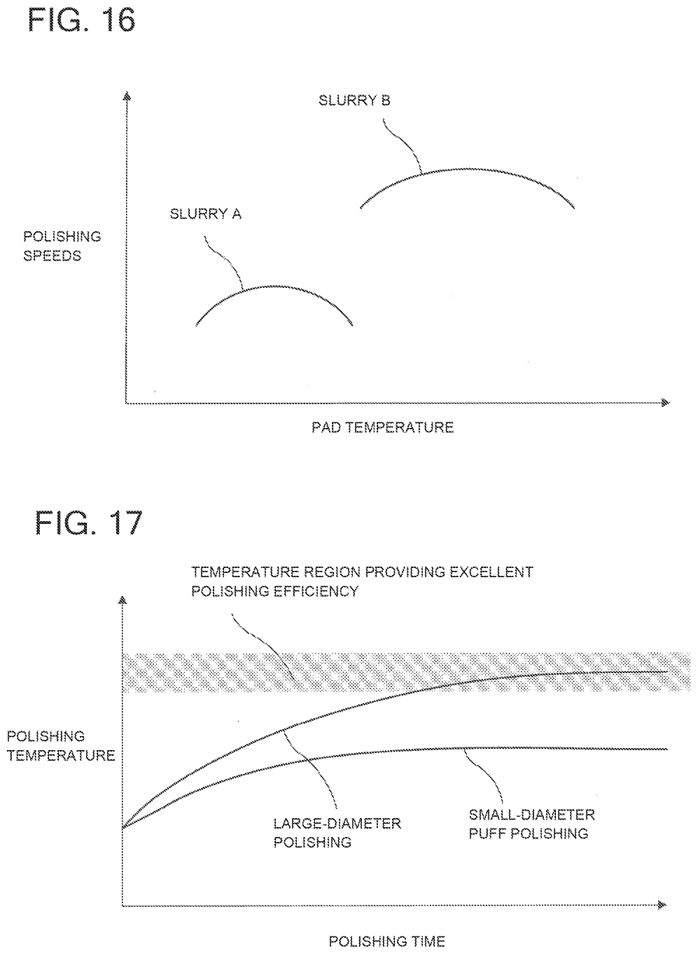

Hereinafter, embodiments of a buff processing apparatus as the substrate processing apparatus according to the present invention will be described with reference to FIGS. 16 to 24. Throughout FIGS. 16 to 24, a same or similar element is denoted by a same reference, and overlapping descriptions of same or similar elements in the descriptions of each embodiment will be omitted in some cases. Features described in each embodiment can be applied to another embodiment as long as there is no inconsistency to each other.

It is known that, in general CMP of pressing the wafer W against a polishing pad of a larger size than the semiconductor wafer W to polish the wafer W, a polishing speed varies according to a polishing temperature. For example, FIG. 16 illustrates variation in polishing speed of different types of slurry A and slurry B used in CMP with the temperatures. The slurry A and the slurry B vary with the temperature. The slurry A and the slurry B exhibit high polishing efficiency at different temperatures.

When CMP polishing is performed using a polishing pad of a larger size than the wafer W to be polished, an entire surface of the wafer W is always in contact with the polishing pad. Accordingly, heat generated by polishing is accumulated, and a temperature on the surface of the wafer W rises with polishing time to reach a temperature region of a high polishing-speed. In this way, polishing may be facilitated.

FIG. 17 is a graph showing surface temperatures of the wafer W relative to polishing times, when a polishing pad of a larger size than the wafer W to be polished is used to polish the wafer W (large-diameter polishing) and when a polishing buff pad of a smaller size than the wafer W to be polished is used to polish the wafer W (small-diameter buff polishing). A shaded part in FIG. 17 indicates a temperature region providing excellent polishing efficiency.

As shown in the graph in FIG. 17, when a polishing pad of a larger size than the wafer W to be polished is used to polish the wafer W, the temperature of the wafer W easily rises. Thus, during polishing, the temperature reaches the temperature region providing excellent polishing efficiency. On the other hand, when a polishing buff pad of a smaller size than the wafer W to be polished is used to polish the wafer W, heat generated by polishing by the buff pad is easily dissipated due to the smaller size of the buff pad in contact with the wafer W so that the temperature of the wafer W is hard to rise. Accordingly, the temperature region providing excellent polishing efficiency is not reached or it takes time to reach the temperature region providing excellent polishing efficiency. When the wafer W is pressed against a polishing pad of a larger size than the wafer W to be polished to polish the wafer W, the temperature of the entire surface of the wafer W rises uniformly. However, when a polishing buff pad of a smaller size than the wafer W to be polished is used to polish the wafer W, a temperature rises only at an area with which the pad is in contact so that the temperature of the wafer W is easy to be nonuniform.

Therefore, the present invention provides a buff processing apparatus and a buff processing method that can improve buff processing efficiency by controlling a temperature of a substrate to be buffed when the buff process is performed using a buff pad of a smaller size than the substrate to be buffed.

Herein, the buff process includes at least one of a buff polishing process and a buff cleaning process.

The buff polishing process is a process of moving a substrate relatively to a buff pad while keeping the buff pad in contact with the substrate and interposing slurry between the substrate and the buff pad to polish and remove a processing target surface of the substrate. In the buff polishing process, a physical acting force that is larger than a physical acting force applied to the substrate when the substrate is cleaned with physical action using a sponge or the like can be applied to the substrate. Through the buff polishing process, a surface layer part that is damaged, for example, scratched or has a contamination can be removed, a part that a main polishing unit has failed to remove in main polishing can be additionally removed, or the morphology after the main polishing including unevenness in a fine region and film thickness distribution over the entire substrate can be improved.

The buff cleaning process is a process of moving a substrate relatively to a buff pad while keeping the buff pad in contact with the substrate, interposing a cleaning processing liquid (a chemical liquid, or a chemical liquid and deionized water) between the substrate and the buff pad to remove a contamination on the surface of the substrate or reform a processing target surface. In the buff cleaning process, a physical acting force that is larger than a physical acting force applied to the substrate when the substrate is cleaned with physical action using a sponge or the like can be applied to the substrate.

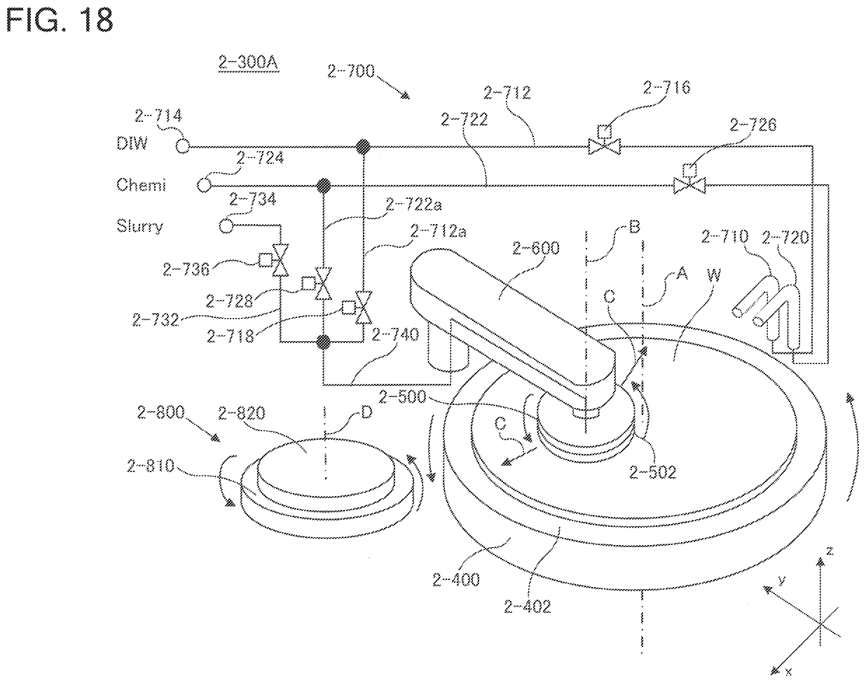

FIG. 18 is a diagram schematically illustrating a buff processing module 2-300A according to an embodiment that is applicable to the buff processing apparatus of the present invention. The buff processing module 2-300A in FIG. 18 can be configured as part of a CMP apparatus or a unit in a CMP apparatus performing a polishing process to a substrate such as a semiconductor wafer. As an example, the buff processing module 2-300A can be installed in a CMP apparatus that includes a polishing unit, a cleaning unit and a substrate transfer mechanism. The buff processing module 2-300A can be used for a finishing process after main polishing in the CMA apparatus.

As illustrated in FIG. 18, the buff processing module 2-300A according to an embodiment includes a buff table 2-400 on which the wafer W is placed, a buff head 2-500 to which a buff pad 2-502 for performing a buff process to a processing target surface of the wafer W, a buff arm 2-600 that holds the buff head 2-500, a liquid supplying system 2-700 that supplies various types of processing liquids, and a conditioning unit 2-800 that performs conditioning (setting) of the buff pad 2-502. The buff processing module 2-300A includes a temperature controlling device that provides a temperature controlling function, which is not illustrated in FIG. 18 for clarification of the drawing and will be described later.

The buff processing module 2-300A can perform the above buff polishing process and/or the buff cleaning process. Also, the buff processing module 2-300A can control a temperature of the wafer W during the buff process, as described later.

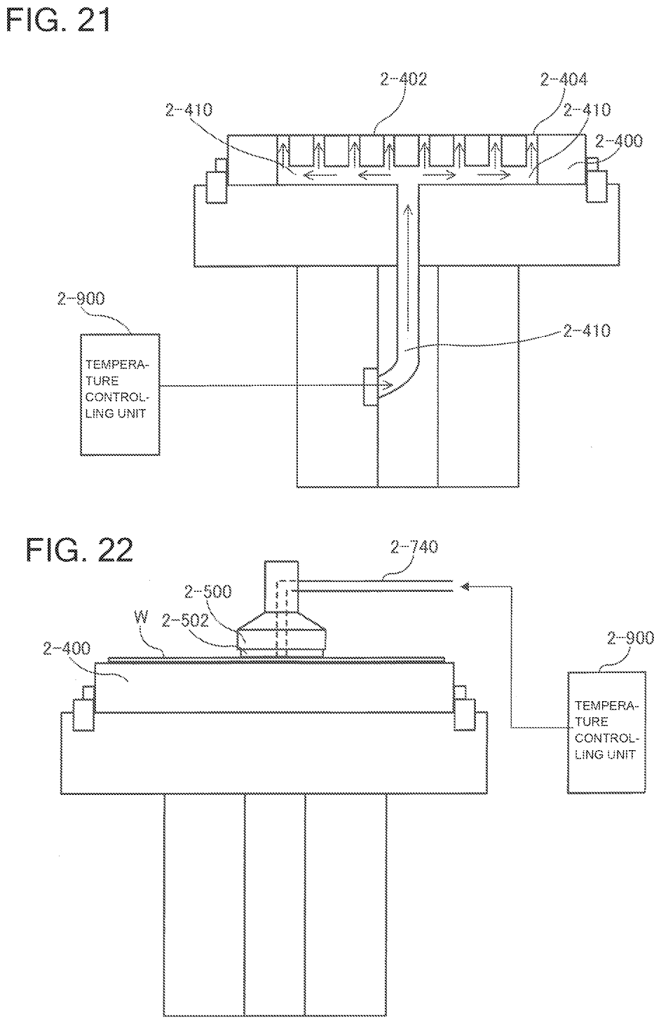

The buff table 2-400 includes a supporting surface 2-402 for supporting the wafer W. In the illustrated embodiment, the supporting surface 2-402 of the buff table 2-400 is configured to support the wafer W with the wafer W horizontally turned up. The supporting surface 2-402 includes an opening part 2-404 of a fluid passage 2-410 (see FIG. 21) that is used to adsorb the wafer W. The fluid passage 2-410 is connected to a non-illustrated vacuum source and can vacuum-suck the wafer W. Alternatively, the wafer W may be sucked to the buff table 2-400 via a stage film. The stage film can be attached to the surface of the buff table 2-400 with an adhesive tape. As the stage film, a known one can be used. The stage film having a through hole 2-452 at a position corresponding to the opening part 2-404 of the buff table 2-400 can be used.

Herein, examples of a case where the wafer W is supported on the buff table 2-400 include a case where the wafer W is supported via the stage film.

The buff table 2-400 is rotatable around the rotation shaft A by a non-illustrated driving mechanism. The buff pad 2-502 is attached to a surface of the buff head 2-500 facing the wafer W. The buff arm 2-600 can rotate the buff head 2-500 around the rotation shaft B and swing the buff head 2-500 in a radial direction of the wafer W, as shown by the arrow C. The buff arm 2-600 can also swing the buff head 2-500 to a position where the buff pad 2-502 faces the conditioning unit 2-800.

In the embodiment illustrated in FIG. 18, the size of the buff pad 2-502 is smaller than the diameter of the buff table 2-400 or the diameter of the wafer W to be buffed. Since the buff process is performed using the buff pad of a smaller size than the wafer W to be buffed, the buff pad can flatten local unevenness on the wafer W, polish only a particular area of the wafer W, and improve adjustability of a polishing amount according to the position of the wafer W. The size of the buff pad 2-502 may be substantially equal to the size of the wafer W to be buffed or the size of the buff table.

The liquid supplying system 2-700 illustrated in FIG. 18 includes a deionized-water nozzle 2-710 for supplying deionized water (DIW) to the processing target surface of the wafer W. The deionized-water nozzle 2-710 is connected to a deionized-water supplying source 2-714 via a deionized-water pipe 2-712. The deionized-water pipe 2-712 is provided with an opening and closing valve 2-716 that can open and close the deionized-water pipe 2-712. A non-illustrated control device controls opening/closing of the opening and closing valve 2-716 to supply deionized water to the processing target surface of the wafer W at an arbitrary timing.

Further, the liquid supplying system 2-700 illustrated in FIG. 18 includes a chemical-liquid nozzle 2-720 for supplying chemical liquid (Chemi) to the processing target surface of the wafer W. The chemical-liquid nozzle 2-720 is connected to a chemical-liquid supplying source 2-724 via a chemical-liquid pipe 2-722. The chemical-liquid pipe 2-722 is provided with an opening and closing valve 2-726 that can open and close the chemical-liquid pipe 2-722. A non-illustrated control device controls opening/closing of the opening and closing valve 2-726 to supply chemical liquid to the processing target surface of the wafer W at an arbitrary timing.

In an embodiment, in the liquid supplying system 2-700, a temperature controlling unit 2-900 as an example of the temperature controlling device may be placed in the middle of the deionized-water pipe 2-712 and/or the chemical-liquid pipe 722 to make the temperature of deionized water and/or a chemical liquid to a desired temperature, and the deionized water and/or the chemical liquid may be supplied to the processing target surface of the wafer W from the deionized-water nozzle 2-710 and/or the chemical-liquid nozzle 2-720. Supply of deionized water and/or a chemical liquid controlled in temperature to the wafer W allows control of the temperature of the wafer W to a desired temperature.

The buff processing module 2-300A according to the embodiment illustrated in FIG. 18 can supply deionized water, chemical liquid or slurry selectively to the processing target surface of the wafer W or the supporting surface 2-420 supporting the wafer W on the buff table 2-400 through the buff arm 2-600, the buff head 2-500, and the buff pad 2-502.

That is, a branch deionized-water pipe 2-712a is branched from the deionized-water pipe 2-712 at a point between the deionized-water supplying source 2-714 and the opening and closing valve 2-716. A branch chemical-liquid pipe 2-722a is branched from the chemical-liquid pipe 2-722 at a point between the chemical-liquid supplying source 2-724 and the opening and closing valve 2-726. The branch deionized-water pipe 2-712a, the branch chemical-liquid pipe 2-722a, and a slurry pipe 2-732, which is connected to a slurry supplying source 2-734, join a liquid supplying pipe 2-740. The branch deionized-water pipe 2-712a is provided with an opening and closing valve 2-718 that can open and close the branch deionized-water pipe 2-712a. The branch chemical-liquid pipe 2-722a is provided with an opening and closing valve 2-728 that can open and close the branch chemical-liquid pipe 2-722a. The slurry pipe 2-732 is provided with an opening and closing valve 2-736 that can open and close the slurry pipe 2-732.

A first end of the liquid supplying pipe 2-740 is connected to three system pipes that are the branch deionized-water pipe 2-712a, the branch chemical-liquid pipe 2-722a, and the slurry pipe 2-732. The liquid supplying pipe 2-740 extends through the inside of the buff arm 2-600, the center of the buff head 2-500, and the center of the buff pad 2-500. A second end of the liquid supplying pipe 2-740 opens to the processing target surface of the wafer W. The non-illustrated control device controls opening/closing of the opening and closing valve 2-718, the opening and closing valve 2-728 and the opening and closing valve 2-736 to supply the surface of the wafer W with one of deionized water, a chemical liquid, slurry, or a combined liquid of an arbitrary combination of them at an arbitrary timing.

In an embodiment, the temperature controlling unit 2-900 as an example of the temperature controlling device may be placed in the middle of the liquid supplying pipe 2-740 to make the temperature of a liquid such as deionized water, chemical liquid or slurry to a desired temperature, and the liquid may be supplied to the processing target surface of the wafer W from the buff pad 2-502. Supply of a liquid controlled in temperature to the wafer W allows control of the temperature of the wafer W to be buffed to a desired temperature.

The buff processing module 2-300A according to the embodiment illustrated in FIG. 18 can perform the buff process to the wafer W by supplying a processing liquid to the wafer W through the liquid supplying pipe 2-740, rotating the buff table 2-400 around the rotation shaft A to press the buff pad 2-502 against the processing target surface of the wafer W, and swinging the buff head 2-500 in a direction of an arrow C while turning the buff head 2-500 around the rotation shaft B.

The conditioning unit 2-800 illustrated in FIG. 18 is a member for performing conditioning of the surface of the buff pad 2-502. The conditioning unit 2-800 includes a dressing table 2-810 and a dresser 2-820 that is placed on the dressing table 2-810. The dressing table 2-810 is rotatable around a rotation shaft D by a non-illustrated driving mechanism. The dresser 2-820 is formed of a diamond dresser, a brush dresser or a combination thereof.

In conditioning of the buff pad 2-502, the buff processing module 2-300A turns the buff arm 2-600 to a position where the buff pad 2-502 becomes opposite to the dresser 2-820. The buff processing module 2-300A rotates the dressing table 2-810 around the rotation shaft D, rotates the buff head 2-500, and presses the buff pad 2-502 against the dresser 2-820 to perform conditioning of the buff pad 2-502.

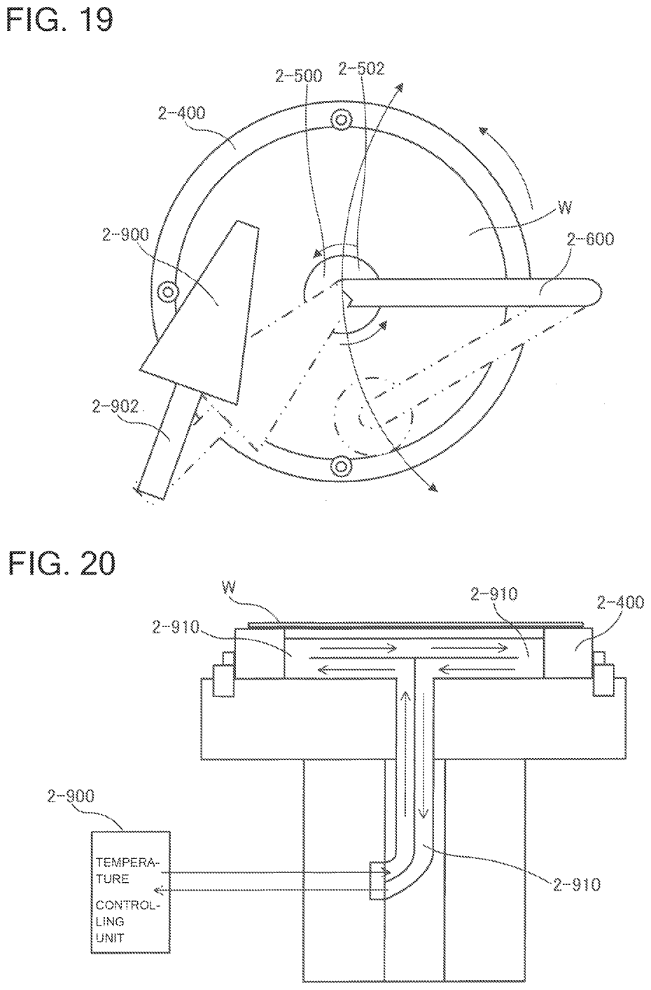

FIG. 19 is an explanatory schematic top view of a buff processing apparatus that includes a temperature controlling device providing a temperature controlling function for the wafer W that is being buffed, according to an embodiment of the present invention. FIG. 19 illustrates the buff arm 2-600, the buff head 2-500 and the buff pad 2-502, which may be same as those in the embodiment illustrated in FIG. 18 or different therefrom. The liquid supplying system 2-700, illustration of which is omitted in FIG. 19, may be same as that in the embodiment illustrated in FIG. 18. In the buff process, slurry can be supplied from the buff pad 2-502 to the wafer W through the liquid supplying pipe 2-740. In the buff process, a chemical liquid and/or deionized water may be supplied from the buff pad 2-502 to the wafer W through the liquid supplying pipe 2-740, or may be additionally supplied from the deionized-water nozzle 2-710 and/or the chemical-liquid nozzle 2-720 to the wafer W through the deionized-water pipe 2-712 and/or the chemical-liquid pipe 2-722. In the embodiment illustrated in FIG. 19, slurry, deionized water and/or the chemical liquid may be controlled in temperature by the temperature controlling unit 2-900 or may not be controlled in temperature.

The buff processing apparatus according to the embodiment illustrated in FIG. 19 includes a blower 2-902 for supplying a gas controlled in temperature toward the wafer W to be buffed, as an example of the temperature controlling device for controlling the temperature of the wafer W. The blower 2-902 is swingable above the buff table 2-400 to which the wafer W is attached by an arm 2-902. The blower 2-902 and the buff arm 2-600 are controlled to swing so as not to interfere with each other. Alternatively, the blower 2-902 may be prevented from interfering with the buff arm 2-600 by placing the blower 2-902 at a position farther from the surface of the wafer W than the buff arm 2-600 in a direction perpendicular to the surface of the wafer W or a horizontal direction.

A gas (e.g., air) adjusted in temperature is supplied to the wafer W by the blower 2-902 so that the temperature of the wafer W that is being buffed can be controlled to an appropriate temperature. As the blower 2-902, an arbitrary blower such as a known one can be used.

FIG. 20 illustrates a configuration for controlling the temperature of the wafer W that is being buffed as an example of the temperature controlling device for controlling the temperature of the wafer W, according to an embodiment. FIG. 20 schematically illustrates a section taken along a direction perpendicular to the supporting surface 2-402 of the buff table 2-400. As illustrated in FIG. 20, in the embodiment, a fluid circulation passage 2-910 for circulating a fluid (e.g., water) is formed in the buff table 2-400. Arrows in the drawing show a flow direction of a fluid in the fluid circulation passage 2-910. Near the surface of the buff table 2-400, the fluid circulation passage 2-910 meanders in an in-plane direction of the buff table 2-400 so that heat exchange between a fluid flowing through the fluid circulation passage 2-910 and the wafer W supported on the buff table 2-400 can be performed. The fluid circulation passage 2-910 is fluidly connected to the temperature controlling unit 2-900 to circulate a fluid controlled in temperature in the fluid circulation passage 2-910 via the temperature controlling unit 2-900. Accordingly, the temperature of the wafer W supported on the buff table 2-400 can be controlled to a temperature appropriate for the buff process. As the temperature controlling unit 2-900, an arbitrary unit such as a known one that can control the temperature of a flowing fluid can be used. The configuration for controlling the temperature of the wafer W illustrated in FIG. 20 is used in combination with the blower 2-902 illustrated in FIG. 19.

FIG. 21 illustrates a configuration for controlling the temperature of the wafer W that is being buffed as an example of the temperature controlling device for controlling the temperature of the wafer W, according to an embodiment. FIG. 21 schematically illustrates a section taken along a direction perpendicular to the supporting surface 2-402 of the buff table 2-400. As illustrated in FIG. 21, in the embodiment, a fluid passage 2-410 through which a fluid flows in the buff table 2-400 and is discharged from the supporting surface 2-402 of the buff table 2-400 is formed in the buff table 2-400. The fluid passage 2-410 is fluidly connected to the temperature controlling unit 2-900 to let a fluid (e.g., deionized water) controlled in temperature by the temperature controlling unit 2-900 flow into the fluid passage 2-410.

After the buffed wafer W is moved from the buff table 2-400, a fluid controlled in temperature flows to the supporting surface 2-402 of the buff table 2-400 from the fluid passage 2-410. In this way, the supporting surface 2-402 of the buff table 2-400 can be adjusted to a desired temperature to control the temperature of the succeeding wafer W to be processed. For example, to clean the supporting surface 2-402 of the buff table 2-400 after the wafer W is moved from the buff table 2-400, a fluid controlled in temperature can flow through the fluid passage 2-410. In the buff process, the fluid passage 2-410 is connected to a non-illustrated vacuum source and is used for the buff table 2-400 vacuum sucking the wafer W.

FIG. 22 illustrates a configuration for controlling the temperature of the wafer W that is being buffed as an example of the temperature controlling device for controlling the temperature of the wafer W, according to an embodiment. FIG. 22 is a schematic view seen from the side of the buff table 2-400. The buff head 2-500 and the buff pad 2-502 illustrated in FIG. 22, as in the embodiment illustrated in FIG. 18, can supply deionized water, chemical liquid, or slurry selectively to the processing target surface of the wafer W via the buff head 2-500 and the buff pad 2-502. In the embodiment illustrated in FIG. 22, the temperature controlling unit 2-900 is placed in the middle of the liquid supplying pipe 2-740 (see FIG. 18). Slurry, deionized water and/or chemical liquid can be controlled to a desired temperature by the temperature controlling unit 2-900 to be supplied to the wafer W through the buff pad 2-502. Accordingly, the temperature of the wafer W supported on the buff table 2-400 can be controlled to a temperature appropriate for the buff process. The configuration for temperature control according to the embodiment illustrated in FIG. 22 may be used in combination with the configurations illustrated in FIGS. 19 to 21.

In an embodiment of the present invention, the buff processing unit 2-300A can include a thermometer that measures the temperature of the wafer W to be buffed.

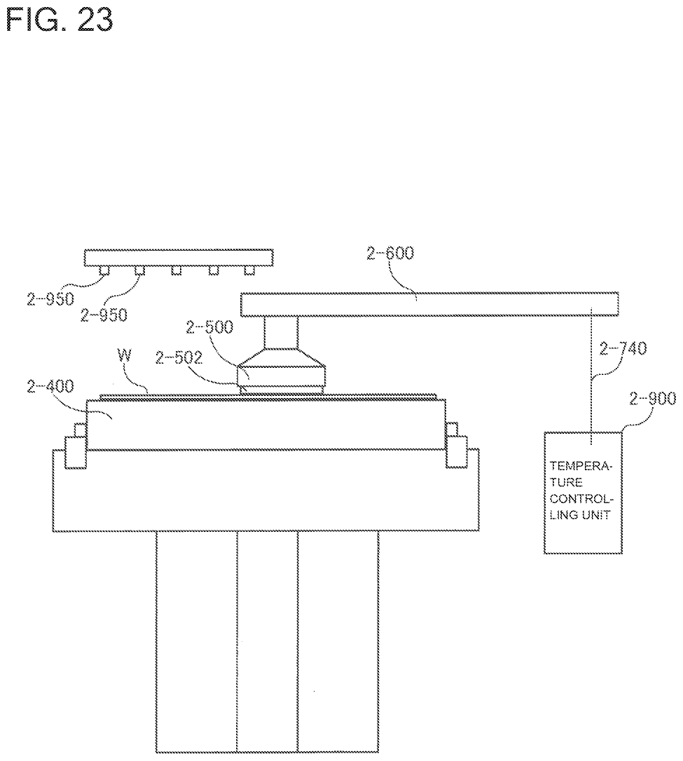

FIG. 23 illustrates a thermometer that is applicable to the buff processing unit 2-300A, according to an embodiment. FIG. 23 is a schematic view seen from the side of the buff table 2-400. The buff processing unit 2-300A illustrated in FIG. 23 includes an array of radiation thermometers 2-950 arranged in a radius direction of the buff table 2-400. The radiation thermometers 2-950 can measure the wafer W that is being buffed in a non-contact manner. In the buff process, since the wafer W is rotated, the array of radiation thermometers 2-950 can measure the temperature of the entire surface of the wafer W. The radiation thermometers 2-950 are arranged so as to face the buff table 2-400 by an appropriate mechanism, which is not illustrated for clarification of the drawing. In an embodiment, the array of radiation thermometers 2-950 is formed so as to measure temperatures of three to eleven areas divided from the center of the wafer W in the edge direction. When the buff pad 2-502 swings in a measurement region of the radiation thermometers 2-950, the radiation thermometers 2-950 are controlled not to measure a temperature or to ignore a measured temperature. As the radiation thermometer 2-950, an arbitrary thermometer such as an infrared thermometer can be used.

In an embodiment, the radiation thermometer 2-950 is connected to the blower 2-902 illustrated in FIG. 19 and the temperature controlling unit 2-900 illustrated in FIGS. 20 to 22. Based on the temperature measured by the radiation thermometer 2-950, the temperature controlling mechanisms 2-900 and 2-902 for the wafer W can be adjusted. Accordingly, the temperature of the wafer W can be controlled more accurately in the buff process.

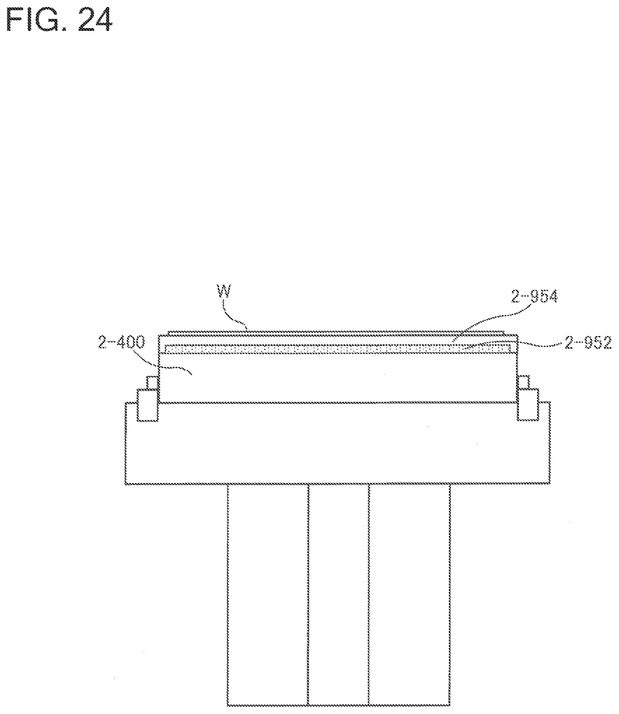

FIG. 24 illustrates a thermometer that is applicable to the buff processing unit 2-300A, according to an embodiment. FIG. 24 is a schematic view seen from the side of the buff table 2-400. As illustrated in FIG. 24, the buff table 2-400 in this embodiment includes a sheet-type in-plane temperature distribution thermometer 2-952 below the supporting surface 2-402. The sheet-type in-plane temperature distribution thermometer 2-952 can measure in-plane temperature distribution of the wafer W. A protection plate 2-954 is placed on the sheet-type in-plane temperature distribution thermometer 2-952 to protect the sheet-type in-plane temperature distribution thermometer 2-952. As an example, the sheet-type in-plane temperature distribution thermometer 2-952 is configured to measure temperatures of three to eleven areas divided from the center of the wafer W in the edge direction. As the sheet-type in-plane temperature distribution thermometer 2-952, an arbitrary thermometer such as a known one can be used.

In an embodiment, the sheet-type in-plane temperature distribution thermometer 2-952 is connected to the blower 2-902 illustrated in FIG. 19 and the temperature controlling unit 2-900 illustrated in FIGS. 20 to 22. Based on the temperature measured by the sheet-type in-plane temperature distribution thermometer 2-952, the temperature controlling mechanisms 2-900 and 2-902 for the wafer W can be adjusted. Accordingly, the temperature of the wafer W can be controlled more accurately in the buff process.

Since the buff processing apparatus according to the embodiments of the present invention can control the temperature of the wafer W that is being buffed, the buff process can be performed efficiently. For example, the processing speed of the buff polishing process can be improved by maintaining the temperature of the wafer W to a temperature appropriate for slurry to be used in the buff polishing process. Improvement in the processing speed of the buff polishing allows efficient lift-off of particles firmly fixed on the surface of the wafer W together with the wafer surface layer or efficient removal of the wafer surface layer with a scratch.

Moreover, the temperature of the wafer W can be maintained to a temperature appropriate for a chemical liquid used in the buff cleaning process and an effect of the chemical liquid can be promoted in buff cleaning. For example, decomposition reaction of particles firmly fixed on the surface of a wafer using a chemical liquid can be facilitated. Activating a chemical liquid can improve the speed of the buff cleaning process.

The buff processing apparatus having a function of controlling a temperature of an object that is being buffed has been described above with reference to FIGS. 16 to 24. However, the present invention is not limited to the above embodiments. Furthermore, a feature of each of the above embodiments can be combined or exchanged as long as there is no inconsistency to each other. For example, in the drawings and descriptions of the above embodiments, the buff table is horizontal and the supporting surface faces upward in a vertical direction. However, in the buff processing apparatus in one embodiment, the supporting table of the buff table may face in a horizontal direction.

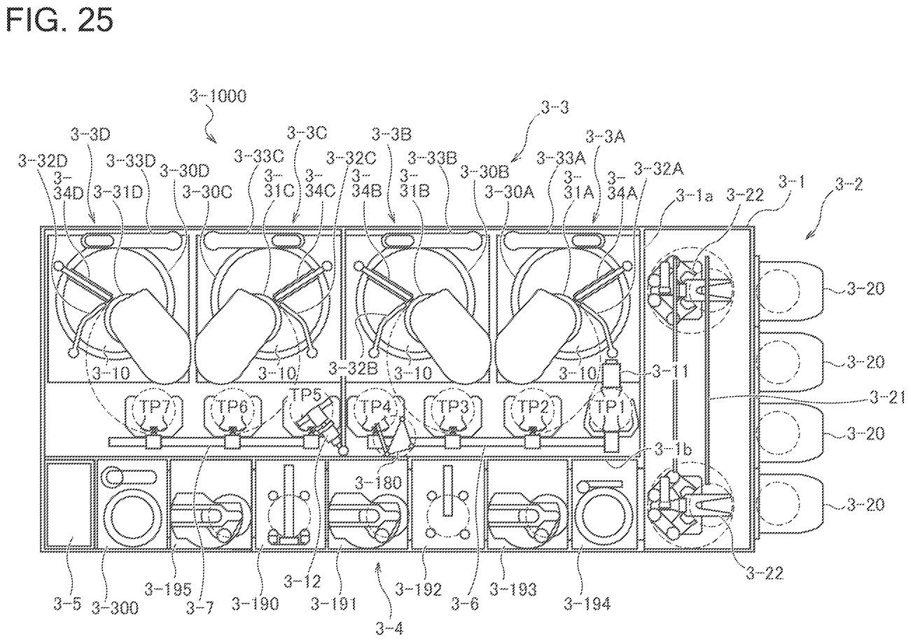

Hereinafter, descriptions will be given of a polishing apparatus and a processing method according to an embodiment of the present invention with reference to FIGS. 25 to 39.

<Polishing Apparatus>

FIG. 25 is a plan view illustrating an entire configuration of a polishing apparatus according to an embodiment of the present invention. As illustrated in FIG. 25, a polishing apparatus (a CMP apparatus) 3-1000 for processing an object includes a housing 3-1 that has a substantially rectangular shape. Inside the housing 3-1, a loading/unloading unit 3-2, a polishing unit 3-3, and a cleaning unit 3-4 are partitioned from one another by partition walls 3-1a and 3-1b. The loading/unloading unit 3-2, the polishing unit 3-3, and the cleaning unit 3-4 are separately assembled and gas in the respective units is independently exhausted. The cleaning unit 3-4 includes a power supply part that supplies power to the polishing apparatus and a control device 3-5 that controls processing operations.

<Loading/Unloading Unit>

The loading/unloading unit 3-2 includes two or more (four in the present embodiment) front loading parts 3-20 on which a wafer cassette for stocking many objects (for example, wafers (substrates)) is placed. The front loading parts 3-20 are adjacent to the housing 3-1 and arranged along a width direction (a direction perpendicular to the longitudinal direction) of the polishing apparatus. To the front loading part 3-20, an open cassette, a SMIF (Standard Manufacturing Interface) pod, or a FOUP (Front Opening Unified Pod) can be mounted. The SMIF and the FOUP each are an airtight container that can house a wafer cassette and be covered with a partition wall to keep an environment isolated from an external space.

On the loading/unloading unit 3-2, a traveling mechanism 3-21 is laid along the arrangement of the front loading parts 3-20. On the traveling mechanism 3-21, two transfer robots (loaders, transfer mechanisms) 3-22 that are movable along the arrangement direction of wafer cassettes are provided. The transfer robots 3-22 moves on the traveling mechanism 3-21 to access the wafer cassettes mounted on the front loading parts 3-20 by moving. Each of the transfer robots 3-22 includes upper and lower hands. The upper hand is used to return a wafer after processing to the wafer cassette. The lower hand is used to take a wafer before processing from the wafer cassette. In this way, the upper and lower hands can be used for different purposes. The lower hand of the transfer robot 3-22 can reverse a wafer.

Since the loading/unloading unit 3-2 needs to keep cleanest, a pressure inside the loading/unloading unit 2 is always kept higher than that of any of the external part of the polishing apparatus, the polishing unit 3-3, and the cleaning unit 3-4. The polishing unit 3 is the dirtiest area because the polishing unit 3-3 uses slurry as a polishing liquid. Accordingly, a negative pressure is made inside the polishing unit 3-3 and is kept lower than the internal pressure of the cleaning unit 3-4. The loading/unloading unit 3-2 is provided with a filter fan unit (not illustrated) having a clean air filter such as a HEPA filter, an ULPA filter or a chemical filter. Clean air from which particles, toxic vapor or toxic gas has been removed is always blown out from the clean fan filter.

<Polishing Unit>

The polishing unit 3-3 is an area where polishing (flattening) of a wafer is performed. The polishing unit 3-3 includes a first polishing module 3-3A, a second polishing module 3-3B, a third polishing module 3-3C, and a fourth polishing module 3-3D. As illustrated in FIG. 25, the first polishing module 3-3A, the second polishing module 3-3B, the third polishing module 3-3C, and the fourth polishing module 3-3D are arranged along a longitudinal direction of the polishing apparatus.

As illustrated in FIG. 25, the first polishing module 3-3A includes a polishing table 3-30A with a polishing pad (a polishing tool) 3-10 having a polishing surface, a top ring 3-31A for holding and pressing a wafer against the polishing pad 3-10 on the polishing table 3-30A to polish the wafer, a polishing-liquid supplying nozzle 3-32A for supplying a polishing liquid or a dressing liquid (for example, deionized water) to the polishing pad 3-10, a dresser 3-33A for dressing the polishing surface of the polishing pad 3-10, and an atomizer 3-34A that injects mixed fluid of liquid (for example, deionized water) and gas (for example, nitrogen gas) or liquid (for example, deionized water) to remove slurry or a polishing product on the polishing surface and a polishing pad residue caused by dressing.

Similarly, the second polishing module 3-3B includes a polishing table 3-30B, a top ring 3-31B, a polishing-liquid supplying nozzle 3-32B, a dresser 3-33B, and an atomizer 3-34B. The third polishing module 3-3C includes a polishing table 3-30C, a top ring 3-31C, a polishing-liquid supplying nozzle 3-32C, a dresser 3-33C, and an atomizer 3-34C. The fourth polishing module 3-3D includes a polishing table 3-30D, a top ring 3-31D, a polishing-liquid supplying nozzle 3-32D, a dresser 3-33D, and an atomizer 3-34D.

Each of the first polishing module 3-3A, the second polishing module 3-3B, the third polishing module 3-3C, and the fourth polishing module 3-3D has a same configuration. Thus, only the first polishing module 3-3A will be described below.

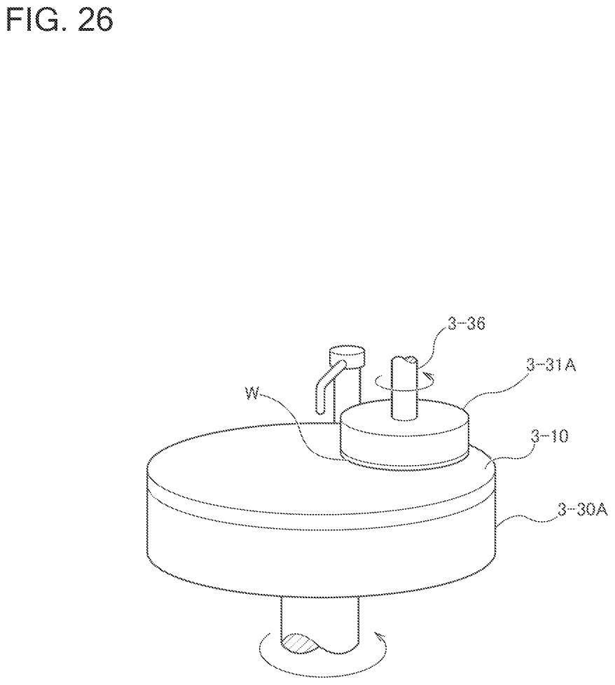

FIG. 26 is a perspective view schematically illustrating the first polishing module 3-3A. The top ring 3-31A is supported by a top-ring shaft 3-36. The polishing pad 3-10 is attached to an upper surface of the polishing table 3-30A. An upper surface of the polishing pad 3-10 forms a polishing surface for polishing a wafer W. Alternatively, fixed abrasive grains may be used instead of the polishing pad 3-10. The top ring 3-31A and the polishing table 3-30A are configured to rotate around a shaft center thereof as illustrated by an arrow. The wafer W is held on a lower surface of the top ring 3-31A by vacuum suction. During polishing, while a polishing liquid is supplied to the polishing surface of the polishing pad 3-10 from the polishing-liquid supplying nozzle 3-32A, the wafer W to be polished is pressed against the polishing surface of the polishing pad 3-10 by the top ring 3-31A so that the wafer W is polished.

<Transfer Mechanism>

Next, a transfer mechanism for transferring a wafer will be described. As illustrated in FIG. 25, a first linear transporter 3-6 is adjacent to the first polishing module 3-3A and the second polishing module 3-3B. The first linear transporter 3-6 is a mechanism for transferring a wafer among four transfer positions (a first transfer position TP1, a second transfer position TP2, a third transfer position TP3, and a fourth transfer position TP4, in order from the side of the loading/unloading unit) arranged along an arrangement direction of the polishing modules 3-3A and 3-3B.

A second linear transporter 3-7 is adjacent to the third polishing module 3-3C and the fourth polishing module 3-3D. The second linear transporter 3-7 is a mechanism for transferring a wafer among three transfer positions (the fifth transfer position TP5, the sixth transfer position TP6, and the seventh transfer position TP7, in order from the side of the loading/unloading unit) arranged along an arrangement direction of the polishing modules 3-3C and 3-3D. The first linear transporter 3-6 and the second linear transporter 3-7 correspond to the first transfer robot that transfer the wafer W before polishing to the polishing unit 3-3 and/or transfers the wafer W after polishing from the polishing unit 3-3.

A wafer is transferred to the polishing modules 3-3A and 3-3B by the first linear transporter 3-6. The top ring 3-31A of the first polishing module 3-3A moves between a polishing position and the second transfer position TP2 by a swinging operation of a top ring head. Accordingly, at the second transport position TP2, a wafer is delivered to the top ring 3-31A. In the same manner, the top ring 3-31B of the second polishing module 3-3B moves between a polishing position and the third transfer position TP3, and a wafer is delivered to the top ring 3-31B at the third transfer position TP3. The top ring 3-31C of the third polishing module 3-3C moves between a polishing position and the sixth transfer position TP6, and a wafer is delivered to the top ring 3-31C at the sixth transfer position TP6. The top ring 3-31D of the fourth polishing module 3-3D moves between a polishing position and the seventh transfer position TP7, and a wafer is delivered to the top ring 3-31D at the seventh transfer position TP7.

At the first transfer position TP1, a lifter 3-11 for receiving a wafer from the transfer robots 3-22 is disposed. A wafer is delivered from the transfer robots 3-22 to the first linear transporter 3-6 via the lifter 3-11. A shutter (not illustrated) is disposed at the partition wall 3-la to be positioned between the lifter 3-11 and the transfer robots 3-22. When a wafer is transferred, the shutter is opened so that the wafer is delivered from the transfer robots 3-22 to the lifter 3-11. A swing transporter 3-12 is disposed among the first linear transporter 3-6, the second linear transporter 3-7, and the cleaning unit 3-4. The swing transporter 3-12 has a hand that is movable between the fourth transfer position TP4 and the fifth transfer position TP5. The swing transporter 3-12 delivers a wafer from the first linear transporter 3-6 to the second linear transporter 3-7. A wafer is transferred to the third polishing module 3-3C and/or the fourth polishing module 3-3D by the second linear transporter 3-7. A wafer having been polished at the polishing unit 3-3 is delivered to the cleaning unit 3-4 via the swing transporter 3-12.

As disclosed in Japanese Patent Laid-Open No. 2010-50436, the first linear transporter 3-6 and the second linear transporter 3-7 each have a plurality of transfer stages (not illustrated). Accordingly, for example, a transfer stage for transferring a wafer before polishing to the transfer positions or a transfer stage for transferring a wafer after polishing from the transfer positions can be used selectively. Therefore, a wafer can be transferred to the transfer position promptly to start polishing, and a wafer after polishing can be delivered to the cleaning unit promptly.

<Cleaning Unit>

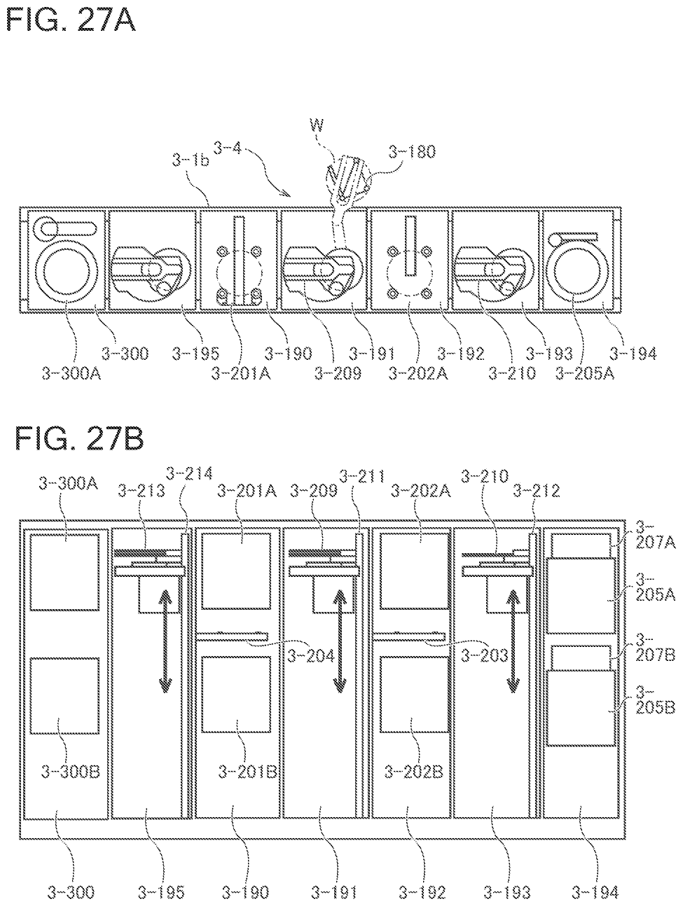

FIG. 27A is a plane view of the cleaning unit 3-4. FIG. 27B is a side view of the cleaning unit 3-4. As illustrated in FIGS. 27A and 27B, the cleaning unit 3-4 is partitioned to a roll cleaning chamber 3-190, a first transfer chamber 1-191, a pen cleaning chamber 3-192, a second transfer chamber 3-193, a drying chamber 3-194, a buff processing chamber 3-300, and a third transfer chamber 3-195.

In the roll cleaning chamber 3-190, an upper roll cleaning module 3-201A and a lower roll cleaning module 3-201B arranged in a longitudinal direction are placed. The upper roll cleaning module 3-201A is placed above the lower roll cleaning module 3-201B. Each of the upper roll cleaning module 3-201A and the lower roll cleaning module 3-201B is a cleaner that cleans a wafer by pressing two rotating roll sponges (first cleaning tools) against individually front and rear surfaces of the wafer while supplying a cleaning liquid to the front and rear surfaces of the wafer. A temporary placing base 3-204 for a wafer is placed between the upper roll cleaning module 3-201A and the lower roll cleaning module 3-201B.

In the pen cleaning chamber 3-192, an upper pen cleaning module 3-202A and a lower pen cleaning module 3-202B arranged in a longitudinal direction are placed. The upper pen cleaning module 3-202A is placed above the lower pen cleaning module 3-202B. Each of the upper pen cleaning module 3-202A and the lower pen cleaning module 3-202B is a cleaner that cleans a wafer by pressing a rotating pencil sponge (a second cleaning tool) against a front surface of a wafer and swinging in a radial direction of the wafer while supplying a cleaning liquid to the front surface of the wafer. A temporary placing base 3-203 for a wafer is placed between the upper pen cleaning module 3-202A and the lower pen cleaning module 3-202B. A temporary placing base 3-180 for the wafer W that is provided in a non-illustrated frame is placed at the side of the swing transporter 3-12. The temporary placing base 3-180 is adjacent to the first linear transporter 3-6 and is positioned between the first linear transporter 3-6 and the cleaning unit 3-4.

In the drying chamber 3-194, an upper drying module 3-205A and a lower drying module 3-205B arranged in a longitudinal direction are placed. The upper drying module 3-205A is separated from the lower drying module 3-205B. Filter fan units 3-207A and 3-207B supplying clean air into the drying modules 3-205A and 3-205B, respectively, are placed on upper parts of the upper drying module 3-205A and the lower drying module 3-205B, respectively.

The upper roll cleaning module 3-201A, the lower roll cleaning module 3-201B, the upper pen cleaning module 3-202A, the lower pen cleaning module 3-202B, the temporary placing base 3-203, the upper drying module 3-205A, and the lower drying module 3-205B are fixed to non-illustrated frames via respective bolts or the like.

In the first transfer chamber 3-191, a first transfer robot (a transfer mechanism) 3-209 that can move upward and downward is placed. In the second transfer chamber 3-193, a second transfer robot 3-210 that can move upward and downward is placed. In the third transfer chamber 3-195, a third transfer robot (a transfer mechanism) 3-213 that can move upward and downward is placed. The first transfer robot 3-209, the second transfer robot 3-210, and the third transfer robot 3-213 are supported by supporting shafts 3-211, 3-212 and 3-214, respectively, that extend in a longitudinal direction, in a movable manner. The first transfer robot 3-209, the second transfer robot 3-210, and the third transfer robot 3-213 each have a driving mechanism such as a motor inside to be movable upward and downward along the supporting shafts 3-211, 3-212, and 3-214, respectively. Similarly to the transfer robot 3-22, the first transfer robot 3-209 has two upper and lower hands. As shown by a dotted line in FIG. 27A, the first transfer robot 3-209 is placed at a position for allowing the lower hand to access the aforementioned temporary placing base 3-180. When the lower hand of the first transfer robot 3-209 accesses the temporary placing base 3-180, a shutter (not illustrated) placed on the partition wall 3-1b opens.

The first transfer robot 3-209 operates so as to transfer the wafer W among the temporary placing base 3-180, the upper roll cleaning module 3-201A, the lower roll cleaning module 3-201B, the temporary placing base 3-204, the temporary placing base 3-203, the upper pen cleaning module 3-202A and the lower pen cleaning module 3-202B. The first transfer robot 3-209 uses the lower hand to transfer a wafer before cleaning (a wafer with slurry adhered), and uses the upper hand to transfer a wafer after cleaning.

The second transfer robot 3-210 operates so as to transfer the wafer W among the upper pen cleaning module 3-202A, the lower pen cleaning module 3-202B, the temporary placing base 3-203, the upper drying module 3-205A, and the lower drying module 3-205B. Since the second transfer robot 3-210 transfers only a cleaned wafer, the second transfer robot 210 has only one hand. The transfer robot 3-22 illustrated in FIG. 25 uses the upper hand to take out a wafer from the upper drying module 3-205A or the lower drying module 3-205B and return the wafer to the wafer cassette. When the upper hand of the transfer robot 3-22 accesses the drying modules 3-205A and 3-205B, a shutter (not illustrated) placed on the partition wall 3-1a opens.

The buff processing chamber 3-300 is provided with an upper buff processing module 3-300A and a lower buff processing module 3-300B. The third transfer robot 3-213 operates so as to transfer the wafer W among the upper roll cleaning module 3-201A, the lower roll cleaning module 3-201B, the temporary placing base 3-204, the upper buff processing module 3-300A, and the lower buff processing module 3-300B. The third transfer robot 3-213 has two upper and lower hands. The first transfer robot 3-209 of the cleaning unit 3-4 transfers the wafer W among the upper roll cleaning module 3-201A, the lower roll cleaning module 3-201B, the upper pen cleaning module 3-202A, the lower pen cleaning module 3-202B, the temporary placing base 3-203, and the temporary placing base 3-204. The second transfer robot 3-210 transfers the wafer W among the upper pen cleaning module 3-202A, the lower pen cleaning module 3-202B, the upper drying module 3-205A, the lower drying module 3-205B, and the temporary placing base 3-203. The third transfer robot 3-213 transfers the wafer W among the upper roll cleaning module 3-201A, the lower roll cleaning module 3-201B, the upper buff processing module 3-300A, the lower buff processing module 3-300B, and the temporary placing base 3-204, and corresponds to the second transfer robot differing from the first transfer robot.

The pressure relationship among the chambers is set to hold the buff processing chamber 3-300<the third transfer chamber 3-195>the roll cleaning chamber 3-190<the first transfer chamber 3-191>the pen cleaning chamber 3-192<the second transfer chamber 3-193>the drying chamber 3-194. That is, pressures in all of the first transfer chamber 3-191, the second transfer chamber 3-193, and the third transfer chamber 3-195 are higher than those in the buff processing chamber 3-300, the cleaning chambers 3-190 and 3-192 or the drying chamber 3-194, which are adjacent thereto, relatively. The pressure in the first transfer chamber 3-191 is higher than that in the polishing unit 3-3. Non-illustrated shutters are placed at respective wall surfaces of the buff processing chamber 3-300, the roll cleaning chamber 3-190, the pen cleaning chamber 3-192, and the drying chamber 3-194, which face the transfer chambers. When the shutters open, the transfer robots 3-209, 3-210, and 3-213 deliver the substrate among the buff processing chamber 3-300, the roll cleaning chamber 3-190, the pen cleaning chamber 3-192, and the drying chamber 3-194. Even when the shutters open, the above pressure relationship is maintained. Thus, airflow is always generated from the transfer chambers to the buff processing chamber 3-300, the cleaning chambers 3-190, 3-192 or the drying chamber 3-194 by the transfer robots transferring a substrate. Accordingly, contaminated atmospheres in the buff processing chamber 3-300, the cleaning chambers 3-190, 3-192 and the drying chamber 3-194 are prevented from being discharged to the outside.

The polishing unit 3-3 uses a polishing liquid, particularly, and the buff processing chamber 3-300 also uses a polishing liquid as a buff processing liquid in some cases. Therefore, the above pressure balance prevents particle components in the polishing unit 3-3 from flowing into the first transfer chamber 3-191, and further prevents particle components in the buff processing chamber 3-300 from flowing into the third transfer chamber. In this way, increase in inner pressures in the transfer chambers adjacent to the unit or the processing chambers using polishing liquids allows the cleanness in the transfer chambers, the cleaning chambers, and the drying chamber to be maintained and the substrate from being contaminated. Unlike the example in FIG. 27, when the polishing unit 3-3, the roll cleaning chamber 3-190, the pen cleaning chamber 3-192, the drying chamber 3-194 and the buff processing chamber 3-300 are directly adjacent without a transfer chamber, the pressure balance among the chambers is set to hold the drying chamber 3-194>the roll cleaning chamber 3-190 and the pen cleaning chamber 3-192>the buff processing chamber 300 the polishing unit 3-3.

Next, descriptions will be given of transfer of a wafer polished by the polishing unit 3-3 to which a buff process, cleaning with a roll sponge, cleaning with a pencil sponge, and drying are performed, in this order.

First, the lower hand of the first transfer robot 3-209 receives the wafer W from the temporary placing base 3-180. The lower hand of the first transfer robot 3-209 places the wafer W on the temporary placing base 3-204. The lower hand of the third transfer robot 3-213 transfers the wafer W to either the upper buff processing module 3-300A or the lower buff processing module 3-300B. After the buff process, the upper hand of the third transfer robot 3-213 transfers the wafer W to either the upper roll cleaning module 3-201A or the lower roll cleaning module 3-201B. After the roll cleaning, the upper hand of the first transfer robot 3-209 transfers the wafer W to the upper pen cleaning module 3-202A and the lower pen cleaning module 3-202B. After the pen cleaning, the second transfer robot 3-210 transfers the wafer W to either the upper drying module 3-205A or the lower drying module 3-205B. The transfer route described here is just an example, and not limited to this. For example, the wafer W does need to be transferred first to the upper buff processing module 3-300A or the lower buff processing module 3-300B. For example, the wafer W may be transferred to be subject to roll cleaning, buffing, pen cleaning, and drying, in this order. The cleaning properties of the individual modules are combined to clean the surface of the wafer W finally.

For example, when drying is performed after roll cleaning without performing pen cleaning, the temporary placing base 3-203 can be used for a base for delivering the wafer W from the first transfer chamber 3-191 to the second transfer chamber 3-193. The temporary placing base 3-203 may be omitted when not needed.

Each of the buff processing chamber 3-300, the roll cleaning chamber 3-190, the pen cleaning chamber 3-192, and the drying chamber 3-194 may have two upper and lower modules. In this case, the continuously delivered wafers W are sorted for the two upper and lower modules and the plurality of the wafers W are processed in parallel so that throughput can be improved. For example, one wafer W is processed only by the upper module while the succeeding wafer W is processed only by the lower module. That is, the present embodiment has a plurality of cleaning lines. The cleaning line refers to a movement route of the wafer W when the wafer W is cleaned by each of the modules in the cleaning unit to which the wafer is fed.

Each of the first linear transporter 3-6 and the second linear transporter 3-7 transfers a wafer before polishing to each transfer position and transfers a wafer after polishing from each transfer position, for polishing at the polishing modules of the polishing unit 3-3. Meanwhile, the transfer robots in the cleaning unit 3-4 receive a wafer from the temporary placing base 3-180 and transfer the wafer among the buff processing chamber 3-300, the roll cleaning chamber 3-190, the pen cleaning chamber 3-192 and the drying chamber 3-194. In this way, each of the first linear transporter 3-6, the second linear transporter 3-7 and the transfer robots in the cleaning unit 3-4 has different roles. Since transfer operations performed by the transfer devices are divided, a transfer waiting time can be reduced and the throughput can be improved. As a result, a problem that corrosion due to a chemical liquid, for example, advances while the wafer W waits to be transferred can be avoided.

As described above, the cleaning unit 3-4 includes the transfer chambers with the transfer robots therein in spaces where the buff processing chamber 3-300, the roll cleaning chamber 3-190, the pen cleaning chamber 3-192, and the drying chamber 3-194 are adjacent. Each of the transfer robots only performs transfer between the adjacent modules. Transfer work of the wafer W can be divided, a transfer waiting time can be reduced, and the throughput can be improved. In particular, leveling processing times in the buff processing chamber 3-300, the roll cleaning chamber 3-190, the pen cleaning chamber 3-192, and the drying chamber 3-194 improves the throughput further.

The upper buff processing module 3-300A and the lower buff processing module 3-300B of the buff processing chamber 3-300 may use different buff processing liquids or different buff pads (which will be described later). In this case, the upper buff processing module 3-300A may perform a first buff process and the lower buff processing module 3-300B may perform a second buff process. For example, the buff polishing process and the buff cleaning process, which will be described later, can be performed continuously.

In the present embodiment, in the cleaning unit 3-4, the buff processing chamber 3-300, the roll cleaning chamber 3-190, and the pen cleaning chamber 3-192 are placed in order from a side far from the loading/unloading unit 3-2, but not limited to this. An arrangement form of the buff processing chamber 3-300, the roll cleaning chamber 3-190, and the pen cleaning chamber 3-192 may be selected as appropriate depending on wafer quality, throughput or the like. Moreover, the present embodiment describes an example where the upper buff processing module 3-300A and the lower buff processing module 3-300B are provided, but not limited to this. Only one of the buff processing modules may be provided.

Furthermore, in the present embodiment, in addition to the buff processing chamber 3-300, the roll cleaning module and the pen cleaning module are described as modules for cleaning the wafer W, but not limited to these modules. Two-fluid jet cleaning (2FJ cleaning) or megasonic cleaning may be performed. In the two-fluid jet cleaning, micro droplets (mist) in high-speed gas are sprayed from a two-fluid nozzle to and collided with the wafer W and a shock wave generated by collision of the micro droplets with the surface of the wafer W is used to remove (clean) particles or the like on the surface of the wafer W. In megasonic cleaning, ultrasonic waves are applied to a cleaning liquid, an acting force caused by vibration acceleration of molecules in the cleaning liquid is applied to adhering particles such as particles to remove the particles. Hereinafter, descriptions are given of the upper buff processing module 3-300A and the lower buff processing module 3-300B. Since each of the upper buff processing module 3-300A and the lower buff processing module 3-300B has a same configuration, only the upper buff processing module 3-300A is described.

<Buff Processing Module>

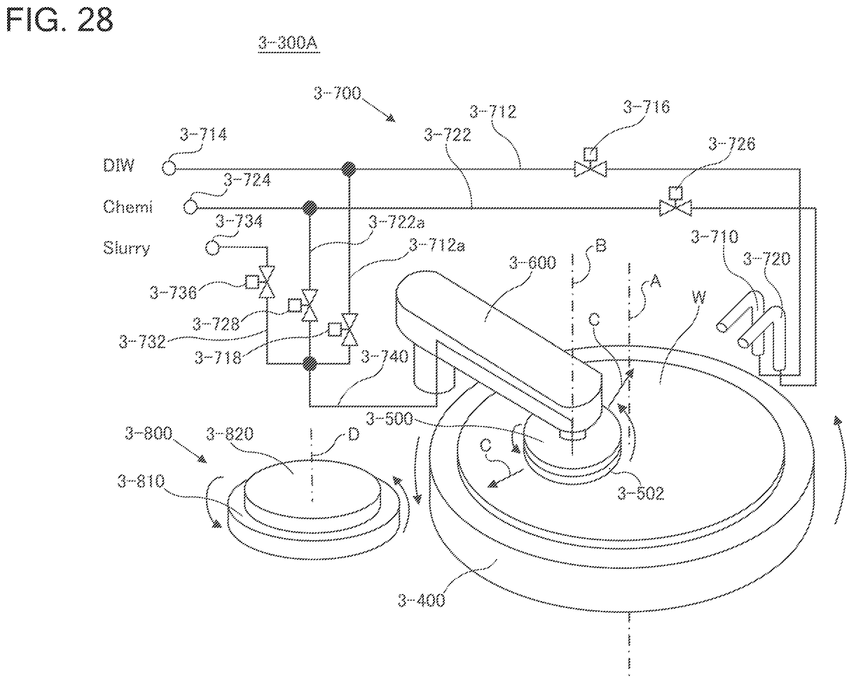

FIG. 28 is a diagram illustrating a schematic configuration of an upper buff processing module. As illustrated in FIG. 28, the upper buff processing module 3-300A includes a buff table 3-400 on which the wafer W is placed, a buff head 3-500 to which a buff pad (a third cleaning tool) 3-502 for performing a buff process to a processing target surface of the wafer W, a buff arm 3-600 that holds the buff head 3-500, a liquid supplying system 3-700 that supplies a buff processing liquid, and a conditioning unit 3-800 that performs conditioning (setting) of the buff pad 3-502. As illustrated in FIG. 28, the buff pad (the third cleaning tool) 3-502 has a smaller diameter than the wafer W. For example, when the wafer W is Φ 300 mm, the buff pad 3-502 is preferably Φ 100 mm or less, and more preferably, Φ 60 to 100 mm. The reason for this is that the buff processing speed of the wafer increases because as the diameter of the buff pad increases, an area ratio to the wafer decreases. On the contrary, as the diameter of the buff pad decreases, the in-plane uniformity of the wafer processing speed is improved. The reason for this is that a processed area per unit becomes smaller. This is effective in a case where the buff arm 3-600 causes relative movement of the buff pad 3-502 such as swinging in the wafer-W plane to process to an entire surface of the wafer, as illustrated in FIG. 28. A buff processing liquid includes at least one of DIW (deionized water), a cleaning chemical liquid and a polishing liquid such as slurry. There are mainly two types of a buffing way. One is a way to remove a contamination such as slurry or a polishing product remaining on a wafer to be processed when contacting with a buff pad. The other is a way to remove a fixed amount of an object to which the above contamination adheres. In the former way, the buff processing liquid is preferably a cleaning chemical liquid or DIW. In the latter way, the buff processing liquid is preferably a polishing liquid. However, in the latter way, the removal amount in the above process is preferably lower than 10 nm, for example, and preferably 5 nm or less in order to maintain the state (the flatness or the remaining film amount) of the processed surface after CMP. In this case, a processing speed does not need to be as high as that in ordinary CMP. In this case, a processing speed may be adjusted by diluting the polishing liquid as appropriate, for example. The buff pad 3-502 is formed of a foamed-polyurethane hard pad, a suede soft pad, or a sponge, for example. The types of the buff pad may be selected as appropriate depending on the material of an object or a condition of a contamination to be removed. For example, when a contamination is buried in a surface of an object, a hard pad that more easily applies a physical force to the contamination, that is, a pad with high hardness and rigidity may be used as a buff pad. On the other hand, for example, when an object is a material with small mechanical strength such as a Low-k film, a soft pad may be used in order to reduce damage on a surface to be processed. When the buff processing liquid is a polishing liquid such as slurry, a removal speed of an object, a removal efficiency of contaminations, presence or absence of a damage are not determined only by hardness and rigidity of the buff pad and may be selected as appropriate. On the surface of the buff pad, a groove shape such as a concentric groove, an XY groove, a swirl groove, and a radial groove, for example, may be formed. Moreover, the buff pad may be formed of a spongy material into which a buff processing liquid can infiltrate, for example, a PVA sponge. Accordingly, flow distribution of a buff processing liquid in the buff pad plane can be unified and a removed contamination in the buff process can be promptly discharged.

The buff table 3-400 has a mechanism of adsorbing the wafer W. The buff table 3-400 is rotatable around the rotation shaft A by a non-illustrated driving mechanism. The buff table 3-400 may cause angle rotating motion (arcuate motion with an angle lower than) 360° or scroll motion (also referred to as orbital motion or circular locus motion) of the wafer W by a non-illustrated driving mechanism. The buff pad 3-502 is attached to a surface of the buff head 3-500 opposite to the wafer W. The buff head 3-500 is rotatable around the rotation shaft B by a non-illustrated driving mechanism. The buff head 3-500 can press the buff pad 3-502 against the processing target surface of the wafer W with a non-illustrated driving mechanism. The buff arm 3-600 can move the buff head 3-500 within a range of a radius or a diameter of the wafer W where the buff pad 3-502 is in contact with the wafer W, as shown by an arrow C. The buff arm 3-600 can swing the buff head 3-500 to a position where the buff pad 3-502 faces the conditioning unit 3-800.

The conditioning unit 3-800 is a member for performing conditioning of a surface of the buff pad 3-502. The conditioning unit 3-800 includes a dressing table 3-810 and a dresser 3-820 that is placed on the dressing table 3-810. The dressing table 3-810 is rotatable around a rotation shaft D by a non-illustrated driving mechanism. The dressing table 3-810 may cause scroll motion of the dresser 3-820 by a non-illustrated driving mechanism. The dresser 3-820 is formed of a diamond dresser that has a surface on which diamond particles are electrodeposited and fixed or has all or part of a contact surface with the buff pad on which diamond abrasive grains are arranged, a brush dresser that has all or part of the contact surface with the buff pad on which resin-made bristles are arranged, or a combination thereof.

In conditioning of the buff pad 3-502, the upper buff processing module 3-300A turns the buff arm 3-600 to a position where the buff pad 3-502 becomes opposite to the dresser 3-802. The upper buff processing module 3-300A rotates the dressing table 3-810 around the rotation shaft D, rotates the buff head 3-500, and presses the buff pad 3-502 against the dresser 3-820 to perform conditioning of the buff pad 3-502. The conditioning condition is a conditioning load of 80 N or less. The conditioning load of 40 N or less is preferable in view of the life of the buff pad 3-502. The buff pad 3-502 and the dresser 3-820 are preferably used with the rotation speed of 500 rpm or less. In the preset embodiment, the processing target surface of the wafer W and the dressing surface of the dresser 3-820 are arranged along a horizontal direction, but are not limited to this. For example, the upper buff processing module 3-300A may place the buff table 3-400 and the dressing table 3-810 in such a way that the processing target surface of the wafer W and the dressing surface of the dresser 3-820 are arranged in a vertical direction. In this case, the buff arm 3-600 and the buff head 3-500 are arranged so as to perform the buff process with the buff pad 3-502 in contact with the vertically arranged processing target surface of the wafer W, and perform the conditioning process with the buff pad 3-502 in contact with the vertically arranged dressing surface of the dresser 3-820. Further, either the buff table 3-400 or the dressing table 3-810 may be arranged in the vertical direction and the whole or part of the buff arm 3-600 may rotate in such a way that the buff pad 3-502 placed on the buff arm 3-600 becomes opposite to the table surfaces.

The liquid supplying system 3-700 includes a deionized-water nozzle 3-710 for supplying deionized water (DIW) to the processing target surface of the wafer W. The deionized-water nozzle 3-710 is connected to a deionized-water supplying source 3-714 via a deionized-water pipe 3-712. The deionized-water pipe 3-712 is provided with an opening and closing valve 3-716 that can open and close the deionized-water pipe 3-712. The control device 3-5 controls opening/closing of the opening and closing valve 3-716 to supply deionized water to the processing target surface of the wafer W at an arbitrary timing.

Further, the liquid supplying system 3-700 includes a chemical-liquid nozzle 3-720 for supplying chemical liquid (Chemi) to the processing target surface of the wafer W. The chemical-liquid nozzle 3-720 is connected to a chemical-liquid supplying source 3-724 via a chemical-liquid pipe 3-722. The chemical-liquid pipe 3-722 is provided with an opening and closing valve 3-726 that can open and close the chemical-liquid pipe 3-722. The control device 3-5 controls opening/closing of the opening and closing valve 3-726 to supply chemical liquid to the processing target surface of the wafer W at an arbitrary timing.

The upper buff processing module 3-300A can supply deionized water, chemical liquid or a polishing liquid such as slurry, selectively, to the processing target surface of the wafer W through the buff arm 3-600, the buff head 3-500 and the buff pad 3-502. The buff pad 3-502 has at least one through hole through which a buff processing liquid can be supplied.

That is, a branch deionized-water pipe 3-712a is branched from the deionized-water pipe 3-712 at a point between the deionized-water supplying source 3-714 and the opening and closing valve 3-716. A branch chemical-liquid pipe 3-722a is branched from the chemical-liquid pipe 3-722 at a point between the chemical-liquid supplying source 3-724 and the opening and closing valve 3-726. The branch deionized-water pipe 3-712a, the branch chemical-liquid pipe 3-722a, and a polishing-liquid pipe 3-732, which is connected to a chemical-liquid supplying source 3-734, join a liquid supplying pipe 3-740. The branch deionized-water pipe 3-712a is provided with an opening and closing valve 3-718 that can open and close the branch deionized-water pipe 3-712a. The branch chemical-liquid pipe 3-722a is provided with an opening and closing valve 3-728 that can open and close the branch chemical-liquid pipe 3-722a. The polishing-liquid pipe 3-732 is provided with an opening and closing valve 3-736 that can open and close the polishing-liquid pipe 3-732.

A first end of the liquid supplying pipe 3-740 is connected to three system pipes that are the branch deionized-water pipe 3-712a, the branch chemical-liquid pipe 3-722a, and the polishing-liquid pipe 3-732. The liquid supplying pipe 3-740 extends through the inside of the buff arm 3-600, the center of the buff head 3-500, and the center of the buff pad 3-502. A second end of the liquid supplying pipe 3-740 opens to the processing target surface of the wafer W. The control device 3-5 controls opening/closing of the opening and closing valve 3-718, the opening and closing valve 3-728 and the opening and closing valve 3-736 to supply the surface of the wafer W with one of deionized water, a chemical liquid, a polishing liquid such as slurry, or a combined liquid of an arbitrary combination of them at an arbitrary timing.

The upper buff processing module 3-300A supplies a processing liquid to the wafer W through the liquid supplying pipe 3-740, rotates the buff table 3-400 around the rotation shaft A, presses the buff pad 3-502 against the processing target surface of the wafer W, and rotates the buff head 3-500 around the rotation shaft B to swing the buff head 500 in a direction of the arrow C so that a buff process can be performed to the wafer W. The buff process condition is a pressure of 3 psi or less, preferably 2 psi or less, considering damage reduction of the wafer W, although the buff process is basically to remove defects by mechanical action. The rotation speed of the wafer W and the buff head 3-500 is preferably 1000 rpm or less, considering in-plane distribution of a buff processing liquid. The moving speed of the buff head 3-500 is 300 mm/sec or less. However, an appropriate distribution of the moving speed differs depending on the rotation speed of the wafer W and the buff head 3-500 and the moving distance of the buff head 3-500. Accordingly, the moving speed of the buff head 3-500 in the wafer-W plane is preferably variable. A varying manner of the moving speed in this case is preferably a manner in which the swinging distance in the wafer-W plane is divided into a plurality of sections and the moving speed is set for each section, for example. The flow amount of the buff processing liquid is preferably large to keep the sufficient in-plane distribution of the processing liquid on the wafer even when the wafer W and the buff head 3-500 rotate at a high speed. However, increase in the flow amount of the processing liquid causes increases in the processing cost. The flow amount is 1000 ml/min or less, and is preferably 500 ml/min or less.

The buff process here includes at least one of a buff polishing process and a buff cleaning process.

The buff polishing process is a process of moving the wafer W relatively to the buff pad 3-502 while keeping the buff pad 3-502 in contact with the wafer W, interposing a polishing liquid such as slurry between the wafer W and the buff pad 3-502 to perform polishing and removing to the processing target surface of the wafer W. In the buff polishing process, a physical acting force that is larger than the physical acting force applied to the wafer W by the roll sponge in the roll cleaning chamber 3-190 or the physical acting force applied to the wafer W by the pen sponge in the pen cleaning chamber 3-192 can be applied to the wafer W. Through the buff polishing process, a surface layer part with a contamination can be removed, a part that the polishing unit 3-3 has failed to remove in main polishing can be additionally removed, or the morphology after the main polishing can be improved.

The buff cleaning process is a process of moving the wafer W relatively to the buff pad 3-502 while keeping the buff pad 3-502 in contact with the wafer W, interposing a cleaning processing liquid (a chemical liquid, or a chemical liquid and deionized water) between the wafer W and the buff pad 3-502 to remove a contamination on the surface of the wafer W or reform the processing target surface. In the buff cleaning process, a physical acting force that is larger than the physical acting force applied to the wafer W by the roll sponge in the roll cleaning chamber 3-190 or the physical acting force applied to the wafer W by the pen sponge in the pen cleaning chamber 3-192 can be applied to the wafer W. In the buff cleaning processing, adhesive particles that a soft material such as a PVA sponge cannot remove or a contamination buried in a substrate surface can be removed.

That is, in the polishing apparatus 3-1000 in the present embodiment, some cleaning modules (the upper buff processing module 3-300A and the lower buff processing module 3-300B) of the plurality of cleaning modules have a function of cleaning the wafer W by moving the wafer W relatively to the cleaning tool while keeping the cleaning tool in contact with the wafer W at a pressure higher than that in the other cleaning modules (the upper roll cleaning module 3-201A, the lower roll cleaning module 3-201B, the upper pen cleaning module 3-202A, and the lower pen cleaning module 3-202B).

As described above, the polishing apparatus 3-1000 in the present embodiment includes the cleaning modules (the upper buff processing module 3-300A and the lower buff processing module 3-300B) providing large mechanical action. Therefore, the polishing apparatus with improved cleaning performance can be provided.

More specifically, in the upper roll cleaning module 3-201A and the lower roll cleaning module 3-201B, a pressure when the roll sponge (the first cleaning tool) is pressed against the wafer W is normally less than 1 psi.

In the upper pen cleaning module 3-202A and the lower pen cleaning module 3-202B, a pressure when the pencil sponge (the second cleaning tool) is pressed against the wafer W is normally less than 1 psi.

On the other hand, the upper buff processing module 3-300A and the lower buff processing module 3-300B have a function of cleaning the wafer W by moving the wafer W relatively to the buff pad 3-502 while keeping the buff pad 3-502 (the third cleaning tool) in contact with the wafer W, for example, at 1 to 3 psi.

Therefore, since the polishing apparatus 3-1000 in the present embodiment includes the cleaning modules (the upper buff processing module 3-300A and the lower buff processing module 3-300B) providing mechanical action larger than those in conventional polishing apparatuses, the cleaning performance can be improved.

When the upper buff processing module 3-300A or the lower buff processing module 3-300B is provided in the polishing unit 3-3, increase in a processing time in the polishing unit 3-3 may affect WPH (Wafers Per Hour). In contrast, in the present embodiment, since the upper buff processing module 3-300A and the lower buff processing module 3-300B are provided in the cleaning unit 3-4, rate controlling in the polishing unit 3-3 can be decreased and decrease in WPH can be suppressed.

<Whole Flowchart>

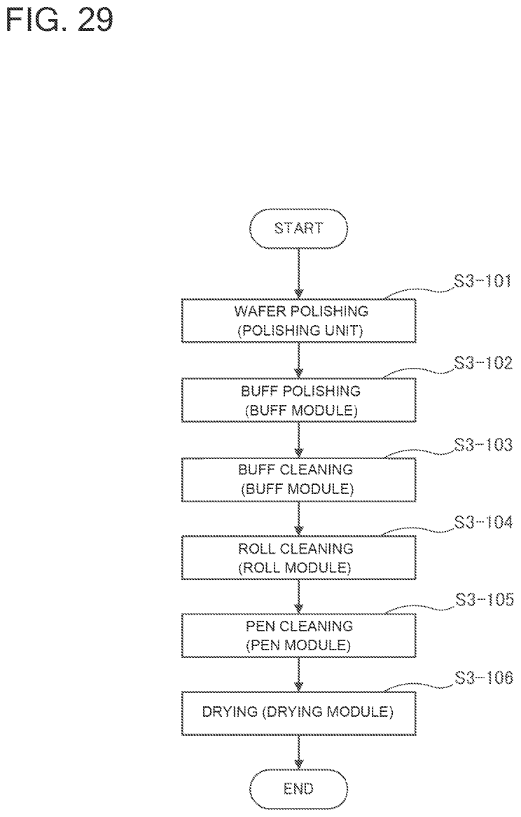

Next, the processing method in the polishing apparatus 3-1000 will be described. FIG. 29 is a diagram illustrating an example of the processing method in the polishing apparatus 3-1000 of the present embodiment. In FIG. 29, the flow in the processing method in the whole polishing apparatus 3-1000 will be described simply.

As illustrated in FIG. 29, first in the polishing method for an object, the polishing unit 3-3 polishes the wafer W (step S3-101). Subsequently, in the processing method, the wafer W polished by the polishing unit 3-3 is transferred to the buff processing chamber 3-300 and the upper buff processing module 3-300A or the lower buff processing module 3-300B performs finish polishing to the wafer W (light polishing) (step S3-102).

Subsequently, in the processing method, the upper buff processing module 3-300A or the lower buff processing module 3-300B performs buff cleaning (a third cleaning step) to the wafer W (step S3-103). The processing method includes a plurality of cleaning steps. The buff cleaning to the wafer W is a part of the plurality of cleaning steps. In the buff cleaning of wafer W, while the cleaning tool (the buff pad 3-502) is kept in contact with the wafer W, the wafer W is moved relatively with the cleaning tool so that the wafer W is cleaned. The buff polishing (step S3-102) and the buff cleaning (step S3-103) may be performed continuously in one buff processing module or performed serially in the two upper and lower buff processing modules.

Subsequently, in the processing method, the wafer W is transferred to the roll cleaning chamber 3-190, and the upper roll cleaning module 3-201A or the lower roll cleaning module 3-201B performs roll cleaning (a first cleaning step) to the wafer W (step S3-104). In the roll cleaning, while a cleaning tool (a roll sponge) is kept in contact with the wafer W at a pressure lower than that in the buff cleaning, the wafer W is moved relatively with the cleaning tool so that the wafer W is cleaned.

Subsequently, in the processing method, the wafer W is transferred to the pen cleaning chamber 3-192, and the upper pen cleaning module 3-202A or the lower pen cleaning module 3-202B performs pen cleaning (a second cleaning step) to the wafer W (step S3-105). In the pen cleaning, while a cleaning tool (a pen sponge) is kept in contact with the wafer W at a pressure lower than that in the buff cleaning, the wafer W is moved relatively with the cleaning tool so that the wafer W is cleaned.

Subsequently, in the processing method, the wafer W is transferred to the drying chamber 3-194, and the upper drying module 3-205A or the lower drying module 3-205B dries the wafer W (step S3-106), and the wafer W is taken out to end the process.

As described above, the processing method of the present embodiment includes the plurality of cleaning steps, and some of the cleaning steps include a cleaning step (the buff cleaning step) providing mechanical action larger than those in conventional polishing apparatuses. Therefore, the cleaning performance can be improved compared to the conventional apparatuses.

In the example of FIG. 29, the buff polishing step is performed after the polishing step by the polishing unit 3-3. However, the buff processing step may be omitted and the order of the buff cleaning step, the roll cleaning step and the pen cleaning step may be changed arbitrarily.

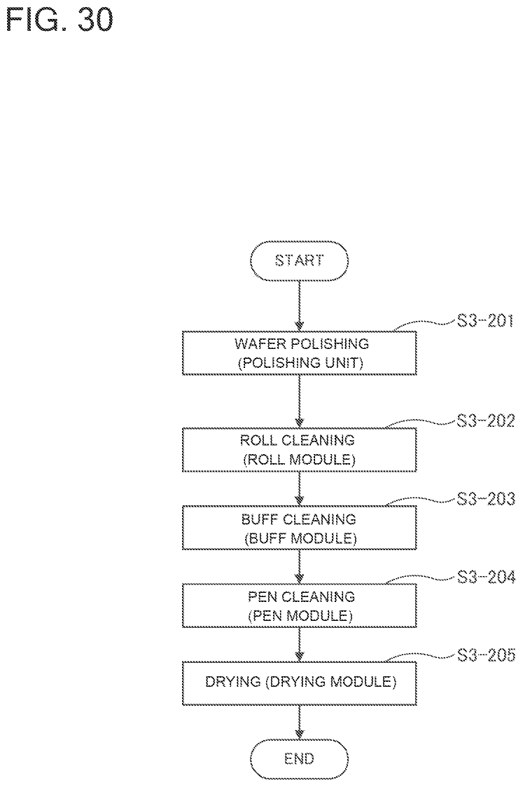

For example, FIG. 30 is a diagram illustrating an example of the processing method in the polishing apparatus 3-1000 of the present embodiment. In FIG. 30, the flow in the processing method in the whole polishing apparatus 3-1000 will be described simply.

As illustrated in FIG. 30, first, in the processing process, the polishing unit 3-3 polishes the wafer W (step S3-201). Subsequently, in the processing method, the wafer W polished by the polishing unit 3-3 is transferred to the roll cleaning chamber 3-190, and the upper roll cleaning module 3-201A or the lower roll cleaning module 3-201B performs roll cleaning (a first cleaning step) of the wafer W (step S3-202). In the roll cleaning, the wafer W is cleaned by moving the wafer W relatively to a cleaning tool (a roll sponge) while keeping the wafer W in contact with the cleaning tool. The reason why the roll cleaning is followed by the buff cleaning is slurry or polishing residues are prevented from entering the buff processing module to maintain the cleaning performance. An object of the buff cleaning is to remove a contamination that is difficult to be removed by a conventional cleaning method. Thus, when a contamination that can be removed by the conventional cleaning method is removed in advance, an influence of reverse contamination by slurry or polishing residues can be minimized so that the cleaning performance is maintained.

Subsequently, in the processing method, the wafer W is transferred to the buff processing chamber 3-300, and the upper roll cleaning module 3-201A or the lower roll cleaning module 3-201B performs roll cleaning (a third cleaning step) of the wafer W (step S3-202). The buff cleaning of the wafer W is part of the plurality of cleaning steps. In the buff cleaning, the wafer W is moved relatively with the cleaning tool (the buff pad 3-502) while the cleaning tool is kept in contact with the wafer W at a higher pressure than those in the other cleaning steps (the roll cleaning, the pen cleaning) so that the wafer W is cleaned.

Subsequently, in the processing method, the wafer W is transferred to the pen cleaning chamber 3-192, and the upper pen cleaning module 3-202A or the lower pen cleaning module 3-202B performs pen cleaning (a second cleaning step) to the wafer W (step S3-204). In the pen cleaning, while a cleaning tool (a pen sponge) is kept in contact with the wafer W, the wafer W is moved relatively with the cleaning tool so that the wafer W is cleaned.

Subsequently, in the processing method, the wafer W is transferred to the drying chamber 3-194, and the upper drying module 3-205A or the lower drying module 3-205B dries the wafer W (step S3-205), and the wafer W is taken out to end the process.

<Flowchart of Buff Module>

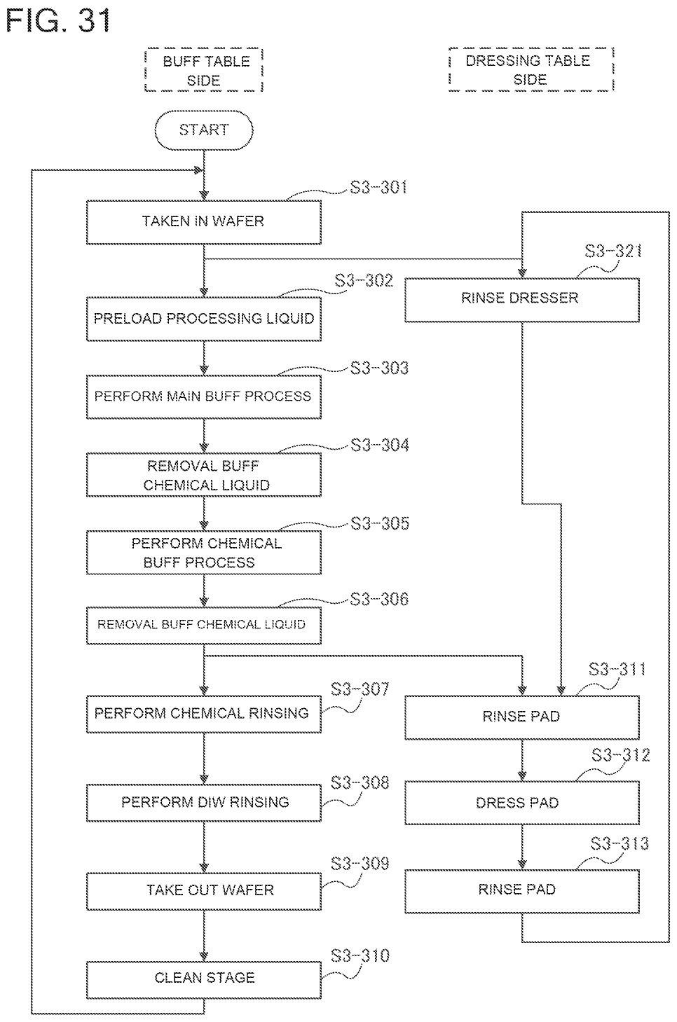

Next, the processing method in the upper buff processing module 3-300A of the polishing apparatus 3-1000 will be described in detail. FIG. 31 is a diagram illustrating an example of the processing method of the present invention.

As illustrated in FIG. 31, first, in a process at the buff table 3-400 side in the processing method, the wafer W is placed on the buff table 3-400 (step S3-301). A buffer may be provided on a stage of the buff table 3-400. Thus, the wafer W may be adsorbed directly to the stage of the buff table 3-400 or the wafer W may be adsorbed via the buffer. The buffer is made of an elastic material such as polyurethane, nylon, fluorine-based rubber or silicone rubber, for example, and is in close contact with the stage of the buff table 3-400 via an adhesive resin layer. Since the buffer has elasticity, the buffer prevents the wafer from being damaged or buffers influences of unevenness on the surface of the buff table 3-400 to the buff process.

Subsequently, in the processing method, a buff processing liquid is supplied in advance (preloaded) to the surface of the wafer (step S3-302). Supply of a buff processing liquid to the processing target surface of the wafer W in advance enables liquid replacement on the processing target surface of the wafer W, for example. Liquid replacement refers to replacement of a liquid remaining on the processing target surface of the wafer W before the buff process, which may be DIW remaining on the processing target surface of the wafer W after polishing in the polishing unit 3-3 or in the previous cleaning process, with a buff processing liquid, for example. When the buff processing liquid is a polishing liquid including abrasive grains, for example, diluting the buff processing liquid with deionized water generates aggregation of the abrasive grains in the polishing liquid to increase the risk of forming a scratch on the processed surface. Accordingly, the present advance supply process allows the aggregation of the abrasive grains to be discharged to the outside of the wafer W before the buff process so that the above risk can be reduced. Further, supply of the buff processing liquid to the processing target surface of the wafer W in advance can stabilize buffing performance at the start of the buff process. More specifically, reduction in the processing speed or cleaning performance due to a shortage of the buff processing liquid can be prevented. Examples of a method of the present advance supply process include a method of supplying the buff processing liquid using an external supplying nozzle (in the case of a chemical liquid, the chemical-liquid nozzle 3-720) and a method of supplying the buff processing liquid through the branch chemical-liquid pipe 3-722a or the polishing-liquid pipe 3-732. In the former method, a supply position of the buff processing liquid may be moved in the wafer-W plane by swinging the external supplying nozzle. In the latter method, the buff processing liquid is supplied while the buff pad 3-502 is in non-contact with the wafer W, for example, by moving the buff head 3-500 to a position near the rotation center of the wafer W. At that time, the buff processing liquid may be supplied while moving the buff head 3-500 in the wafer-W plane. The moving form is, for example, circular arc movement, linear movement, single-direction movement, reciprocating movement or a combination thereof. The moving speed of the buff head 3-500 in wafer-W plane may be either a constant speed of programmed movement or a variable speed.

Subsequently, in the processing method, a main buff process is performed (step S3-303). In the main buff process, at least one of DIW, a cleaning chemical liquid, or a polishing liquid as a buff processing liquid is supplied to the processing target surface of the wafer W. Although the cleaning chemical liquid varies depending on the process, the main buff process may be performed using a chemical liquid used in cleaning at a later stage, for example. In this case, with the mechanical action in the buff process (a higher pressure and a higher-speed rotation than in the cleaning), the cleaning performance increases. A polishing liquid to be used differs depending on the process. For example, a liquid obtained by diluting the slurry used in the polishing unit 3-3 may be used. When a polishing liquid including abrasive grains is supplied, the processing target surface of the wafer W is polished by the abrasive grains in the polishing liquid so that a defect (a flaw, a failure) that has been generated in the polishing before the buff process can be removed.

In this state, with a predetermined pressure of the buff pad 3-502 to the wafer W, a predetermined rotation speed of the buff pad 3-502 and the wafer W, a predetermined moving pattern and predetermined moving speed distribution of the buff arm 3-600 on the wafer W, the buff process is performed. For the pressure, the rotation speed and the moving speed, a plurality of steps may be performed. For example, in a first main buff processing step, a buff process may be performed under a high pressure condition and in a second buff processing step, a buff process may be performed at a lower pressure than in the first step. Accordingly, a contamination to be removed can be removed intensively in the first step, and a finishing process can be performed in the second step so that an efficient buff process can be performed. Before and after the main buff process, a RampUp step or a RampDown step may be introduced. For example, the RampUp step is a step of bringing the buff pad 3-502 into contact with the wafer W at a lower pressure than in the later main buff step, or rotating the buff head 3-500 and the buff table 3-400 at a low speed. The RampUp step assumes a state where a touchdown of the buff head 3-500 starts the buff process. If the buff process suddenly starts under the condition of a high pressure and a high-speed rotation, there is a possibility of occurrence of a scratch. To avoid such a possibility, the RampUp step is introduced. Subsequently, in the main buff process, a main buff step is performed. The main buff step is a step of bringing the buff pad 3-502 into contact with the wafer W at a higher pressure than in the RampUp step and rotating the buff head 3-500 and the buff table 3-400 at a high speed. The RampDown step is a step of bringing the buff pad 3-502 into contact with the wafer W at a lower pressure than in the main buff step and rotating the buff head 3-500 and the buff table 3-400 at a low speed. Under such pressure and rotation condition, the buff head 3-500 moves horizontally in the wafer-W plane. Depending on the rotation speed of the wafer W and the buff head 3-500 and the moving distance of the buff head 3-500, appropriate distribution of the moving speed varies. Accordingly, the moving speed of the buff head 3-500 in the wafer-W plane is preferably variable. A varying manner of the moving speed in this case is preferably a manner in which the swinging distance in the wafer-W plane is divided into a plurality of sections and the moving speed is set for each section, for example.

When the buff processing liquid is a polishing liquid including abrasive grains, particularly, the RampDown step may cause a scratch (damage) in the later step of washing off the buff processing liquid, because aggregation of the abrasive grains are generated by dilution of the slurry depending on the slurry. Therefore, when the pressure of the buff pad 3-502 applied to the wafer W is reduced in advance, occurrence of a scratch particularly in a transition state to a next step can be suppressed. The RampUp step and the RampDown step are not essential and may be omitted. When the processing target surface of the wafer W is polished by supplying slurry in the main buff process, the polishing amount is less than 10 nm, and preferably 5 nm or less, as described above.

Subsequently, in the processing method, a buff-processing-liquid washing off process is performed (step S3-304). In the buff-processing-liquid washing off process, the buff processing liquid in the main buff process is removed from the processing target surface of the wafer W (and the buff pad 3-502). When a chemical buff process is to be performed at a later stage, particularly, the buff-processing-liquid washing off process is performed to prevent the buff processing liquid used in the main buff process from being mixed in the later chemical buff processing. The buff-processing-liquid washing off process is performed in a state where, while deionized water is supplied to the wafer W, the buff pad 3-502 is brought into contact with the wafer W, the buff head 3-500 and the buff table 3-400 are rotated and the buff arm 3-600 swings. The buffing condition (a pressure, a rotation speed of the buff pad and the wafer, and the moving condition of the buff arm) may be different from that in the main buff process. For example, a pressure of the buff pad 3-502 against the wafer W is preferably smaller than that in the condition of the main buff process. An external supplying nozzle may supply deionized water to the wafer W. However, more preferably, the through hole of the buff pad, or the thorough hole in combination with the external supplying nozzle supplies deionized water. Thereby, particularly, the buff processing liquid is effectively removed from the contact area of the buff pad 3-502 with the wafer W.

Subsequently, in the processing method, a chemical buff process is performed (step S3-305). The chemical buff process is a process of removing the buff processing liquid (particularly, slurry) used in the main buff process from the processing target surface of the wafer W (and the buff pad 3-502). Furthermore, the chemical buff process assists the main buff process in removing a defect when all defects to be removed have failed to be removed in the main buff process. When the buff processing liquid used in the main buff process is a cleaning chemical liquid, the present step can be skipped, because this is just repetition of the same process. Even when the buff processing liquid used in the main buff process is a cleaning chemical liquid, the chemical buff process may be performed using a buff processing liquid different from that in the main buff process. The buffing condition (a pressure, the rotation speed of the buff pad and the wafer and the moving condition of the buff arm) may be different from that in the main buff process. For example, in a preferable condition, a pressure of the buff pad 3-502 to the wafer W is smaller than that in the main buff process condition. In this case, re-adhesion of a buff processing liquid having been removed from the wafer W can be reduced.

Subsequently, in the processing method, a buff chemical washing off process is performed (step S3-306). The buff chemical washing off process is a process of removing the buff processing liquid used in the chemical buff process from the processing target surface of the wafer W (and the buff pad 3-502). The buff chemical washing off process is performed while deionized water is supplied to the wafer W, the buff pad 3-502 is brought into contact with the wafer W, the buff head 3-500 and the buff table 3-400 are rotated and the buff arm 3-600 swings. The buffing condition (a pressure, the rotation speed of the buff pad and the wafer and the moving condition of the buff arm) may be different from that in the main buff process. When a later chemical rinsing process or a DIW rinsing process suffices, the present skip may be skipped.

After step S3-305 or step S3-306, the buff head 3-500 moves upward and the buff arm 3-600 turns so that the buff pad 3-502 leaves the processing target surface of the wafer W. In this state, the DIW rinsing (step S3-308) is performed as a process at the buff table 3-400 side. However, before the DIW rinsing, the chemical rising process (step S3-307) may be performed. The chemical rinsing process is performed while the buff table 3-400 is being rotated. Depending on the buff processing liquid, when the DIW rinsing process is started immediately after the chemical buff process, there is a possibility of re-adhesion of a defect that has been removed from the processing target surface of the wafer W in the chemical buff process, due to variation in pH or zeta potential. In the case of such buff processing liquid, when the present step is introduced, the zeta potential is maintained and the removed defect is discharged to the outside of the diameter of the wafer W so that the risk of re-adhesion of the removed defect can be reduced in the following DIW rinsing process.

Subsequently, in the processing method, the DIW rinsing process is performed (step S3-308). The DIW rinsing process is a process of removing the buff processing liquid (particularly, slurry) used in the chemical buff process from the processing target surface of the wafer W (and the buff pad 3-502). The DIW rinsing process is performed while the buff table 3-400 is being rotated.

Subsequently, in the processing method, adsorption of the wafer W in the buff table 3-400 is released and the wafer W is retracted from the buff table 3-400 (step S3-309). Subsequently, in the processing method, the stage of the buff table 3-400 on which the wafer W is placed is cleaned (step S3-310). The cleaning process of the stage is either to clean the stage of the buff table 3-400 directly or to clean the buffer. The cleanliness of the stage surface or the buffer surface can be obtained by cleaning the adsorbing surface of the wafer W on the wafer-W stage of the buff table 3-400. Thus, a rear surface that is opposite to the processing target surface of the wafer W to be processed next can be prevented from being contaminated. The cleaning process of the stage is performed by supplying a fluid (e.g., DIW and a chemical liquid) from the nozzle while rotating the buff table 3-400. When the fluid is a high-pressure fluid (for example, 0.3 MPa), even mechanical action is provided. Thus, the cleaning effect is further improved. To increase the cleaning efficiency, the cleaning process of the stage may be a process of generating ultrasonic waves or cavitation, instead of supplying a fluid from the nozzle.

In the process at the buff table 3-400 side, when another wafer W is processed after step S3-310, the processing method returns to step S3-301.

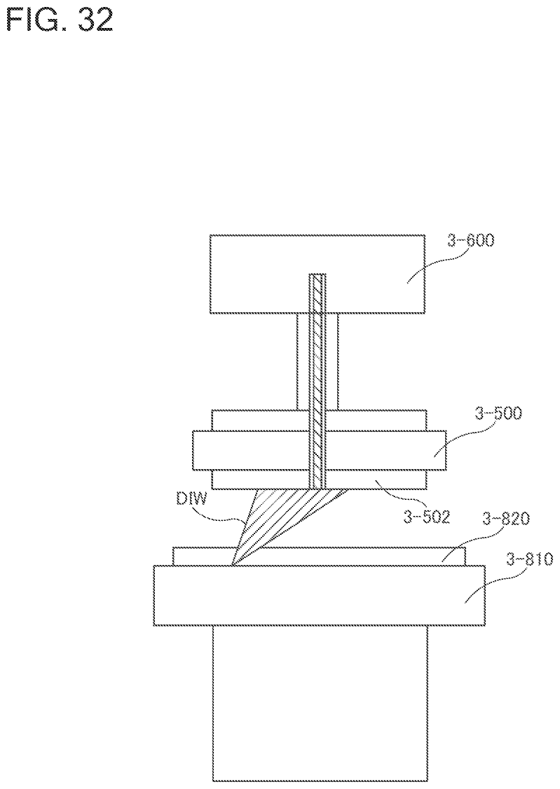

Next, the process performed at the dressing table 3-810 side will be described. After step S3-306, the buff head 3-500 moves upward and the buff arm 3-600 turns so that the buff pad 3-502 leaves the processing target surface of the wafer W to be opposite to the dresser 3-820. In this state, in the processing method, a pad rinsing process is performed (step S3-311). FIG. 32 is a diagram showing an outline of the pad rinsing process. The pad rinsing process is, as illustrated in FIG. 32, for example, a process of performing rough cleaning of a contamination attached to the surface of the buff pad 3-502 by spraying DIW from below while rotating the buff head 3-500 above the dresser 3-820.

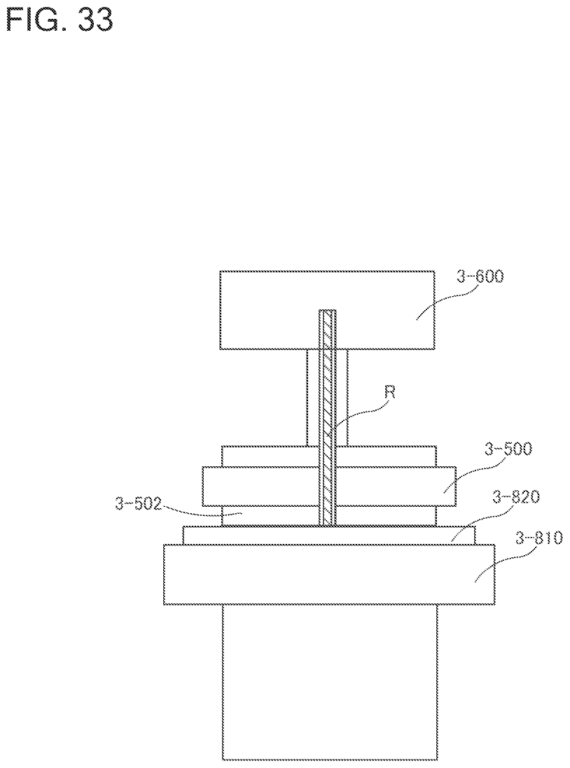

Subsequently, a pad dressing process is performed (step S3-312). FIG. 33 is a diagram showing an outline of the pad dressing process. In the pad dressing process, as illustrated in FIG. 33, for example, conditioning of the surface of the buff pad 3-502 is performed by pressurizing the buff pad 3-502 to the dresser 3-820 while supplying a processing liquid R from the center of the buff head 3-500 and the buff pad 3-502 via the buff arm 3-600, and rotating the buff pad 3-502 and the dresser 3-820. The conditioning condition is a conditioning load of 80 N or less. The conditioning load of 40 N or less is preferable in view of the buff pad life. The buff pad 3-502 and the dresser 3-820 are preferably used with the rotation speed of 500 rpm or less.

Subsequently, a pad rinsing process is performed (step S3-313). In the pad rinsing process, as at step S3-311, while the buff head 3-500 is being rotated above the dresser 3-820, DIW is sprayed from below so that the surface of the buff pad 3-502 is cleaned. The pad rinsing process at this step is a process to remove a dressing residue on the surface of the buff pad 3-502 after the pad dressing process.

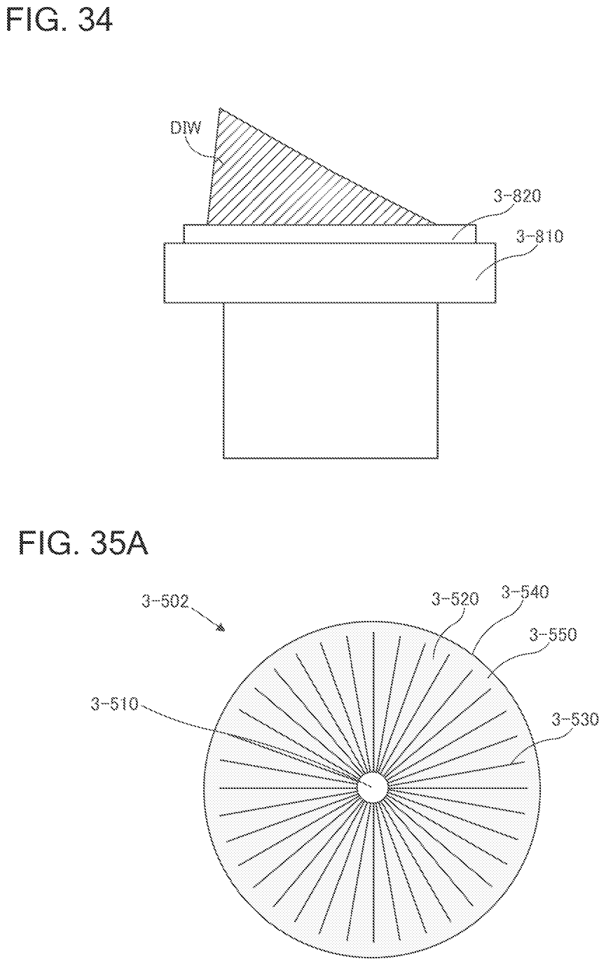

Conditioning of the surface of the buff pad 3-502 is completed by the above processes. To perform a buff process to a next wafer, the buff pad 3-502 moves from a position on the dresser 3-820 to a position on the wafer W in step S3-302, and the buff process is started. During this time, at the dressing table 3-810 side, a dresser rinsing process is performed (step S3-321). FIG. 34 is a diagram showing an outline of the dresser rinsing process. The dresser rinsing process is a process of cleaning the surface of the dresser 3-820 by retracting the buff arm 3-600 from the dresser 3-820, and spraying DIW to the dresser 3-820 while rotating the dressing table 3-810, as illustrated in FIG. 34, for example.

<Buff Pad>

Next, the buff pad 3-502 used in the upper buff processing module 3-300A and the lower buff processing module 3-300B is described.

When buff cleaning or buff polishing is performed using the buff pad 3-502 having a smaller diameter than the wafer W, in order to increase the linear velocity of the buff pad 3-502, the buff pad 3-502 needs to be rotated at a high speed. At that time, a processing liquid supplied from the center of the buff pad 3-502 is easy to scatter by centrifugal force. On the other hand, since the buff pad 3-502 is pressed against the wafer W to perform buff cleaning and buff polishing, the polishing liquid hardly spreads in the buff pad 3-502. Thus, there is a possibility that the polishing liquid does not spread over the processing target surface of the wafer W uniformly. It is preferable that the processing liquid is easy to circulate in the buff pad 3-502 and is difficult to scatter to the outside of the buff pad 3-502. Accordingly, the surface of the buff pad preferably has the aforementioned groove shape and hole, and the like. Specific examples will be described below.

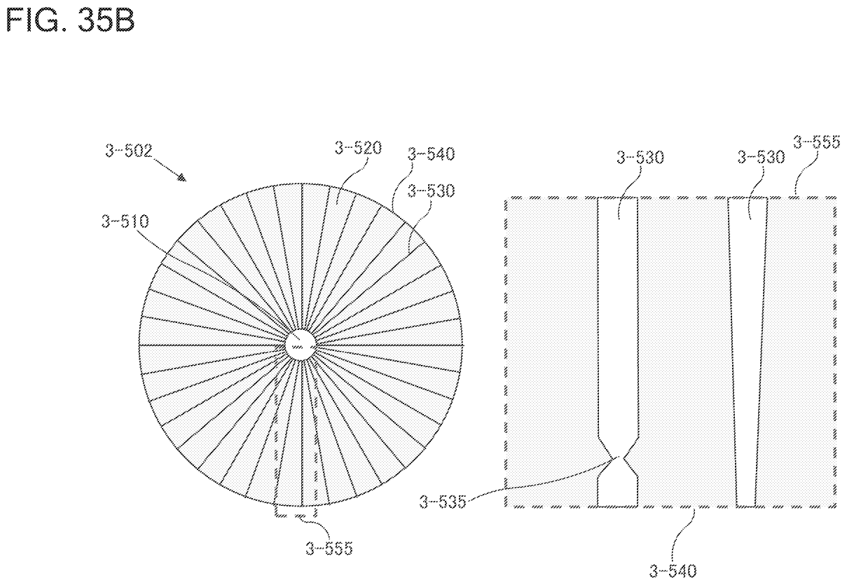

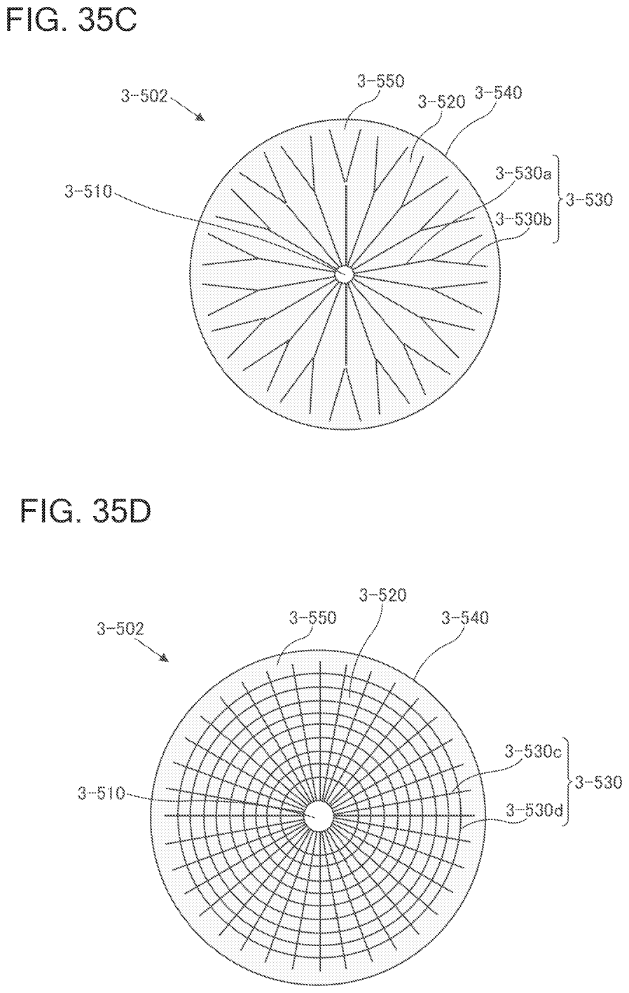

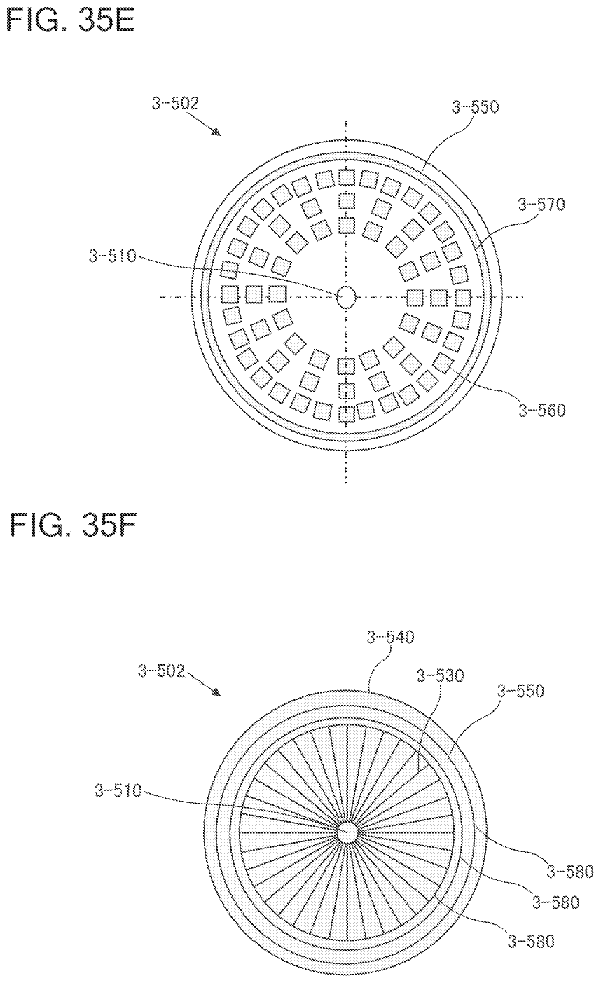

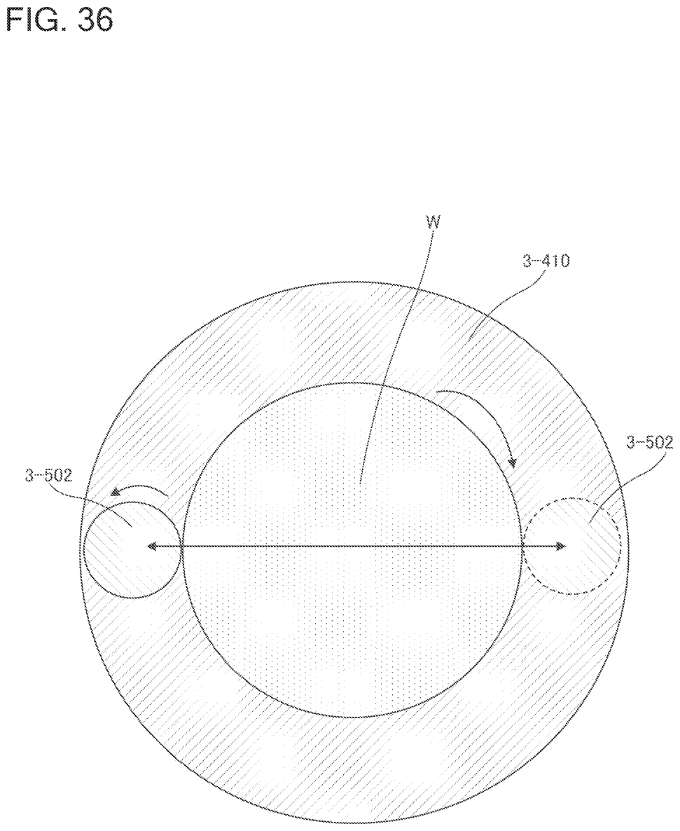

FIGS. 35A to 35F are diagrams illustrating an example of the structure of the buff pad 3-502. FIG. 35A schematically illustrates a processing surface of the buff pad 3-502. As illustrated in FIG. 35A, an opening 3-510 through which a processing liquid flows is formed at the center of the buff pad 3-502. As illustrated in FIG. 35A, a plurality of grooves 3-530 that communicate with the opening 3-510 and radially extend are formed on the processing surface (a surface to contact with the processing target surface of the wafer W) of the buff pad 3-502. The grooves 3-530 do not reach an outer circumferential end 3-540 of the buff pad 3-502 but reach an outer circumferential part 3-550 that is a part inside the outer circumferential end 3-540 of the buff pad 3-502. That is, a first end of the groove 3-530 communicates with the opening 3-510 and a second end of the groove 3-530 communicates with the outer circumferential part 3-550 of the processing surface of the buff pad 3-502.

In the buff pad 3-502 having the above shape, since the grooves 3-530 are formed radially, a processing liquid easily spreads in the buff pad 3-502 by centrifugal force. Further, since the grooves 3-530 reach not the outer circumferential end 3-540 of the buff pad 3-502 but the outer circumferential part 3-550, a processing liquid is difficult to scatter to the outside of the buff pad 3-502.

FIG. 35B schematically illustrates the processing surface of the buff pad 3-502 and the partially enlarged processing surface of the buff pad 3-502 (a part 3-555 shown by a broken line). As illustrated in FIG. 35B, the opening 3-510 through which a processing liquid flows is formed at the center of the buff pad 3-502. As illustrated in FIG. 35B, the plurality of grooves 3-530 that communicate with the opening 3-510 and radially extend are formed on the processing surface of the buff pad 3-502. The grooves 3-530 reach the outer circumferential end 3-540 of the buff pad 3-502. That is, a first end of the groove 3-530 communicates with the opening 3-510 and a second end of the groove 3-530 communicates with the outer circumferential end 3-540 of the buff pad 3-502. In this case, as illustrated in the enlarged view, the groove 3-530 has a constriction part 3-535, which is a part where the groove width is smaller than in other parts, in the vicinity of the outer circumferential end 3-540 of the buff pad 3-502. The groove width of the groove 3-530 decreases toward the outer circumferential end 3-540 of the buff pad 3-502 to form a tapered shape.

In the buff pad 3-502 having the above shape, since the grooves 3-530 are formed radially, a processing liquid easily spreads in the buff pad 3-502 by centrifugal force. Further, since the constriction part 3-535 is formed in the groove 3-530 or the groove 3-530 is tapered, a processing liquid is difficult to scatter to the outside of the buff pad 3-502.

FIG. 35C schematically illustrates the processing surface of the buff pad 3-502. As illustrated in FIG. 35C, the opening 3-510 through which a processing liquid flows is formed at the center of the buff pad 3-502. As illustrated in FIG. 35C, the plurality of grooves 3-530 that communicate with the opening 3-510 and radially extend are formed on the processing surface of the buff pad 3-502. The groove 3-530 includes a groove 3-530a that radially extends and grooves 3-530b that are branched from the groove 3-530a into two and radially extend. The groove 3-530b does not reach the outer circumferential end 3-540 of the buff pad 3-502 but reaches the outer circumferential part 3-550 that is a part inside the outer circumferential end 3-540 of the buff pad 3-502. That is, a first end of the groove 3-530 communicates with the opening 3-510 and a second end of the groove 3-530 communicates with the outer circumferential part 3-550 of the processing surface of the buff pad 3-502.

In the buff pad 3-502 having the above shape, since the grooves 3-530a and 3-530b are formed radially, a processing liquid easily spreads in the buff pad 3-502 by centrifugal force. Further, since the grooves 3-530 reach not the outer circumferential end 3-540 of the buff pad 3-502 but the outer circumferential part 3-550, a processing liquid is difficult to scatter to the outside of the buff pad 3-502. Moreover, in the buff pad 3-502 having the above shape, since the groove 3-530a is branched into the two grooves 3-530b in the outer circumferential part 3-550 of the buff pad 3-502, groove distribution in the inner and outer circumferential parts of the buff pad 3-502 can be equalized.

FIG. 35D schematically illustrates the processing surface of the buff pad 3-502. As illustrated in FIG. 35D, the opening 3-510 through which a processing liquid flows is formed at the center of the buff pad 3-502. As illustrated in FIG. 35D, the grooves 3-530 are formed on the processing surface of the buff pad 3-502. The grooves 3-530 include a plurality of grooves 3-530c that communicate with the opening 3-510 and radially extend and a plurality of grooves 3-530d that are formed concentrically with the buff pad 3-502. The grooves 3-530c do not reach the outer circumferential end 3-540 of the buff pad 3-502 but reach the outer circumferential part 3-550 that is a part inside the outer circumferential end 3-540 of the buff pad 3-502. That is, a first end of the groove 3-530c communicates with the opening 3-510 and a second end of the groove 3-530c communicates with the outer circumferential part 3-550 of the processing surface of the buff pad 3-502.

In the buff pad 3-502 having the above shape, since the grooves 3-530c are formed radially, a processing liquid easily spreads in the buff pad 3-502 by centrifugal force. Further, since the grooves 3-530c reach not the outer circumferential end 3-540 of the buff pad 3-502 but the outer circumferential part 3-550, a processing liquid is difficult to scatter to the outside of the buff pad 3-502. Moreover, in the buff pad 3-502 having the above shape, since the grooves 3-530d are formed concentrically, a processing liquid easily circulates in the buff pad 3-502.

FIG. 35E schematically illustrates the processing surface of the buff pad 3-502. As illustrated in FIG. 35E, the opening 3-510 through which a processing liquid flows is formed at the center of the buff pad 3-502. As illustrated in FIG. 35E, protruding parts 3-560 and 3-570 are formed by emboss processing on the processing surface of the buff pad 3-502. The protruding parts 3-560 are radially formed in an inner circumferential part of the buff pad 3-502. The protruding part 3-570 surrounding the outer circumferential part 3-550 in a circumferential direction is formed in the outer circumferential part 3-550 of the buff pad 3-502.

In the buff pad 3-502 having the above shape, since the protruding parts 3-560 are formed radially, a processing liquid easily spreads in the buff pad 3-502 by centrifugal force. Further, since the protruding part 3-570 surrounding the outer circumferential part 3-550 in the circumferential direction is formed, a processing liquid is difficult to scatter to the outside of the buff pad 3-502.

FIG. 35F schematically illustrates the processing surface of the buff pad 3-502. As illustrated in FIG. 35F, the opening 3-510 through which a processing liquid flows is formed at the center of the buff pad 3-502. As illustrated in FIG. 35F, the plurality of grooves 3-530 that communicate with the opening 3-510 and radially extend are formed on the processing surface of the buff pad 3-502. A few (three in FIG. 35F) grooves 3-580 surrounding the outer circumferential part 3-550 in the circumferential direction are formed in the outer circumferential part 3-550 of the buff pad 3-502. The grooves 3-530 do not reach the outer circumferential end 3-540 of the buff pad 3-502 but reach the innermost groove 3-580. That is, a first end of the groove 3-530 communicates with the opening 3-510 and a second end of the groove 3-530 communicates with the groove 3-580.

In the buff pad 3-502 having the above shape, since the grooves 3-530 are formed radially, a processing liquid easily spreads in the buff pad 3-502 by centrifugal force. Further, since the grooves 3-530 do not reach the outer circumferential end 3-540 of the buff pad 3-502 but communicates with the groove 3-580, a processing liquid remains in the grooves 3-580 and hardly scatters to the outside of the buff pad 3-502.

<Swing of Buff Arm>

Next, detailed descriptions will be given of the swing of the buff arm 3-600 when the buff process is performed in the upper buff processing module 3-300A and the lower buff processing module 3-300B.

FIG. 36 is an explanatory diagram of a swinging range of the buff pad 3-502 by the buff arm 3-600. In the buff process, reciprocating swinging of the buff pad 3-502 to a position where the buff pad 3-502 does not completely overlap with the wafer W (to a position where 100% hangout of the buff pad 3-502 from the wafer W is obtained) can be performed by the buff arm 3-600, as illustrated in FIG. 36. When an overlapping area of the buff pad 3-502 and the wafer W becomes small, the buff pad 3-502 inclines in the outer circumferential part of the wafer W. Thus, uniform contact of the buff pad 3-502 with the wafer W is inhibited. Accordingly, as illustrated in FIG. 36, a ring-shaped supporting guide 3-410 can be placed outside the buff table 3-400. The shape of the supporting guide 3-410 is not limited to the ring shape in FIG. 36. It suffices that the supporting guide 3-410 can support an area where the buff pad 3-502 swings. Also, the supporting guide 3-410 may move relatively to the wafer W.

When the buff arm 3-600 uniformly moves in such a way that the buff pad 3-502 does not overhang the wafer W, the sliding distance of the buff pad 3-502 in the outer circumferential part of the wafer W is shorter than that in the inner circumferential part, resulting in decrease in the removing speed in the buff polishing. In contrast, as illustrated in FIG. 36, reciprocating swinging of the buff pad 3-502 to a position where the buff pad 3-502 does not completely overlap with the wafer W and the buff table 3-400 (to a position where 100% hangout of the buff pad 3-502 from the wafer W is obtained) enables equalization of the sliding distance of the buff pad 3-502 in the outer circumferential part and the inner circumferential part of the wafer W.

A case to provide the supporting guide 3-410 is not limited to the case where the buff pad 3-502 swings to a position where the buff pad 3-502 does not completely overlap with the wafer W. The supporting guide 3-410 may be provided when the buff pad 3-502 swings to a position outside the outer circumferential end of the wafer W.

The position of the supporting guide 3-410 in a high direction can be controlled. Accordingly, for example, when the buff pad 3-502 swings and protrudes from the wafer W, the height of the supporting guide 3-410 can be controlled so as to substantially match the height of the processing target surface of the wafer W. Furthermore, for example, if the height of the supporting guide 3-410 is adjusted to be higher than the height of the processing target surface of the wafer W, the buff pad 3-502 can be prevented from protruding from the wafer W. Moreover, if the height of the supporting guide 3-410 is adjusted to be higher than the height of the processing target surface of the wafer W, a processing liquid to be used for the buff process can be kept on the processing target surface of the wafer W.

In the polishing apparatus 3-1000, the swinging range of the buff pad 3-502 may be divided into arbitrary sections and at least one of the swinging speed of the buff arm 3-600, the rotation speed of the buff head 3-500, the rotation speed of the buff table 3-400, and the press pressure of the buff pad 3-502 to the wafer W can be controlled for each section.

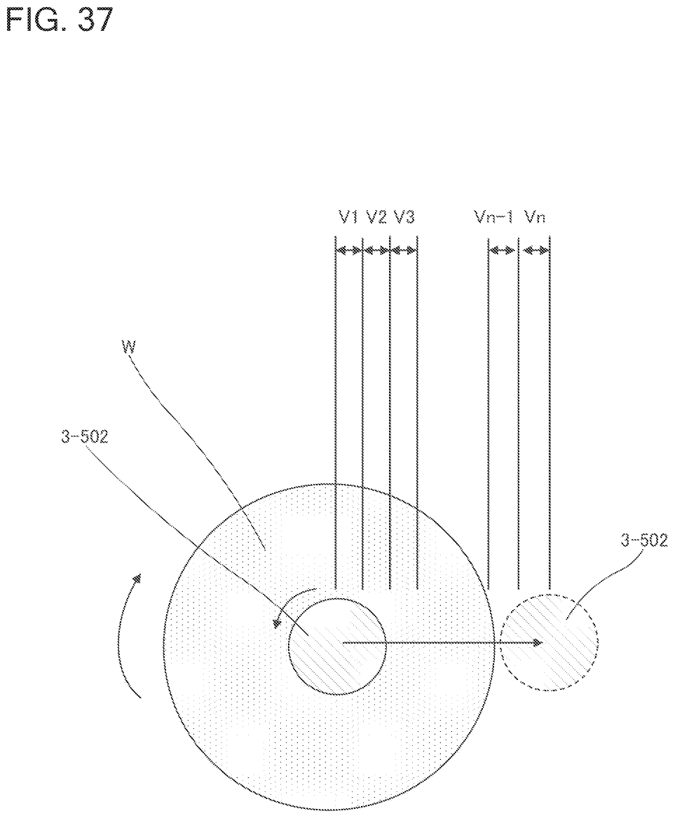

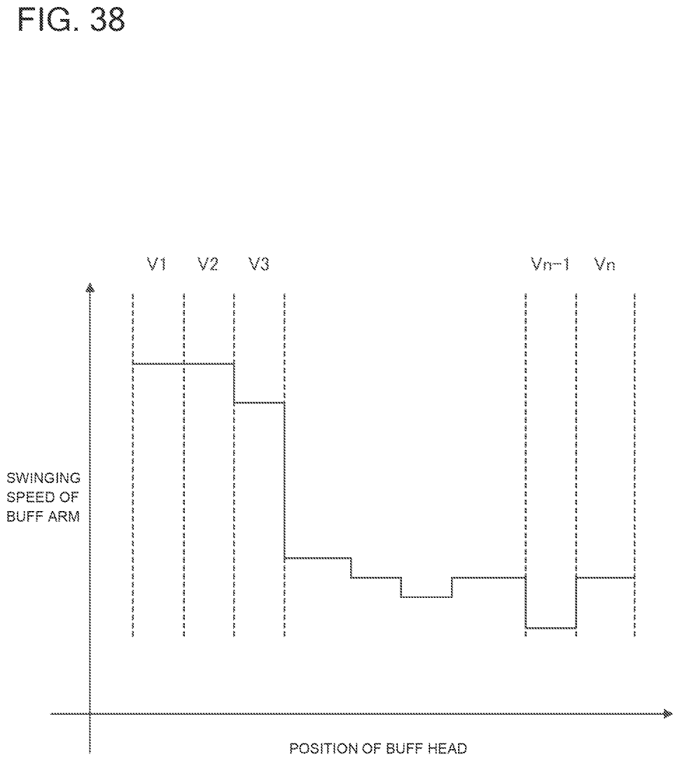

FIG. 37 is an explanatory diagram of an outline of control of a swinging speed of the buff arm. FIG. 38 is a diagram illustrating an example of control of the swinging speed of the buff arm. In FIG. 38, the supporting guide is not illustrated for simplification of the descriptions. In FIG. 38, the abscissa represents the position of the buff head 3-500 and the ordinate represents the swinging speed of the buff arm. In the example in FIGS. 37 and 38, the swinging speed of the buff arm 3-600 is controlled. However, the polishing apparatus 3-1000 is not limited to this. The polishing apparatus 3-1000 may control at least one of the swinging speed of the buff arm 3-600, the rotation speed of the buff head 3-500, the rotation speed of the buff table 3-400 and the press pressure of the buff pad 3-502 to the wafer W for each section.

In the example in FIG. 37, the swing of the buff arm 3-600 is reciprocating movement between the center of the wafer W and a position where the buff pad 3-502 does not completely overlap with the wafer W or the buff table 3-400. As illustrated in FIGS. 37 and 38, in the polishing apparatus 3-1000, the swinging range of the buff pad 3-502 is divided into a plurality of sections (n sections). In the polishing apparatus 3-1000, the swinging speed of the buff arm 3-600 can be variably controlled to be V1, V2, V3, . . . Vn−1, Vn for each section.

The swinging speed of the buff arm 3-600 is variably controlled for each section of the swinging range of the buff arm 3-600 so that a staying time of the buff pad 3-502 in the outer circumferential part of the wafer W can be made longer than that in the inner circumferential part, for example. Accordingly, the sliding distances of the buff pad 3-502 in the outer circumferential part and the inner circumferential part of the wafer W, or the processing-speed distribution can be equalized.

In the example in FIG. 36, the buff arm 3-600 linearly swings to obtain 100% overhang of the buff pad 3-502 at both ends of the wafer W. In the example in FIG. 37, the buff arm 3-600 linearly swings to obtain 100% overhang of the buff pad 3-502 at one end of the wafer W from the center of the wafer W. However, the swing of the buff arm 3-600 is not limited to these examples.

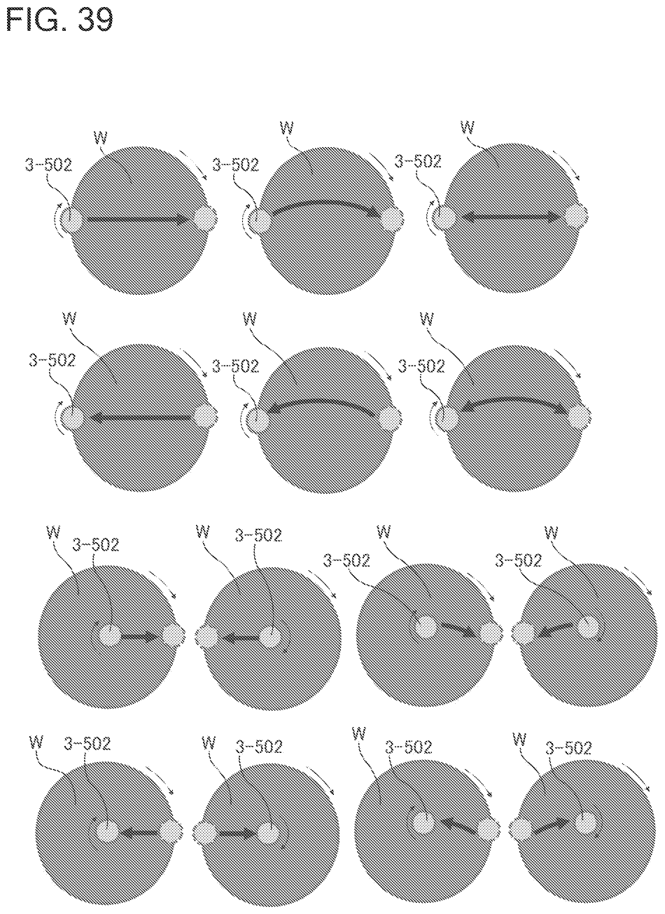

FIG. 39 is a diagram illustrating variations of a swinging form of the buff arm 3-600. In FIG. 39, the supporting guide is omitted for simplification of the descriptions.

As illustrated in FIG. 39, the buff arm 3-600 may perform linear motion to reciprocate the buff pad 3-502 or to move the buff pad 3-502 only in one direction. Alternatively, the buff arm 3-600 may perform circular arc motion to reciprocate the buff pad 3-502 or to move the buff pad 3-502 only in one direction. In performing the linear motion or circular arc motion, the buff pad 3-502 is preferably moved so as to pass through a range of ±10 mm, for example, from the center of the wafer W.

As illustrated in FIG. 39, the buff arm 3-600 may move the buff pad 3-502 between both ends of the wafer W, or may move the buff pad 3-502 between the center and the end of the wafer W. Also in this case, the buff pad 3-502 is preferably moved by the buff arm 3-600 so as to pass through the range of ±10 mm, for example, from the center of the wafer W.

### REFERENCE SIGNS LIST

300A upper buff processing module
300B lower buff processing module
350 buff processing component
400 buff table
500 buff head
500-1 first buff head
500-2 second buff head
502 buff pad
502-1 first buff pad
502-2 second buff pad
502-3 third buff pad
600 buff arm
600-1 first buff arm
600-2 second buff arm
610, 610-1, 610-2 shaft
620 end
810 dressing table
820, 820-1, 820-2 dresser
2-300A buff processing module
2-400 buff table
2-410 fluid passage
2-500 buff head
2-502 buff pad
2-600 buff arm
2-900 temperature controlling unit
2-902 blower
2-910 fluid circulation passage
2-950 radiation thermometer
2-952 sheet-type in-plane temperature distribution thermometer
3-3 polishing unit
3-4 cleaning unit
3-5 controlling device
3-10 polishing pad
3-190 roll cleaning chamber
3-191 first transfer chamber
3-192 pen cleaning chamber
3-193 second transfer chamber
3-194 drying chamber
3-195 third transfer chamber
3-201A upper roll cleaning module
3-201B lower roll cleaning module
3-202A upper pen cleaning module
3-202B lower pen cleaning module
3-205A upper drying module
3-205B lower drying module
3-300 buff processing chamber
3-300A upper buff processing module
3-300B lower buff processing module
3-400 buff table
3-410 supporting guide
3-500 buff head
3-502 buff pad
3-510 opening
3-530, 3-530a, 3-530b, 3-530c, 3-530d, 3-580
3-535 constriction part
3-540 outer circumferential end
3-550 outer circumferential part
3-560, 3-570 protruding part
3-600 buff arm
3-700 liquid supplying system
3-800 conditioning unit
3-810 dressing table
3-820 dresser
3-1000 polishing apparatus
W wafer

What is claimed is:

1. A processing component comprising:
a head to which a pad is attached, the pad coming into contact with and moving relatively to a substrate to perform a predetermined process to the substrate; and
an arm holding the head, wherein
the head includes a first head to which a first pad having a smaller diameter than the substrate is attached, and a second head to which a second pad having a smaller diameter than the first pad is attached, and the second head is different from the first head.

2. A processing module comprising the processing component according to claim 1, wherein
the arm includes a first arm and a second arm that is different from the first arm,
the first head is held by the first arm, and
the second head is held by the second arm.

3. The processing module according to claim 2, wherein
the second head is held by the second arm in such a way that the second pad contacts with a peripheral edge part of the substrate.

4. The processing module according to claim 3, further comprising a plurality of the second heads to which the respective second pads are attached, wherein
the second heads are held by the second arm in such a way that the second pads are adjacent to each other in a direction of a peripheral edge of the substrate and are in contact with the peripheral edge part of the substrate.

5. A processing module comprising the processing component according to claim 1, wherein
the arm includes a single arm, and
the first head and the second head are held by the single arm.

6. The processing module according to claim 5, wherein
the second head is held by the single arm in such a way that the second pad is in contact with at least the peripheral edge part of the substrate.

7. The processing module according to claim 6, wherein
the first head and the second head are held by the single arm so as to be adjacent with each other along a swinging direction of the single arm.

8. The processing module according to claim 7, further comprising a plurality of the second heads to which the respective second pads are attached, wherein
the first head is held by the single arm, and
the second heads are held by the single arm so as to be adjacent to both sides of the first head along the swinging direction of the single arm.

9. A processing module comprising the processing component according to claim 1, wherein
the arm includes a first arm and a second arm that is coupled with the first arm,
the first head is held by the first arm, and
the second head is held by the second arm.

10. A processing module comprising:
the processing component according to claim 1; and
a table holding the substrate, wherein
the processing module processes the substrate by supplying a processing liquid to the substrate, rotating the table and the head, bringing the first and second pads into contact with the substrate simultaneously or alternately, and swinging the arm.

11. The processing module according to claim 2, wherein
the processing module is a buff processing module performing a buff process to the substrate.

12. The processing module according to claim 2, wherein
when the pad includes a plurality of pads, a kind or material of at least one of the pads may be different from a kind or material of the other pads.

13. The processing module according to claim 2, further comprising a plurality of dressers performing conditioning of the pad.

14. The processing module according to claim 13, wherein
at least one of the plurality of dressers may have a diameter, a kind or a material different from those of the other dresser.
